(19) United States
(12) Patent Application Publication
(10) Pub. No.: US 2026/0173426 A1
(43) Pub. Date: Jun. 18, 2026

(54) THIN FILM SEMICONDUCTOR DEVICE AND FABRICATION

(71) Applicant: Texas Instruments Incorporated, Dallas, TX (US)

(72) Inventors: Baher Haroun, ALLEN, TX (US); Sebastian Meier, MUENCHEN (DE); Orlando Lazaro, CARY, NC (US); Ujwal Radhakrishna, SAN JOSE, CA (US); Manoj Jain, Plano, TX (US); Luigi Colombo, Dallas, TX (US)

(73) Assignee: Texas Instruments Incorporated, Dallas, TX (US)

(21) Appl. No.: 19/179,088

(22) Filed: Apr. 15, 2025

Related U.S. Application Data
(60) Provisional application No. 63/734,606, filed on Dec. 16, 2024.
(60) Provisional application No. 63/734,588, filed on Dec. 16, 2024.
(60) Provisional application No. 63/734,596, filed on Dec. 16, 2024.

(51) Int. Cl. H10D 30/01; H10D 30/67

(52) U.S. Cl. CPC H10D 30/031; H10D 30/6755

(57) ABSTRACT

In one example, a method comprises: forming a stack structure including a first dielectric structure, a channel layer, and a second dielectric structure, in which the first and second dielectric structures are on opposing sides of the channel layer; forming a third dielectric structure on the first dielectric structure, in which the first dielectric structure is between the third dielectric structure and the channel layer; patterning the third dielectric structure to form a dielectric spacer; patterning the first dielectric structure by a wet etching operation to expose a first part of the channel layer and a second part of the channel layer, in which the dielectric spacer is between the first part and the second part of the channel layer; forming a first current terminal of a transistor on the first part of the channel layer; and forming a second current terminal of the transistor on the second part of the channel layer.

### CROSS-REFERENCE TO RELATED APPLICATIONS

This application claims priority to: 1) U.S. Provisional Application No. 63/734,588, filed Dec. 16, 2024, titled “Thin Film Semiconductor Device and Fabrication”; 2) U.S. Provisional Application No. 63/734,606, filed Dec. 16, 2024, titled “Thin Film Semiconductor Device and Fabrication”; and 3) U.S. Provisional Application No. 63/734,596, filed Dec. 16, 2024, titled “Thin Film Semiconductor Device and Fabrication”, all of which are hereby incorporated by reference by their entireties.

### BACKGROUND

An integrated circuit may include various devices, such as transistors, diodes, resistors, etc., formed in a semiconductor substrate. A metallization structure including contacts, vias, metal layers, and insulating layers (e.g., dielectric layers) are formed over the devices to provide electrical connections among the devices and to provide external access to the devices. A front-end-of-line (FEOL) process can be a first portion of IC fabrication process where the individual devices (transistors, diodes, resistors, etc.) are patterned in a wafer. A back end of line (BEOL) process can be a second (or a subsequent) portion of the IC fabrication process where the metallization structure is formed on the wafer to connect the individual devices with wiring or metal layers on the wafer.

### SUMMARY

This Summary is provided to introduce examples of disclosed concepts in a simplified form, which are further described below in the Detailed Description including the drawings provided.

In one example, a method comprises forming a stack structure including a first dielectric structure, a channel layer, and a second dielectric structure, in which the first and second dielectric structures are on opposing sides of the channel layer. The method further comprises forming a third dielectric structure on the first dielectric structure, in which the first dielectric structure is between the third dielectric structure and the channel layer, and patterning the third dielectric structure to form a dielectric spacer. The method further comprises patterning the first dielectric structure by a wet etching operation to expose a first part of the channel layer and a second part of the channel layer, in which the dielectric spacer is between the first part and the second part of the channel layer. The method further comprises forming a first current terminal of a transistor on the first part of the channel layer, and forming a second current terminal of the transistor on the second part of the channel layer.

### BRIEF DESCRIPTION OF THE DRAWINGS

Illustrative examples are described in detail below with reference to the following figures.

FIG. 1A, FIG. 1B, FIG. 1C, and FIG. 1D are schematics of a thin film semiconductor device, according to some examples.

FIG. 2A, FIG. 2B, and FIG. 2C are schematics of a thin film semiconductor device, according to some examples.

FIG. 3, FIG. 4A, FIG. 4B, FIG. 5, FIG. 6, FIG. 7A, and FIG. 7B are schematics of a thin film semiconductor device, according to some examples.

FIG. 8 is a flowchart of a method of fabricating a thin film semiconductor device, according to some examples.

FIGS. 9A-1, 9A-2, 9B, 9C, 9D, 9E, 9F, 9G, 9H, 9I, 9J, 9K-1, 9K-2, 9K-3, 9K-4, 9L-1, 9L-2, 9M-1, 9M-2, 9N-1, 9N-2, 9O-1, 9O-2, and 9P are schematics illustrating cross sections of a thin film semiconductor device in the fabrication operations described in the flowchart of FIG. 8, according to some examples.

FIGS. 10A, 10B, 10C, 10D, 10E, 10F, 10G, 10H, and 10I are schematics illustrating cross sections of a thin film semiconductor device in the fabrication operations described in the flowchart of FIG. 8, according to some examples.

FIGS. 11A, 11B, 11C, 11D, and 11E are schematics of a thin film semiconductor device, according to some examples.

FIGS. 12A, 12B, 12C, and 12D are schematics of a thin film semiconductor device, according to some examples.

FIGS. 13 and 14 are schematics of a thin film semiconductor device, according to some examples.

FIG. 15 is a flowchart of a method of fabricating a thin film semiconductor device, according to some examples.

FIGS. 16A, 16B, 16C, and 16D are schematics illustrating cross sections of a thin film semiconductor device in the fabrication operations described in the flowchart of FIG. 15, according to some examples.

FIGS. 17A, 17B, 17C, 17D, 17E, and 17F are schematics illustrating cross sections of a thin film semiconductor device in the fabrication operations described in the flowchart of FIG. 15, according to some examples.

FIGS. 18A, 18B, 18C, 18D, 18E, 18F, and 18G are schematics illustrating cross sections of a thin film semiconductor device in the fabrication operations described in the flowchart of FIG. 15, according to some examples.

FIGS. 19A, 19B, 19C, 19D, and 19E are schematics illustrating cross sections of a thin film semiconductor device in the fabrication operations described in the flowchart of FIG. 15, according to some examples.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

The present disclosure relates generally to semiconductor devices, an in particular, thin film semiconductor devices and their fabrications. As described above, a device can be fabricated using a metallization structure on the wafer in the back-end-of-line (BEOL) to connect the individual devices, formed in a front-end-of-line (FEOL) process as FEOL devices (e.g., transistors, passive devices, etc.), with wiring or metal layers on the wafer. As part of the BEOL process, thin film devices, such as thin film transistors (TFT) and switches, can also be formed in or on the metallization structure. Forming thin film devices in or on the metallization structure can offer various advantages. For example, by having both FEOL and BEOL transistors, the density of transistors in an integrated circuit can be increased. Moreover, the BEOL transistors can have different structures and/or different channel materials from the FEOL transistors, which allow the BEOL transistors to have a different (and in some cases superior) performance profile compared with the FEOL transistors. Alternatively, TFT devices can be fabricated directly on other dielectric substrates such as: glass, aluminum nitride, sapphire or ceramic like substrates providing active device capability for functions that require tuning of passive devices such as capacitors or inductors implemented on top of such substrates or enabling photonic capabilities.

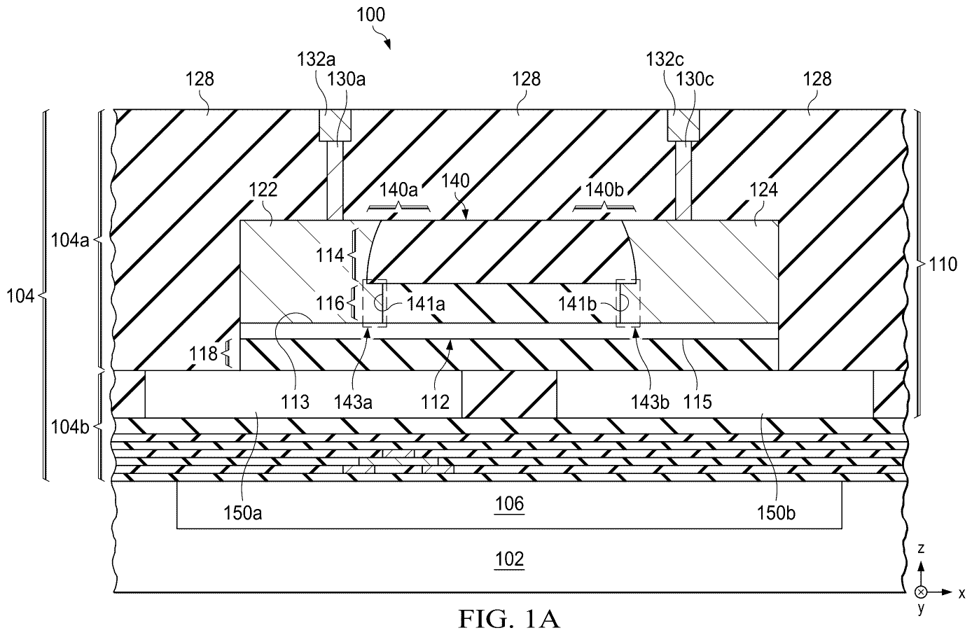

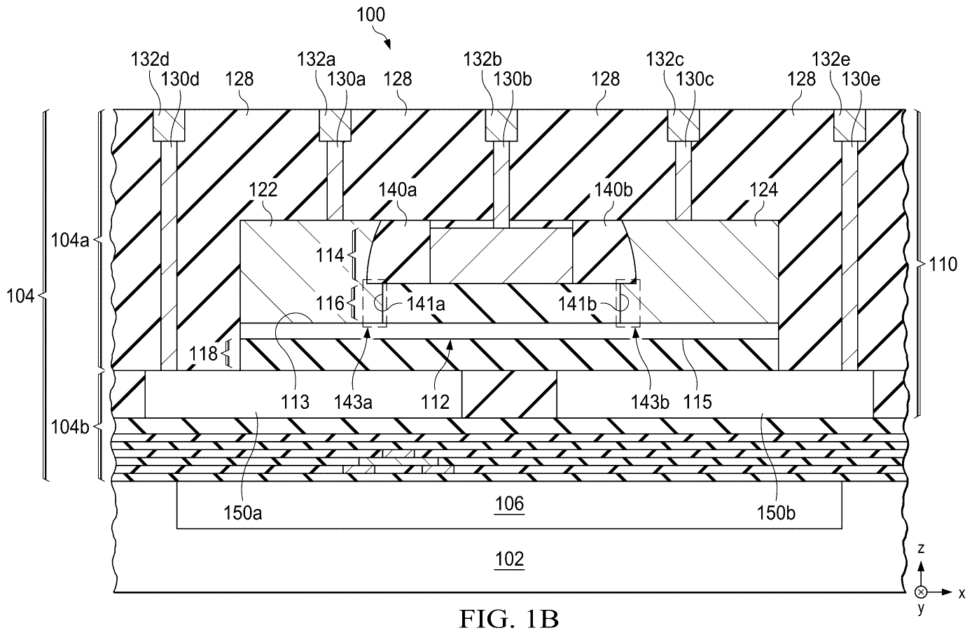

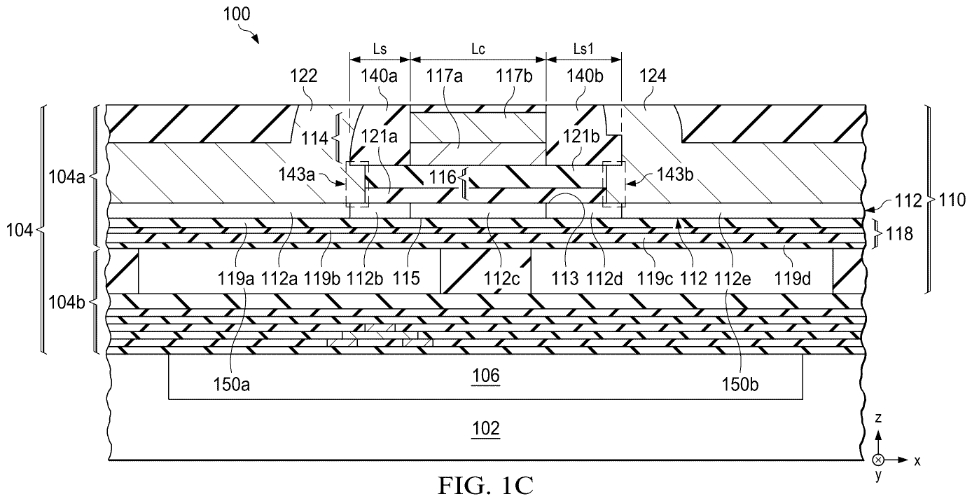

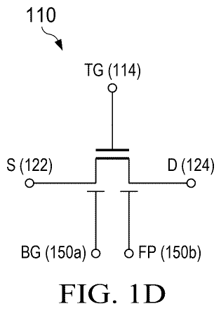

As to be described herein, examples of a TFT that can be fabricated in a BEOL process may include a channel layer, a first dielectric structure on a first side of the channel layer, and a second dielectric structure on a second side of the channel layer opposing the first side, such that the channel layer is between the first and second dielectric structures. As to be shown in FIG. 1A, the TFT may include a dielectric spacer structure on the first dielectric structure and on the first side of the channel layer, and a first current terminal and a second current terminal (e.g., source and drain) on the first side of the channel layer, where the dielectric spacer structure is between the first and second current terminals to provide electrical insulation between the current terminals. The dielectric spacer structure may include overhang regions that extend over two ends of the first dielectric structure and forming recesses between the dielectric spacer structure and the channel layer. The first and second current terminals can fill the recesses. As to be described below, the first dielectric structure, the channel layer (e.g., a metal oxide such as indium oxide), and the second dielectric structure can be formed in situ (e.g., in the same vacuumed environment), to reduce/eliminate defects and contamination at the interfaces between the channel layer and the first and second dielectric structures. With such arrangements, the concentrations of defects/contaminations at the interfaces can be in the same order as the concentrations of defects/contamination at the channel layer and at the first and second dielectric structures. In contrast, in a case where the channel layer is not formed in situ with the first or second dielectric structures, the concentrations of defects/contaminations at the interfaces can be at least ten times of the concentrations of defects/contaminations at the first and second dielectric structures.

Part of the first dielectric structure is then etched, using the dielectric spacer structure as a mask, to expose the channel layer, and to form the metal contacts of the first and second current terminals. In some examples, the first and second dielectric structures and the channel layer can be formed by an atomic layer deposition (ALD) process, and the channel layer has a thickness in the order of nanometers (nm), such as 1-2 nm. In such examples, an isotropic wet etch operation can be performed to avoid etching through the channel layer, and the wet etch operation may create undercuts in part of the first dielectric structure below the dielectric structure, where the undercuts form the recesses.

In some examples, the TFT can be part of a metallization structure on a semiconductor substrate. The metallization structure can include an upper metallization structure and a lower metallization structure, where the lower metallization structure is between the upper metallization structure and the semiconductor substrate. In some examples, as to be shown in FIG. 1A, the TFT may include a control terminal (e.g., a gate) on the second side of the channel layer, where the second dielectric structure is between the control terminal and the channel layer to provide electrical insulation. The control terminal can control the on/off of TFT as well as an amount of current that flows in the channel layer between the first and second current terminals based on voltages at the control terminal and at the first and second current terminals, and the threshold voltage of the TFT. The first and second dielectric structures, the channel layer, the first and second current terminals, and the dielectric spacer structure of the TFT may be in the upper metallization structure, whereas the control terminal can be part of the lower metallization structure and can be coupled to active and/or passive FEOL circuitries in/on the substrate via the metal interconnects (e.g., vias and metal layers) of the lower metallization structure. The first and second current terminals can be coupled to external metal contacts via metal interconnects (e.g., vias and metal layers) of the upper metallization structure. In some examples, as to be shown in FIG. 7B, the first and second current terminals can also be coupled to active and/or passive FEOL circuitries in/on the substrate via the metal interconnects (e.g., vias and metal layers) of the lower metallization structure.

In some examples, as to be shown in FIG. 1B and some of the subsequent figures, the control terminal on the first side of the channel layer can be a first control terminal and a top gate, and the top gate can be separated from each of first and second current terminals by a respective dielectric spacer structure. The TFT may also include one or more second control terminals on the second side of the channel layer and is separated from the channel layer by the second dielectric layer. The one or more second control terminals can also include metal terminals, and the transistor include one or more metal-vias through the third dielectric layer to electrically couple with the one or more second control terminals. In some examples, the first control terminal can be a top gate to control the channel formation and the current in the channel, as described above, and the one or more second control terminals can include a bottom gate overlapping a part of the channel region between the first current terminal/source and the top gate. The bottom gate can receive a second voltage to set a threshold voltage for the formation of the channel in the channel layer. In some examples, the one or more second control terminals can also include a field plate overlapping a part of the channel layer between the second current terminal/drain and the top gate. The field plate can receive a third voltage and adjust the electric field distribution along the channel layer when the channel is disabled or off. Such arrangements allow formation of a transistor with multiple control terminals that allow static/dynamic tuning of various properties, such as charge density, on-resistance, and breakdown voltage of the transistor when the transistor is off. All these allow the transistor to be configured/adapted, using control signals, to support a wide range of applications, such as power converters operating in high voltage domains, communication circuits, high frequency/speed applications, etc. Such transistors can be used to form more complex circuits, such as bi-directional switches, that have tunable properties to also support a wide range of applications. The second control terminals can also conduct heat way from the channel layer (and by the second dielectric layer) to reduce both the thermal resistance and increase the thermal time constant of the transistor.

In some examples, the control terminal (e.g., gate) can include a stack of two different metals, one for providing improved electrical connection (e.g., reduced resistance) to the metal via, and the other for setting the threshold voltage of the transistor. For example, the gate can include a bottom layer of a high work function metal (e.g., a noble metal), or metal oxide, such as platinum (Pt), palladium (Pd), iridium (Ir), iridium oxide (IrOx), ruthenium (Ru), ruthenium oxide (RuO₂), to set the threshold voltage, and a top layer such as copper (Cu), cobalt (Co), ruthenium (Ru), aluminum (Al), or tungsten (W) in contact with/abutting the metal via. The first and second current terminals (source and drain) can have the same metal as the top layer and/or bottom layer of the gate or different metal such as cobalt, nickel, tungsten and other barrier metals or nitrides such as tantalum (Ta), Titanium (Ti), tungsten (W), tantalum nitride (TaN), tantalum carbo nitride (TaCN), titanium nitride (TiN), titanium carbo nitride (TiCN), titanium silicon carbo nitride (TiSiCN), tantalum silicon carbo nitride (TaSiCN) ruthenium (Ru), ruthenium nitride (RuN), ruthenium carbo nitride (RuCN), ruthenium silicon carbo nitride (RuSiCN), titanium tungsten (TiW), titanium tungsten carbo nitride (TiWCN), cobalt tungsten phosphorus (CoWP), or layered stacks using any combination of the aforementioned materials.

In some examples, the dielectric spacer structure between the control terminal and at least one of the first or second current terminals can have sub-lithography lateral thickness (e.g., thickness along an axis parallel to a major surface of the substrate). Because of the sub-lithography lateral thickness, the dielectric spacer can have a lateral thickness that is smaller than a minimum dimension allowed by the lithography process used in fabricating the transistor, to reduce the channel length in the spacer region and hence the on-resistance (Rₒₙ), by shrinking the part of channel layer below the spacer region, which has a higher resistance than the part of channel layer below the gate when the device is on. The parasitic capacitance (e.g., C_{off}) of the transistor can also be reduced by using a relatively low dielectric constant material for the spacer, thus reducing (and improving) the figure of merit (FOM) of Rₒₙ*C_{off} for use in high frequency applications (e.g., radio-frequency (RF) applications), and/or to allow the source to be optimized for improved on-state current (Iₒₙ) over off-state current (I_{off}) ratio (Iₒₙ/I_{off}). For example, in a case where the control terminal is patterned to have a minimum length (along an axis between the source and drain) allowed by a lithography process. This also sets the channel length of the transistor, the lateral thickness of at least one of the dielectric spacers (e.g., the dielectric spacer on the source side) can be smaller than the channel length. In some examples, the dielectric spacer on the drain side includes an extension to increase the lateral distance between the drain (e.g., the second current terminal) and the gate (e.g., the control terminal), to enhance the tolerance of high drain/source voltages by the transistor for high voltage applications. The longer channel on the drain side also allows for a drift region when the device is turned on and the drain has a high voltage. This allows a higher voltage on the drain before the channel or the neighboring dielectrics breaks down under a high electric field.

In some examples, the channel layer in the BEOL device may include a material that is different from the semiconductor substrate and can provide, for example, increased charge mobility, increased charge density, a higher bandgap value, a higher breakdown electric field and/or a reduced gate charge for the channel (when on at a specific Rₒₙ) compared with a semiconductor material for a FEOL transistor such as a Silicon MOSFET. In some examples, the channel layer may include a semiconducting metal-oxide material, such as: indium oxide (In₂O₃), indium gallium oxide (InGaO), indium gallium zinc oxide (InGaZnO or IGZO), indium tin oxide (InSnO or ITO), or any of these metal oxides doped/alloyed with tungsten or nitrogen, and transition metal dichalcogenides. In some examples, the channel layer may include carbon nanotubes, such as single wall carbon nanotubes (SWCNT). In some examples, the chemical composition and/or mechanical structure of the channel layer can be uniform throughout the channel layer. In some examples, the channel layer can have different chemical compositions and/or mechanical structures in different regions. For examples, channel regions under the gate/control terminal, under the dielectric spacers, and under (or interfacing with) the source/drain contacts, can have different chemical compositions and/or mechanical structures, to improve various properties of the thin film transistor, such as reducing contact resistance, improving channel mobility, increasing drain-source breakdown voltage, increasing on-state current (Iₒₙ) over off-state current (I_{off}) ratio, etc.

For example, in a case where the channel layer includes carbon nanotubes such as SWCNTs, regions of the channel layer that interface with the first and second current terminals can be treated (e.g., a hydrogen, oxygen, nitrogen or inert gas plasma treatment) to introduce defects to the carbon nanotubes in the regions to improve contact between the current terminals and the SWCNTs, which can reduce contact resistance. The SWCNTs under the first control terminal (e.g., gate) can be masked/protected from the plasma treatment to prevent damage that can lead to charge mobility degradation. The surface of SWCNTs which are usually covered by residual organics can also be cleaned using a lanthanide metal or other low work function metals that can react with the underlying residue oxidized in air and then chemically removed with acids to yield a clean SWCNT surface which then be treated or using the above mentioned plasma process to created defects that act as edge contacts that tend to have a lower contact resistance. Also, the oxide charge of the SWCNTs in the regions of the channel layer under the dielectric spacers can be controlled/reduced by chemically removing residues from the SWCNT deposition process to improve the Iₒₙ/I_{off} ratio and adjust the threshold voltage of the TFT.

Also, in a case where the charge layer includes a metal oxide material, such as indium oxide (e.g., In₂O₃), the oxygen vacancy (or doping content) of regions of the channel layer that interface with the first and second current terminals can be adjusted by, for example, annealing at BEOL compatible temperatures (below 450° C.) with one or more of the contact metals (e.g., cobalt (Co), nickel (Ni), molybdenum (Mo), titanium (Ti), tantalum (Ta), gallium (Ga), zinc (Zn), etc.) to share the oxygen already present and produce a low contact resistance. Example barrier metals include: tantalum (Ta), titanium (Ti), tungsten (W), tantalum nitride (TaN), tantalum carbo nitride (TaCN), titanium nitride (TiN), titanium carbo nitride (TiCN), titanium silicon carbo nitride (TiSiCN), tantalum silicon carbo nitride (TaSiCN) ruthenium (Ru), ruthenium nitride (RuN), ruthenium carbo nitride (RuCN), ruthenium silicon carbo nitride (RuSiCN), titanium tungsten (TiW), titanium tungsten carbo nitride (TiWCN), cobalt tungsten phosphorus (CoWP), or layered stacks using any combination of the aforementioned materials. Also, the oxygen vacancy (or doping content) of a region of the channel layer under the first control terminal (e.g., gate) can be adjusted to improve charge density by adjusting the oxygen vacancy level or terminating some vacancies with hydrogen or fluorine annealing. Further, the oxygen vacancy (or doping content) of a region of the channel layer under the dielectric spacer between the source (e.g., the first current terminal) and the top gate (e.g., the first control terminal) can be adjusted to change the threshold voltage of the TFT, and/or reduce sub-threshold slope and I_{off}, while the oxygen vacancy (or doping content) of a region of the channel layer under the dielectric spacer between the drain (e.g., the second current terminal) and the top gate (e.g., the first control terminal) can also be adjusted to increase the drain-source breakdown voltage of the transistor when the transistor is in the off state.

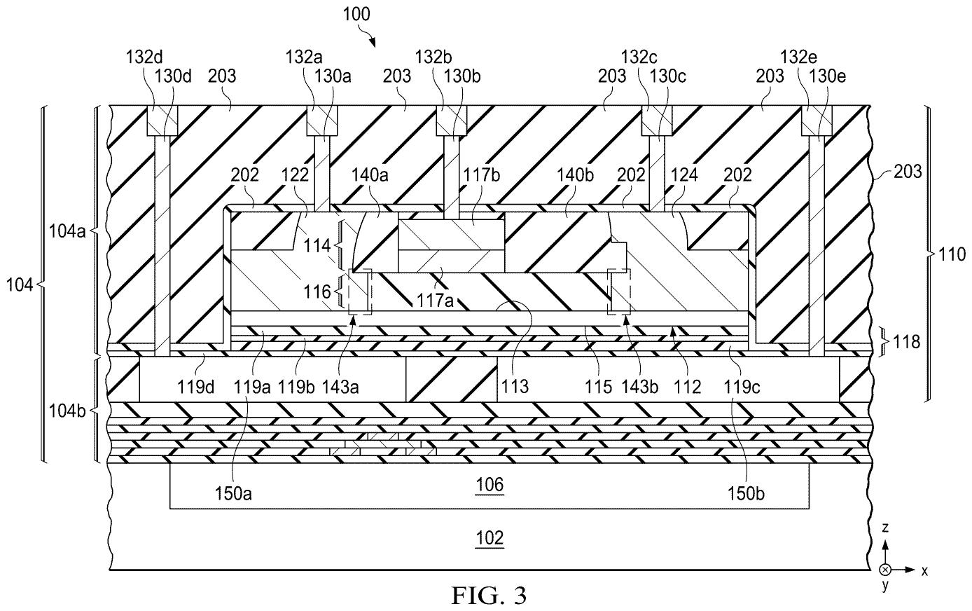

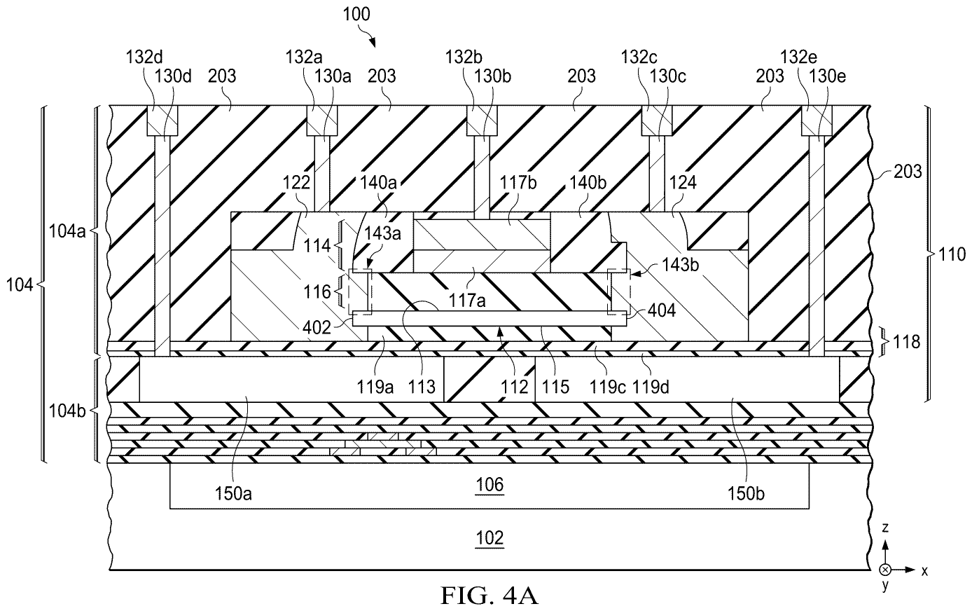

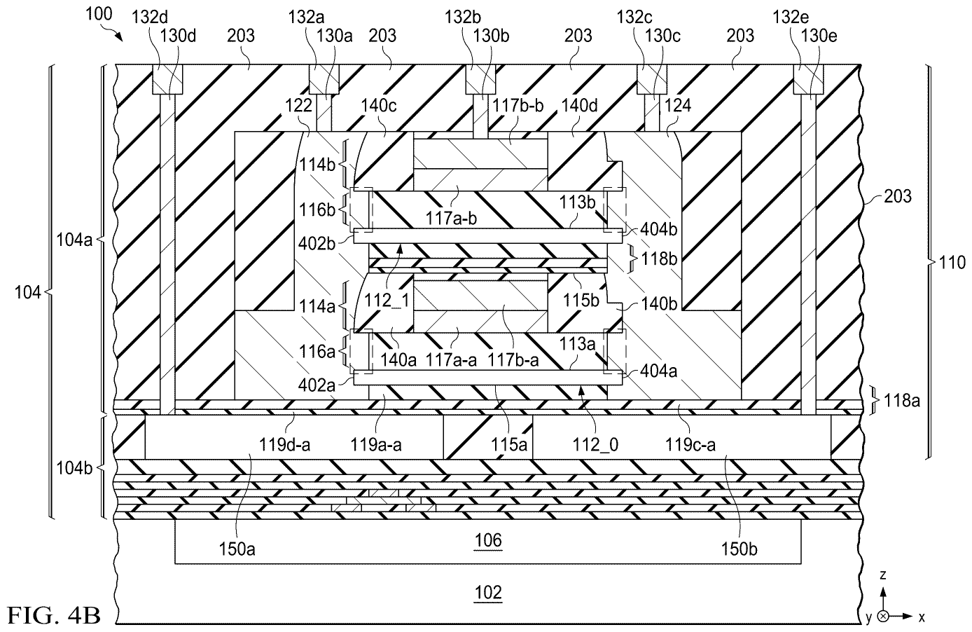

In some examples, as to be shown in FIG. 3, the first and second current terminals are on the first side of the channel layer, where a metal (e.g., nickel (Ni), palladium (Pd), copper (Cu), tungsten (W), cobalt (Co), etc.) or a metal stack (e.g., stacks of Ni/Cu, Ni/Ti/W, Ni/Al, and a stack of A/B (e.g., a barrier layer metal and contact metal), where A can be TiN or TaN and B can be Ni, Cu, Al, or W) can be deposited on top of the channel layer material to form top contacts and in contact with/abutting the dielectric spacers and the first side of the channel layer, and the metal (or metal stack) can be patterned to form the metal contacts/terminals of first and second current terminals. In some examples, as to be shown in FIG. 4A, one or more of the first and second current terminals can extend between the first and second sides of the channel layer as an edge contact that wraps around the edges of the channel layer. The edge contacts can shape the voltage potential around the contact area, making the electric field (voltage potential gradient) more uniform to the channel layer around the drain and/source contacts, which can reduce peaking of the electric field and increase the breakdown voltage of the transistor when in the off-state, and reduce contact resistance. In such examples, the second dielectric layer can be part of a multi-layer dielectric structure that can be partially etched/removed to allow the metal to be deposited on the second side of the channel layer. Also, as shown in FIG. 4B, a thin film transistor can include a stack of multiple channel layers, which allows increasing the channel width (and reduce channel resistance) of the transistor while maintaining the transistor footprint/area. In such examples, each current terminal can include multiple edge contacts, each wrapping around the edges of a respective channel layer, joined together.

In some examples, as to be shown in FIG. 5, one or more of the first and second current terminals can include a hybrid edge contact, in which the contact has a metal portion and a portion made of the channel material. In some examples where the channel layer includes SWCNT, the channel layer can extend into the metal edge contact of the current terminal and below the metal vias to form a hybrid edge contact. The channel layer can be extended by, for example, a regrowth process of SWCNT using a metal catalyst with plasma-enhanced chemical vapor deposition (PECVD) using a hydrocarbon gas flow at a BEOL compatible temperature. In some examples where the channel layer includes a metal oxide material (e.g., In₂O₃), the hybrid edge contact can include a metal portion, and a layer of the channel material or similar (In₂O₃, ITO, IGZO or respective W and N doped channel layer materials) adjacent to the dielectric spacer and joins with the channel layer, so that the layer of the channel material is between the metal portion and the dielectric spacer. In some examples, as to be shown in FIG. 6, the layer of the channel material can also extend (e.g., through the aforementioned regrowth process) on and cover at least part of the multi-layer dielectric structure (e.g., the second dielectric layer), so that the layer of channel material is between the metal portion and the part of the multi-layer dielectric structure. The portion of hybrid edge contact having the channel material may shape the electric field to further reduce the peaking of the electric field and increase the breakdown voltage of the transistor when in the off-state, and the metal portion of the hybrid edge contact can further reduce contact resistance as it may offer a larger contact surface.

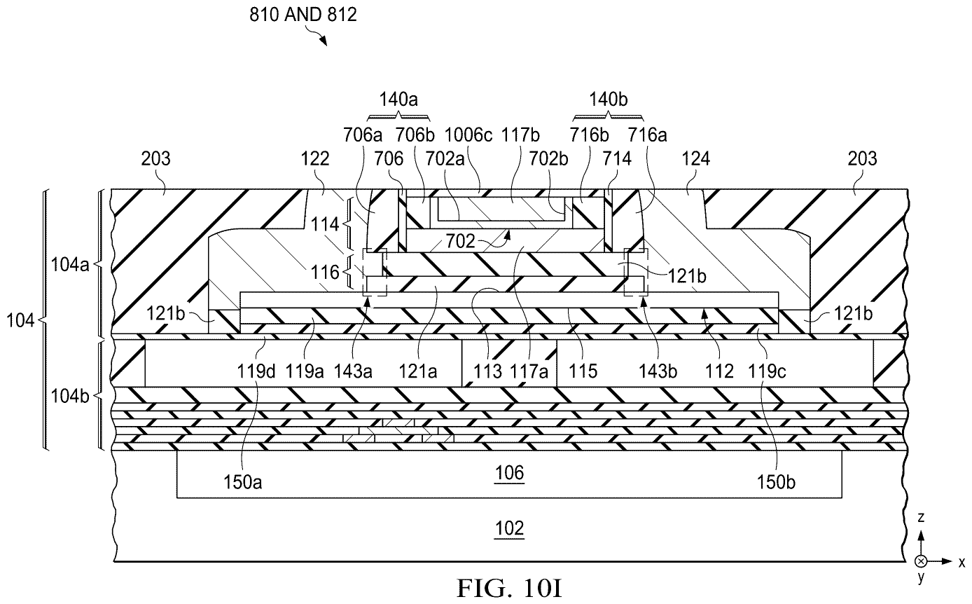

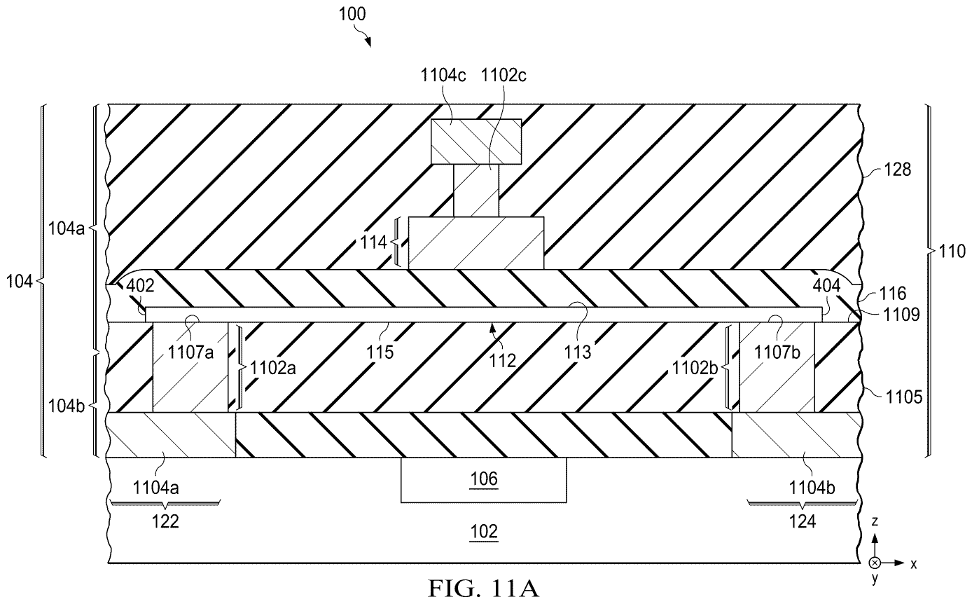

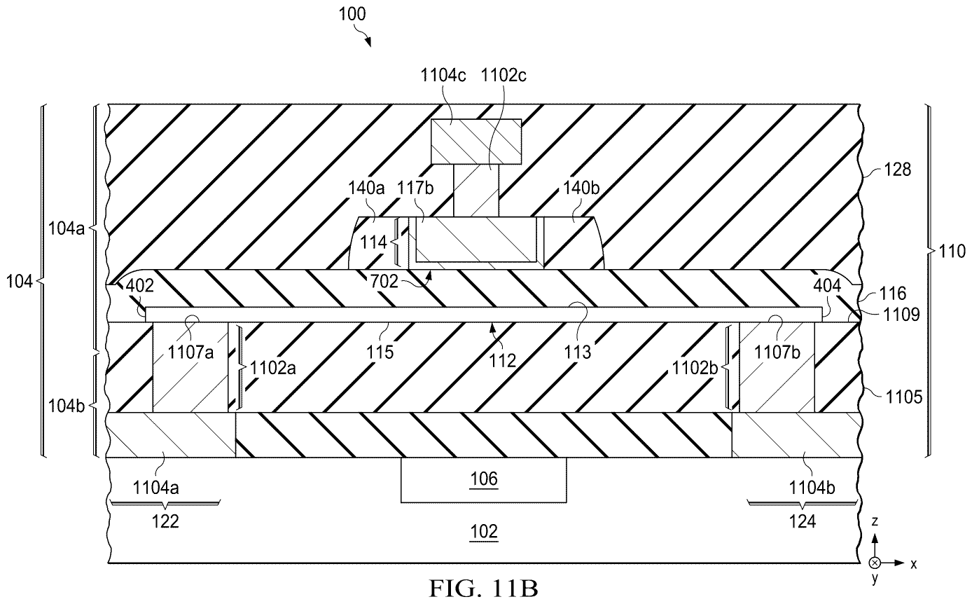

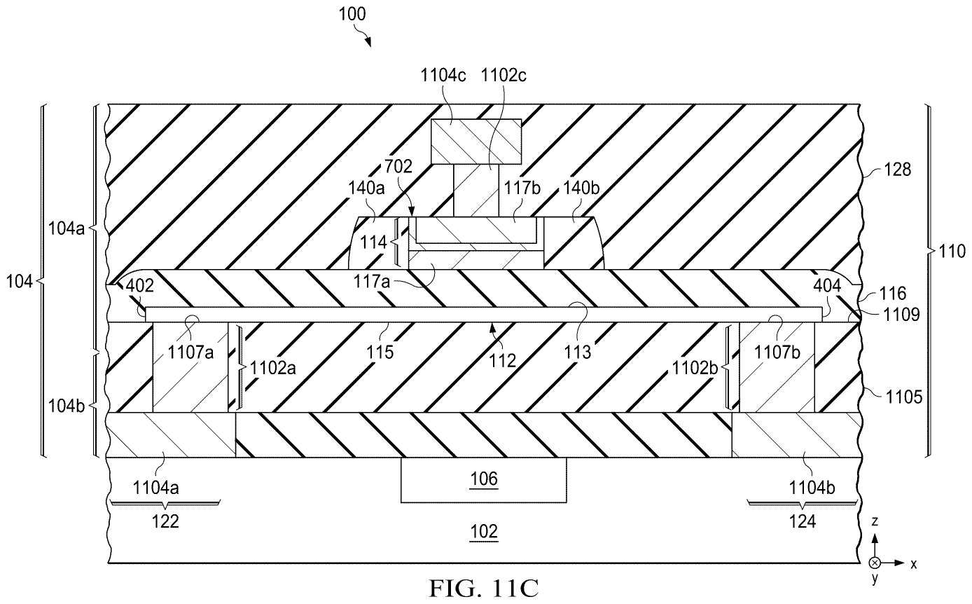

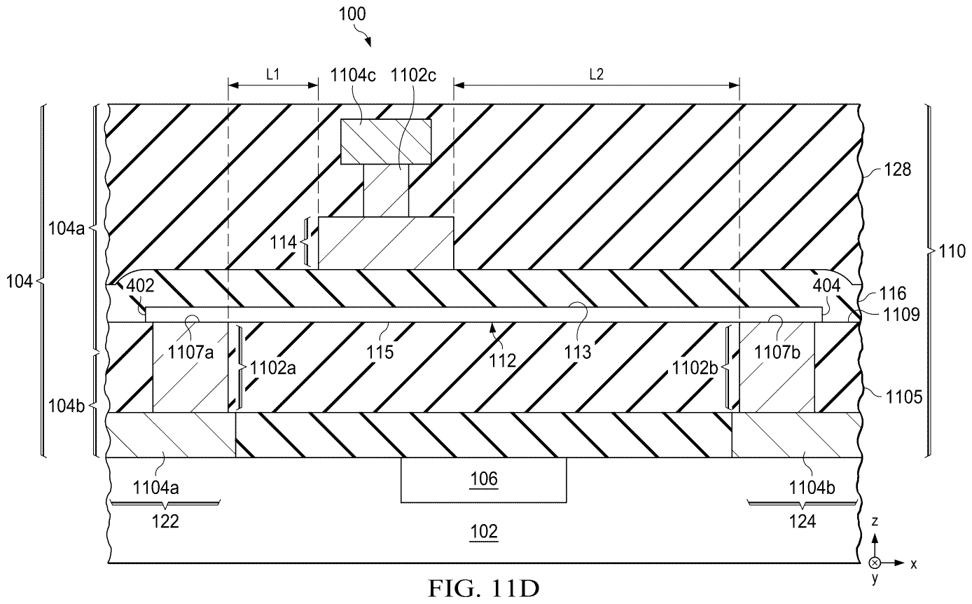

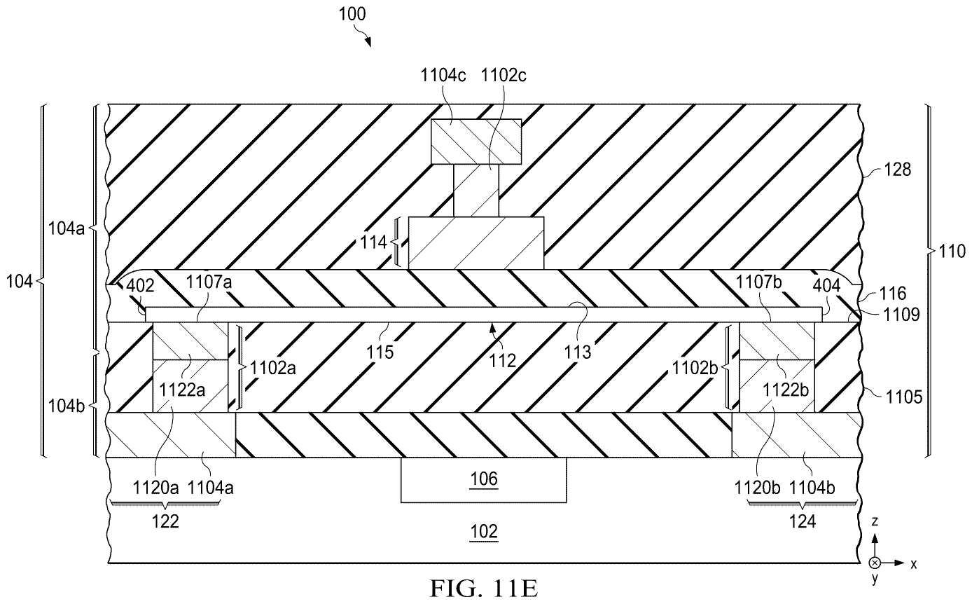

In some examples, as to be shown in FIGS. 11A-14, one or more terminals of the TFT can be formed as vias in the second dielectric structure. For example, the current terminals of the TFT can be formed as vias under the channel layer and through the second dielectric structure on the second side of the channel layer. The control terminal of the thin film transistor can be formed above (or on the first side) the channel layer, such that the channel layer is vertical between the current terminals and the control terminal. With such arrangements, the vias of the current terminals can be formed prior to forming the channel layer. The channel layer needs not be etched to form the contacts of the current terminals. This can simplify the fabrication operation of the TFT and avoid inadvertently introducing defects to areas of channel layer under (or proximate) the control terminal 114 and improve the properties of channel layer (e.g., charge mobility, current density, etc.). Having the current terminals and the control terminal on opposite sides of the channel layer also allows shrinking the lateral distance between the control terminal and each current terminal, and the overall footprint of the thin film transistor can be shrunk. In some examples, the control terminal can also be formed as a via under the control terminal, and the via as well as the dielectric structure around the via can be planarized to provide a planar surface on which the channel layer is formed. Such arrangements allows the channel layer to be planar, which can improve the uniformity of the threshold voltage of the transistor across the channel layer. The layout of these vias can be arbitrary shapes like metal layers and is not limited to, for example, drawn square which ends up being near circular in actuality. In such examples, the second dielectric structure can be formed in a different vacuumed environment from the channel layer and the first dielectric structure (e.g., not in situ), or can be formed in a selective ALD process where the deposition of the dielectric material only selectively occurs on a dielectric seed layer where there is no metal interconnects (e.g., vias).

As to be described herein, examples of TFTs can be fabricated in a BEOL process, or other thin film deposition process that shares similar process conditions as a BEOL process (e.g., at or under a temperature of 450° C.). The BEOL process also enables fabrication of bottom gate and/or field plate (e.g., the one or more second control terminals) under the channel layer. Various metal terminals (top gate, source, drain) and the metal vias can be formed using for example, a metal patterning process, an additive patterning process (e.g., a damascene process, or a dual damascene process), etc., that are compatible with a BEOL process. The fabrication of the dielectric spacer having sub-lithography lateral thickness can be performed using a planarization operation (e.g., a chemical planarization operation), which not only allows the fabrication of the transistor at a reduced lithographic resolution but also reduces the number of masks and lithography processes. All these can reduce the complexity and cost associated with the fabrication of the thin film transistor.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three-dimensional x-y-z axes are illustrated in some figures for ease of reference. Some cross-sectional views of various semiconductor devices herein may be general depictions to illustrate various aspects or concepts concerning such semiconductor devices. More specifically, some structures, such as drain/source contacts illustrated in cross-sectional views, may not necessarily accurately depict the exact structures of such contacts, except to the extent described herein. The illustrations of those structures are to illustrate various aspects or concepts concerning those structures.

In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

FIG. 1A, FIG. 1B, and FIG. 1C illustrate cross sections of examples of a semiconductor device 100 including a thin film transistor (TFT), and FIG. 1D is a circuit schematic representation of examples of the TFT of FIGS. 1B and 1C. Semiconductor device 100 includes a semiconductor substrate 102 (e.g., a substrate made of silicon or other semiconductor material) and a metallization structure 104 on semiconductor substrate 102. Semiconductor substrate 102 includes active and/or passive FEOL circuitries 106 such as transistors, resistors, capacitors, trench isolation (e.g., silicon trench isolation, STI), etc. Metallization structure 104 includes metal layers including metal interconnects (e.g., vias, contacts, lateral interconnects) covered by one or more layers of inter metal dielectric (IMD) layers. The dielectric layers can include, for example, silicon dioxide (SiO₂), silicon nitride (Si₃N₄), etc. In the example shown in FIG. 1A, metallization structure 104 includes an upper structure 104a and a lower structure 104b, each including one or more metal layers and IMDs, and lower structure 104b is vertically between (e.g., along the z-axis of FIG. 1A) upper structure 104a and semiconductor substrate 102.

Semiconductor device 100 also includes a TFT 110 on semiconductor substrate 102. In some examples, TFT 110 can be in or on metallization structure 104. In the examples shown therein, TFT 110 is in metallization structure 104. In some examples, TFT 110 can be a device fabricated in a metallization structure on the wafer in the BEOL to connect the individual devices, formed in a FEOL process as FEOL devices (e.g., transistors, passive devices, etc.), with wiring or metal layers on the wafer. In some examples (not shown in the figures), TFT 110 can be on other non-semiconductor substrate, such as a glass substrate.

In some examples, TFT 110 can be a field effect transistor (FET) and may include a channel layer 112, a control terminal 114, a dielectric structure 116, a dielectric structure 118, a current terminal 122, a current terminal 124, and a dielectric spacer 140. In the examples shown in FIGS. 1A-1C, the aforementioned components are in upper metallization structure 104a.

Control terminal 114 is on a first side 113 (e.g., a top side) of channel layer 112 and is configured as a gate terminal. Dielectric structure 116 is also on first side 113 of channel layer and is vertically (e.g., along the z-axis in the figures) between control terminal 114 and channel layer 112. Dielectric structure 118 is on a second side 115 (e.g., a bottom side) of channel layer 112 opposing first side 113, so that channel layer 112 is vertically (e.g., along the z-axis of FIG. 1A) between the dielectric structure 116 and dielectric structure 118.

In some examples, channel layer 112 includes a material that can provide increased charge mobility, increased charge density, and reduced gate charge for the channel (when on) compared with a channel in semiconductor substrate 102 (e.g., a FEOL transistor of circuitries 106). In some examples, channel layer 112 may include a semiconducting metal oxide material, such as: indium oxide (In₂O₃), indium gallium oxide (InGaO), indium gallium zinc oxide (InGaZnO or IGZO), doped zinc oxide with dopant including Al₂O₃, indium tin oxide (InSnO or ITO), or any of these metal oxides doped/alloyed with tungsten or nitrogen, and transition metal dichalcogenides. In some examples, channel layer 112 may include carbon nanotubes such as SWCNTs. In some examples, the chemical composition and/or mechanical structure of the channel layer can be uniform throughout the channel layer. In some examples, channel layer 112 can have different chemical compositions and/or mechanical structures in different regions. For examples, channel regions under the gate/control terminal, under the dielectric spacers, and under (or interfacing with) the source/drain contacts, can have different chemical compositions and/or mechanical structures, to improve various properties of the thin film transistor, such as reducing contact resistance, improving channel mobility, increasing drain-source breakdown voltage, increasing on-state current (Iₒₙ) over off-state current (I_{off}) ratio, etc. In some examples, channel layer 112 may have a thickness of 1-2 nanometers (nm) and can be deposited by an atomic layer deposition (ALD) process.

Dielectric structure 116 may include one or more dielectric layers of, for example, silicon oxide (SiO₂), silicon carbo oxygen hydride (SiCOH), hafnium oxide (HfO₂), zirconium oxide (ZrO₂), aluminum oxide (Al₂O₃), tantalum oxide (Ta₂O₃), oxides of alloys, or laminates of one or more of these oxides, or insulating nitrides like aluminum nitride (AlN) or silicon nitride (SiN) or silicon carbo nitride (SiCN) to insulate control terminal 114 from channel layer 112. In the examples shown in FIG. 1C and some of the subsequent figures, dielectric structure 116 can include a vertical stack of two dielectric layers 121a and 121b, with dielectric layer 121a abutting (or at least facing) channel layer 112, and dielectric layer 121b abutting (or at least facing) control terminal 114. Dielectric layer 121a can seal channel layer 112 and protect channel layer 112 from being impacted by agents (e.g., mask ash) involved in the fabrication of the thin film semiconductor devices. Dielectric layer 121a can also shield channel layer 112 from the interface with control terminal 114, which can include traps that affect the charge mobility of channel layer 112. Dielectric layer 121a can also be of an oxide type, such as SiO₂, amorphous boron nitride (a-BN) or other low-k gate dielectrics, that enhances the charge mobility of channel layer 112, as dielectric layer 121a can reduce the electron scattering due to the nature of such type of dielectric interaction with the electrons carrying the current in the channel.

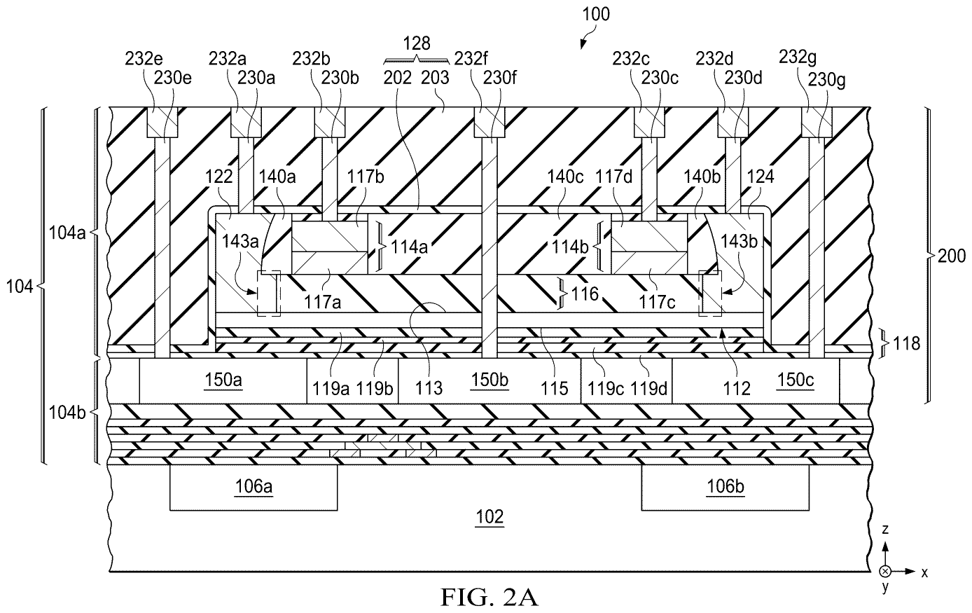

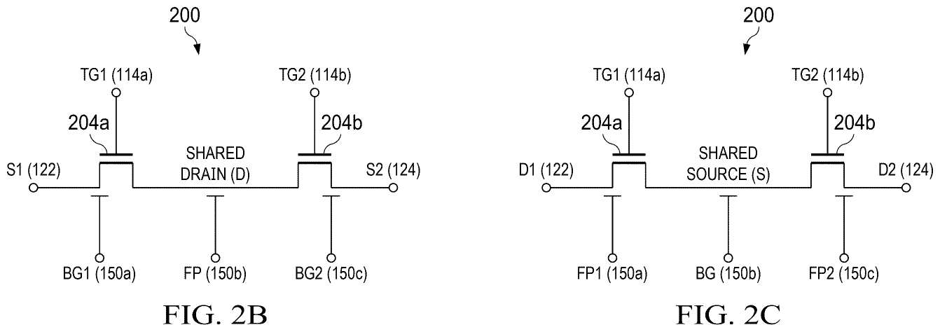

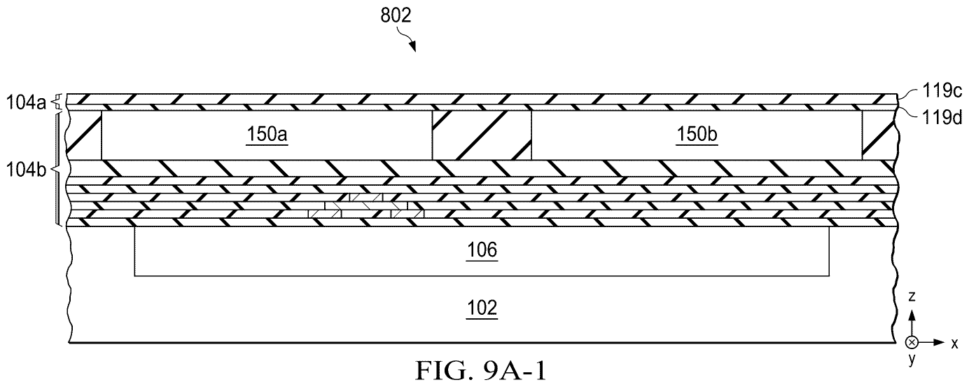

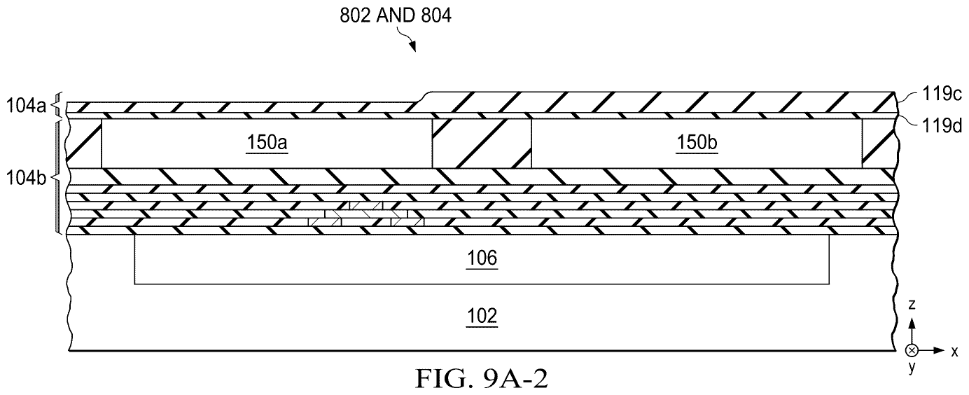

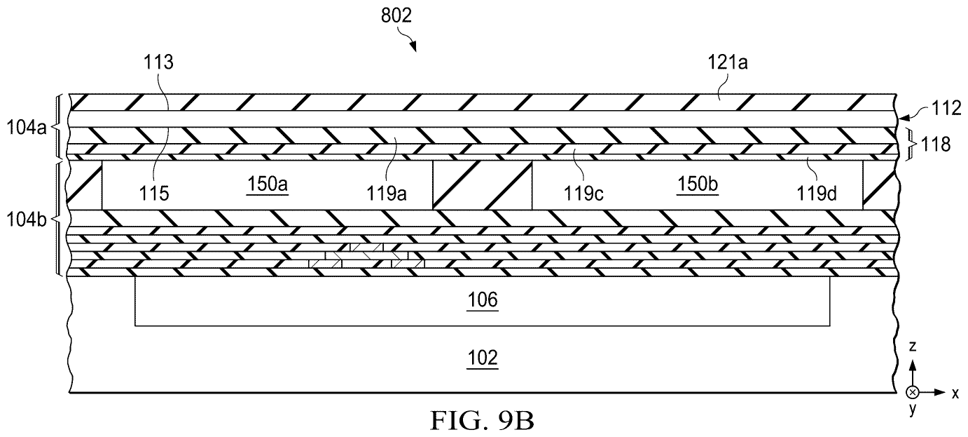

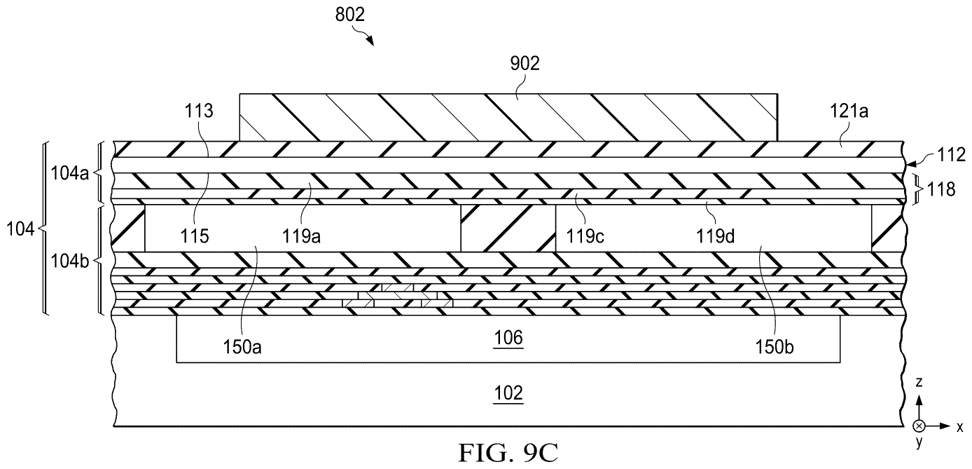

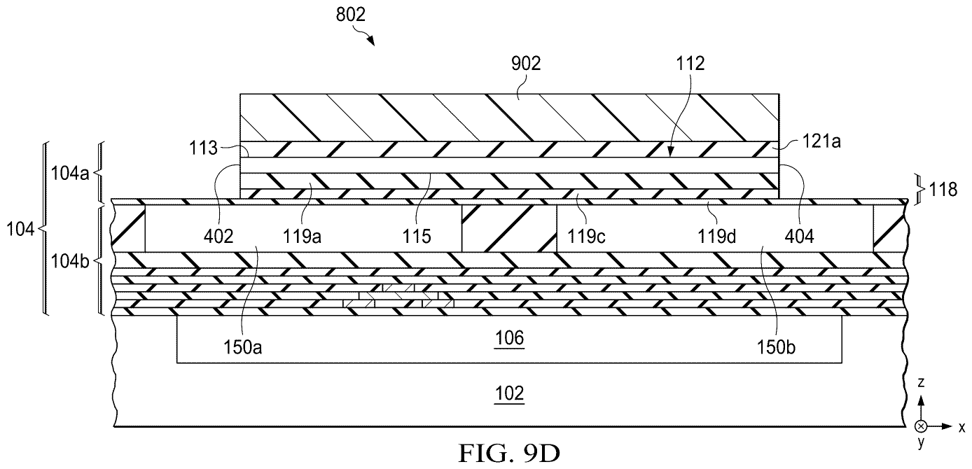

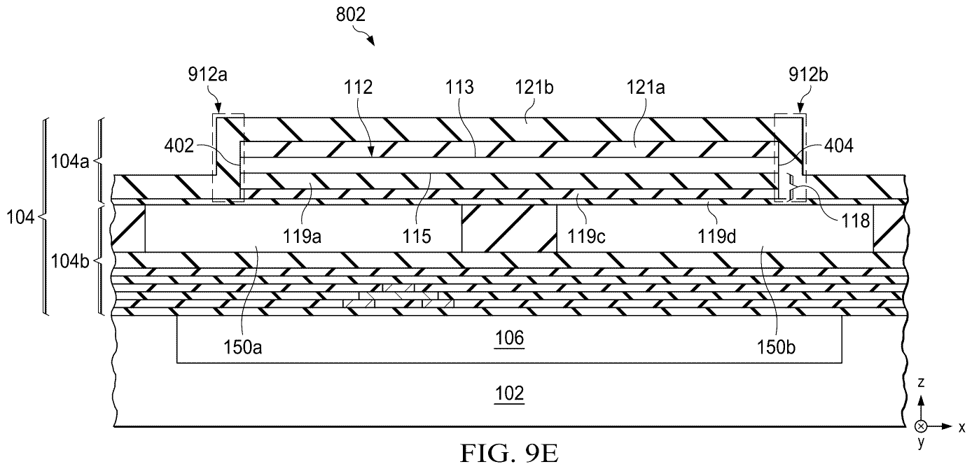

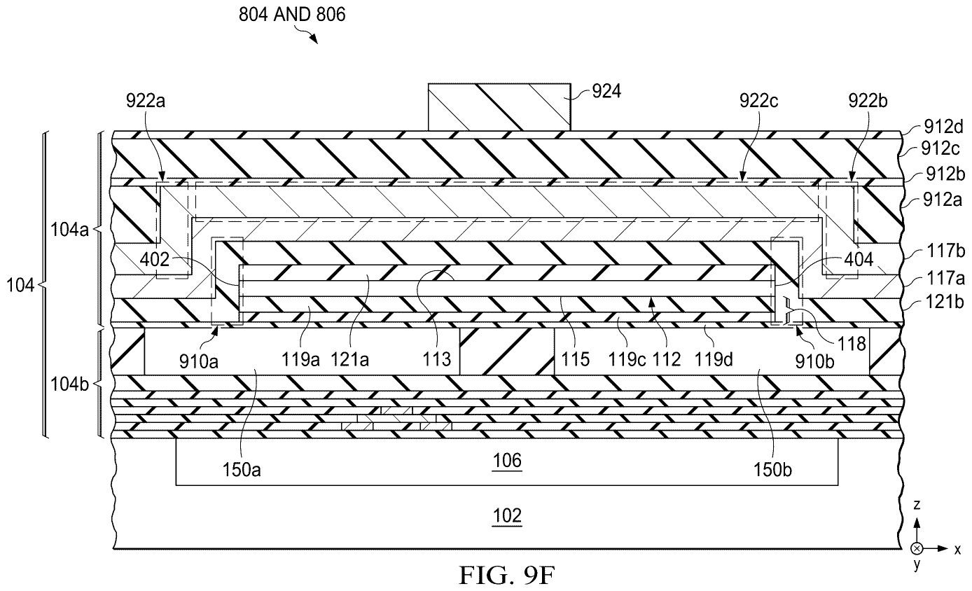

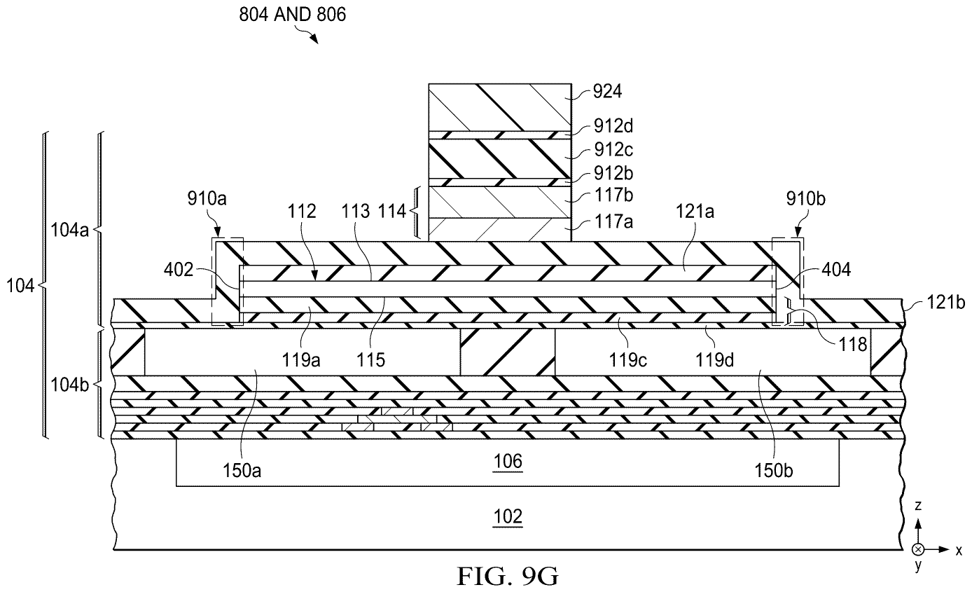

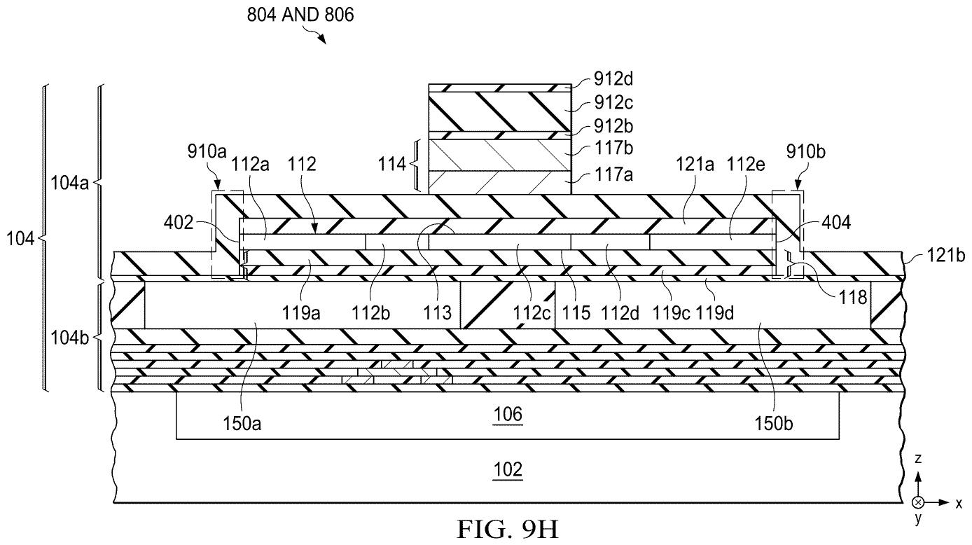

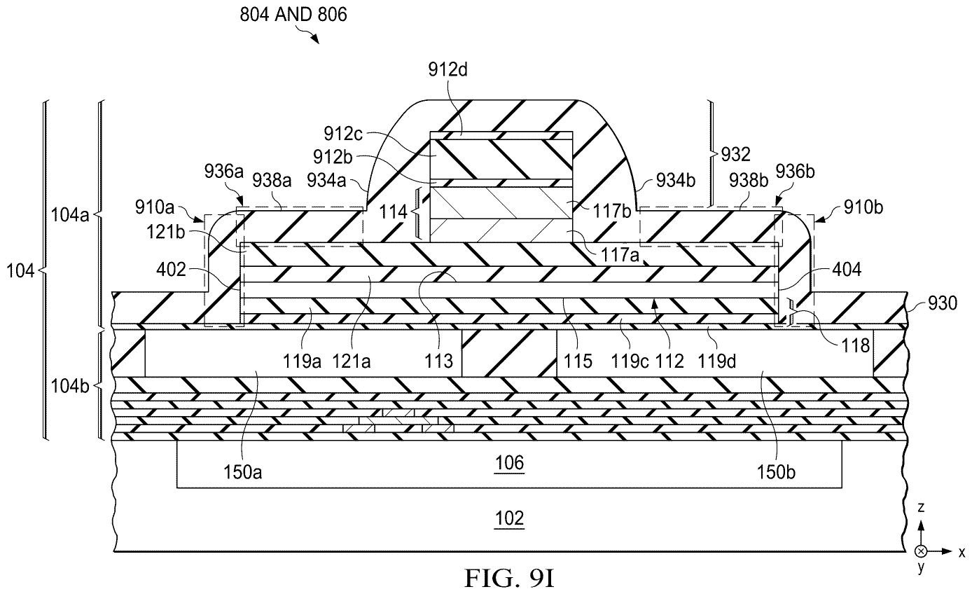

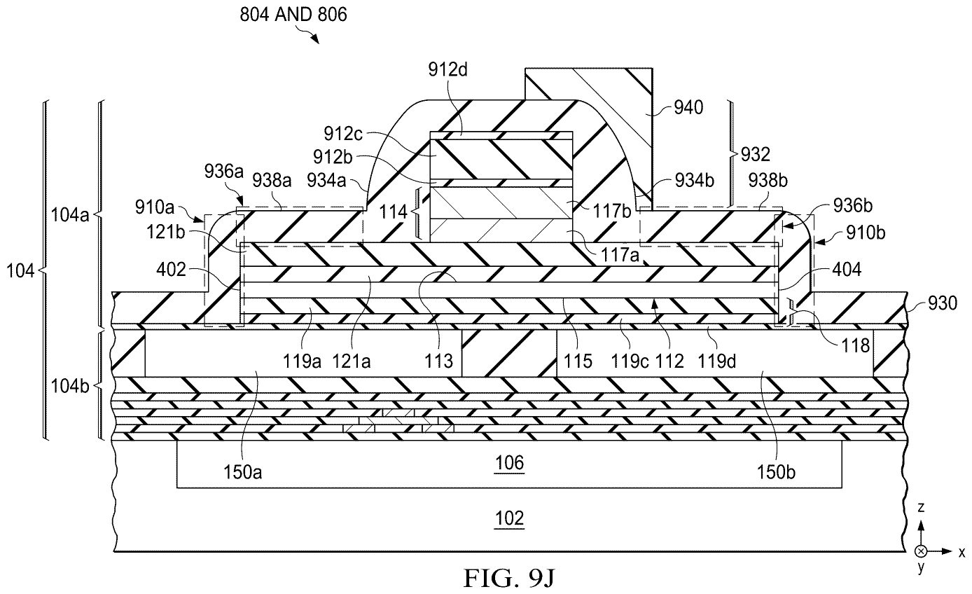

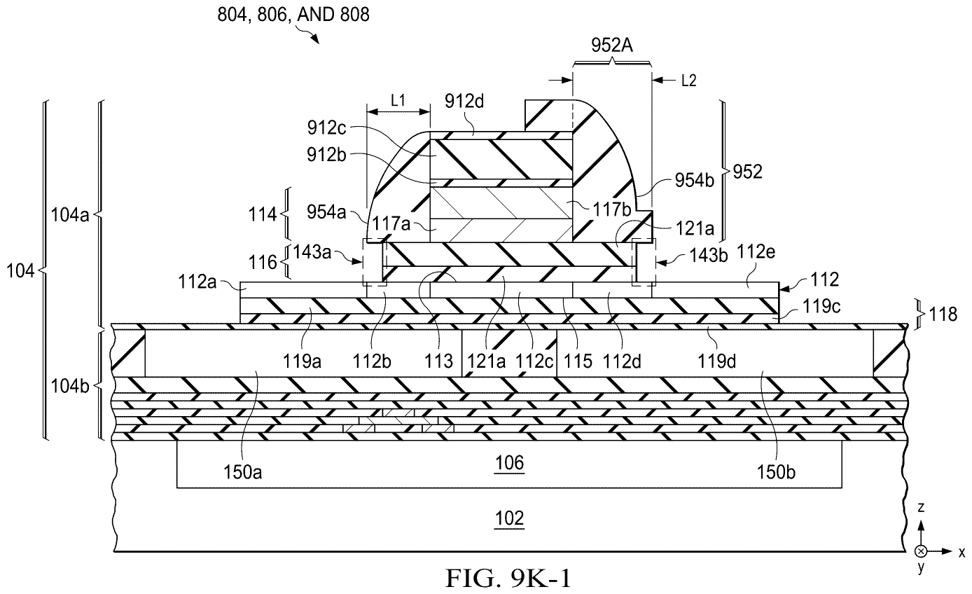

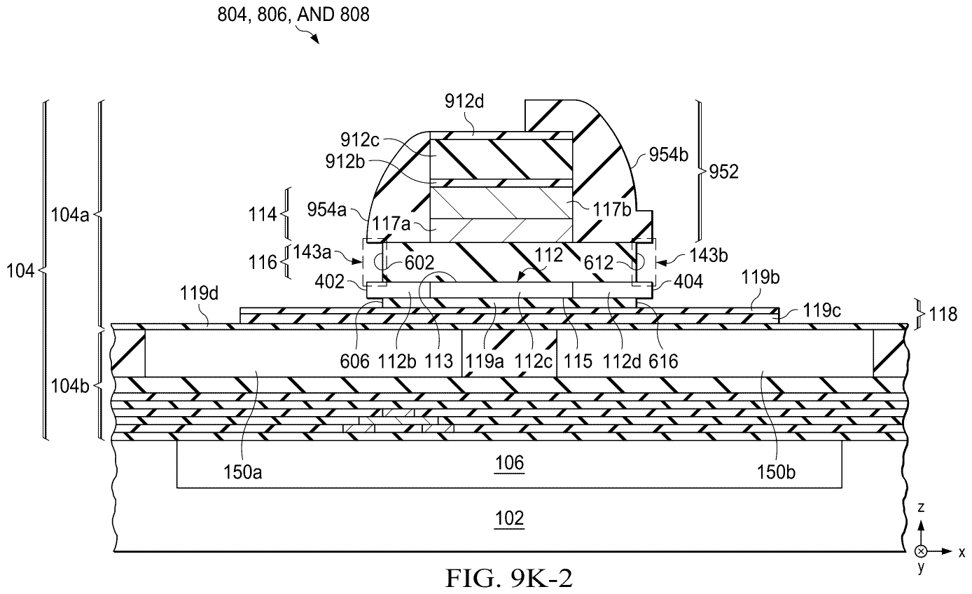

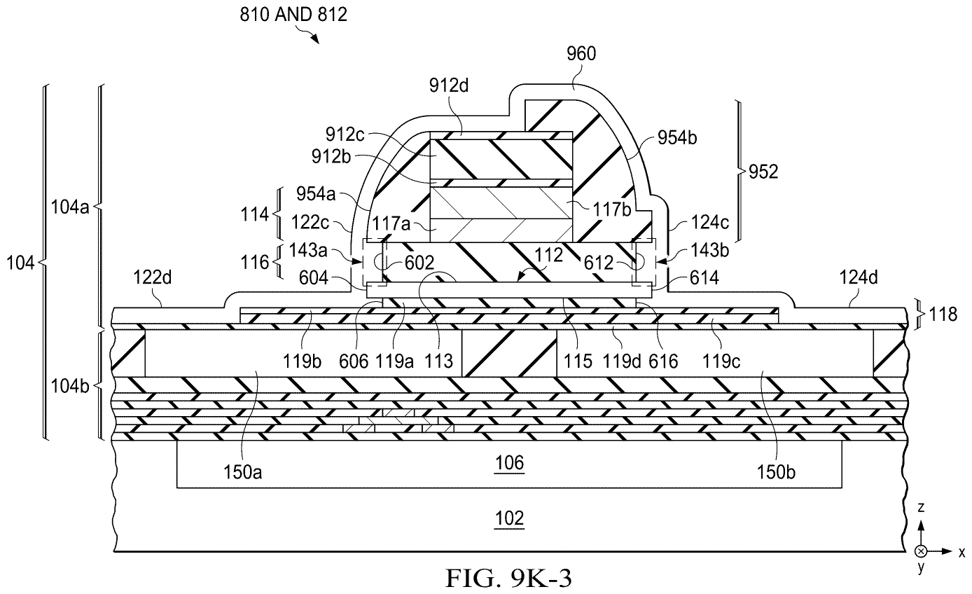

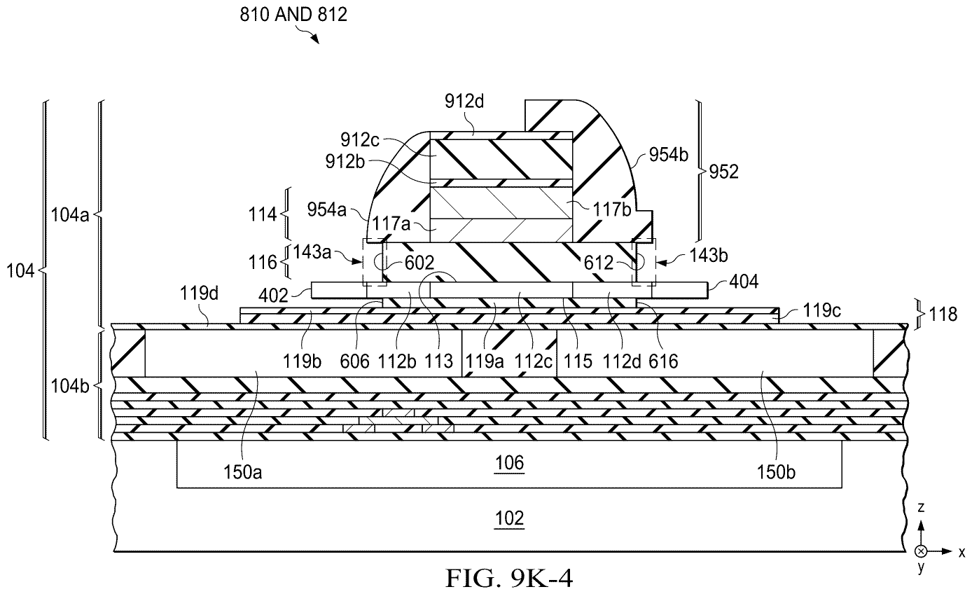

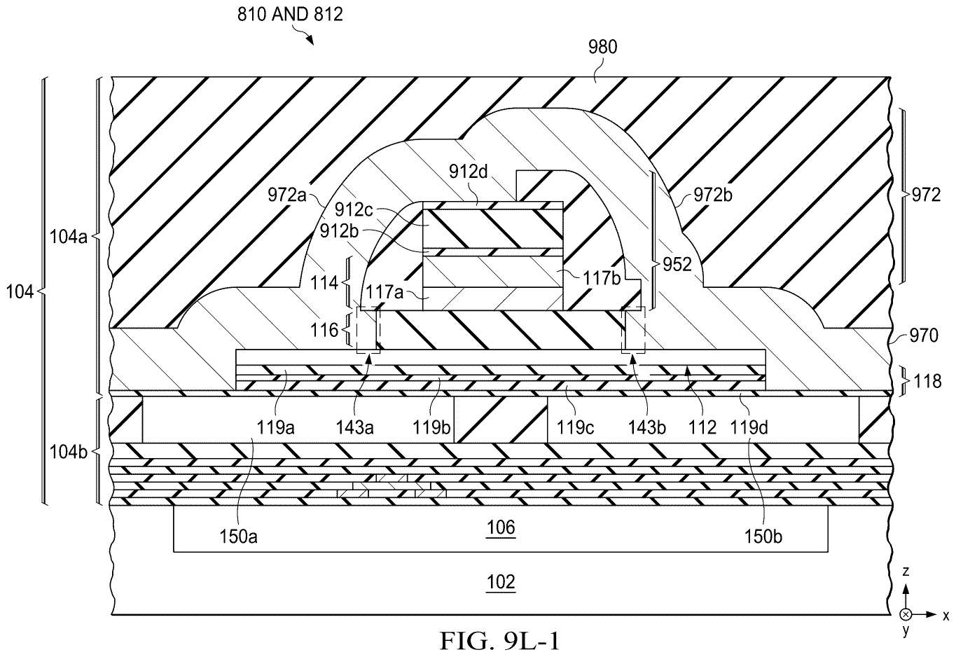

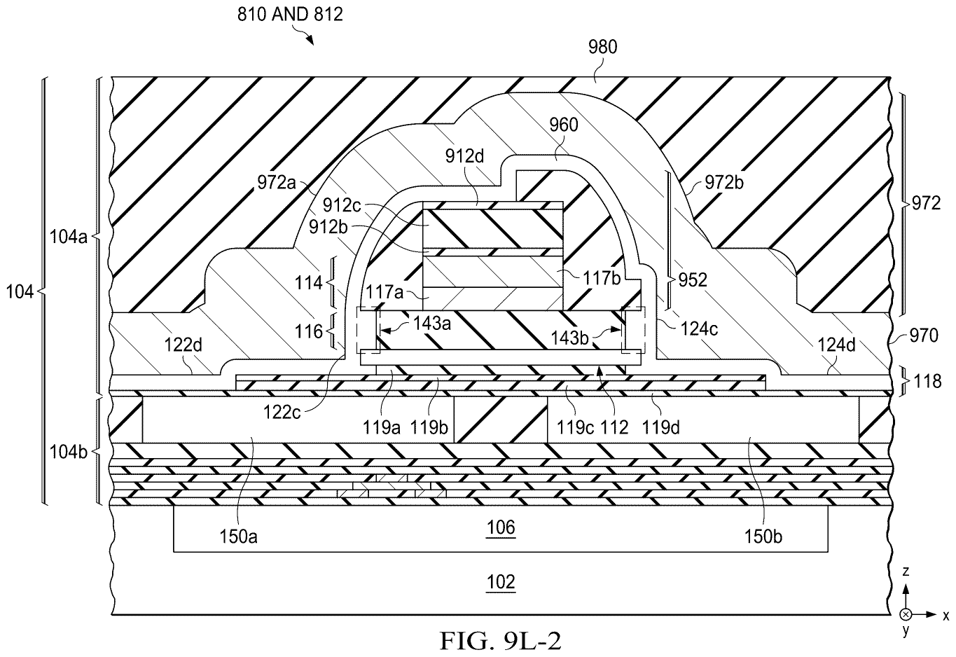

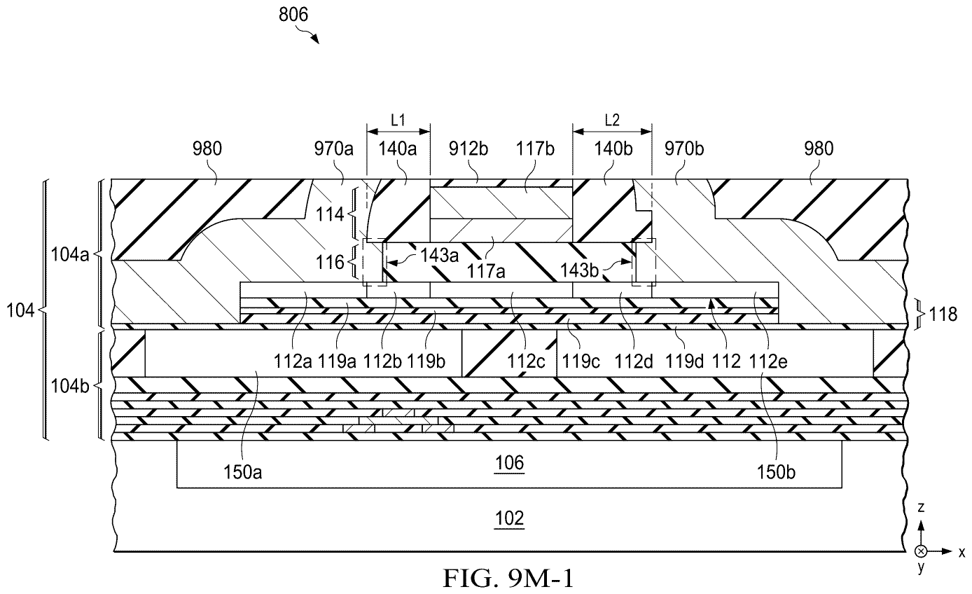

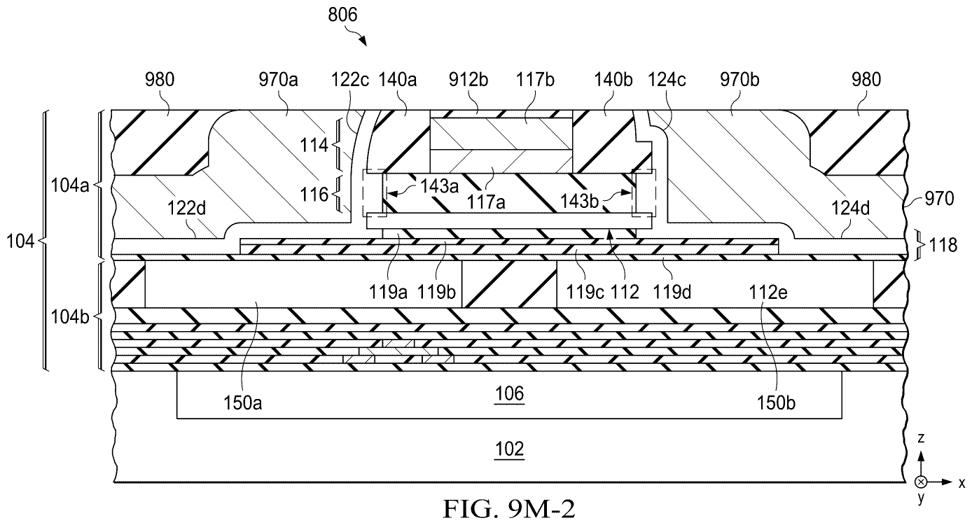

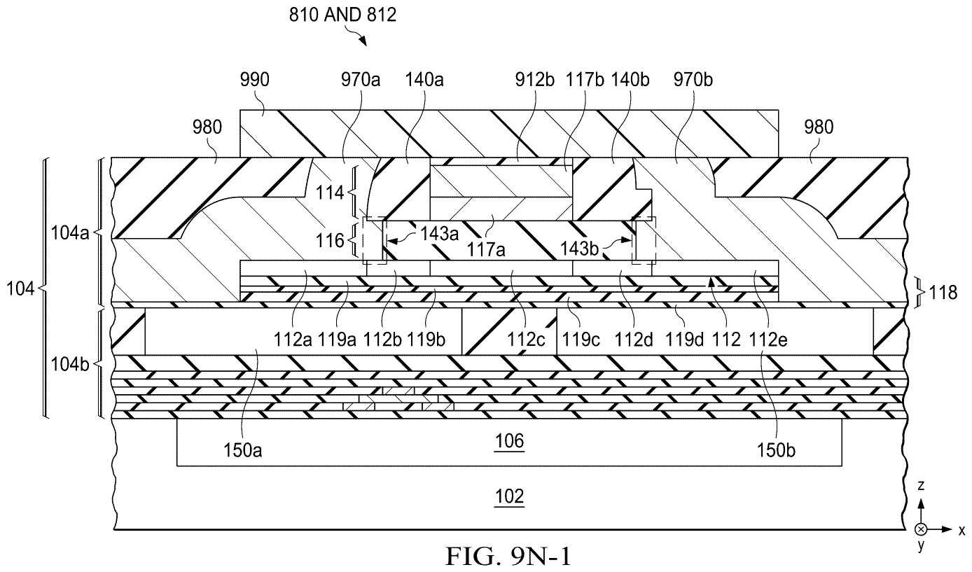

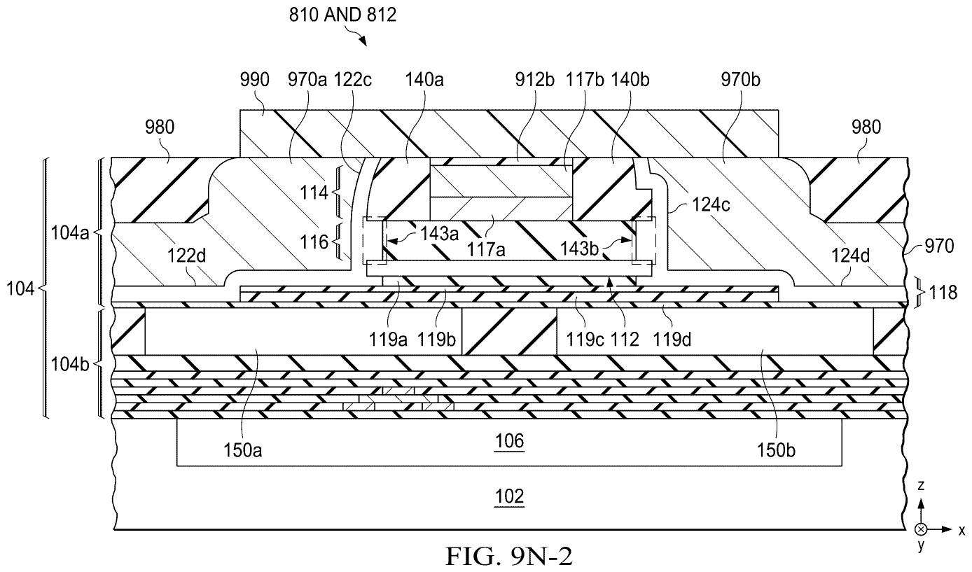

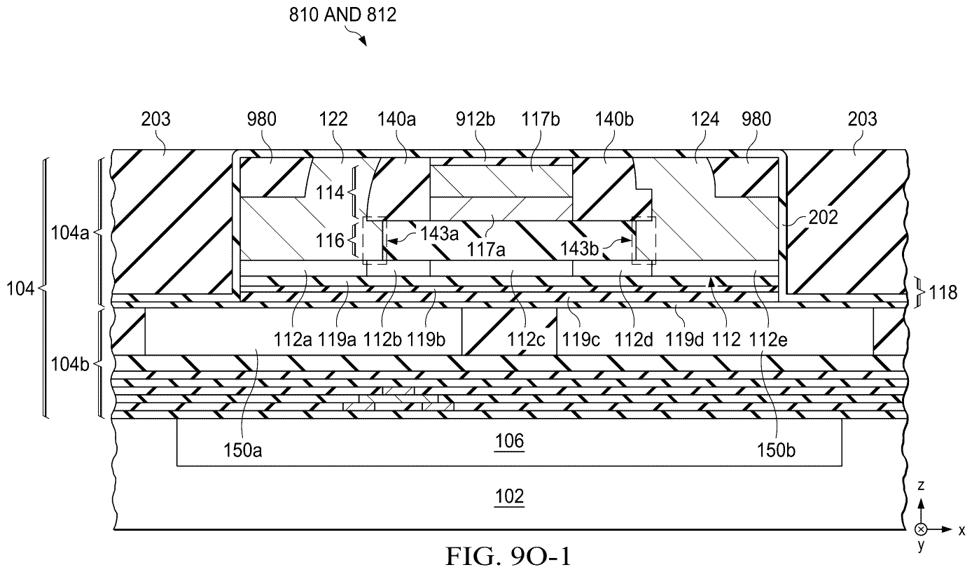

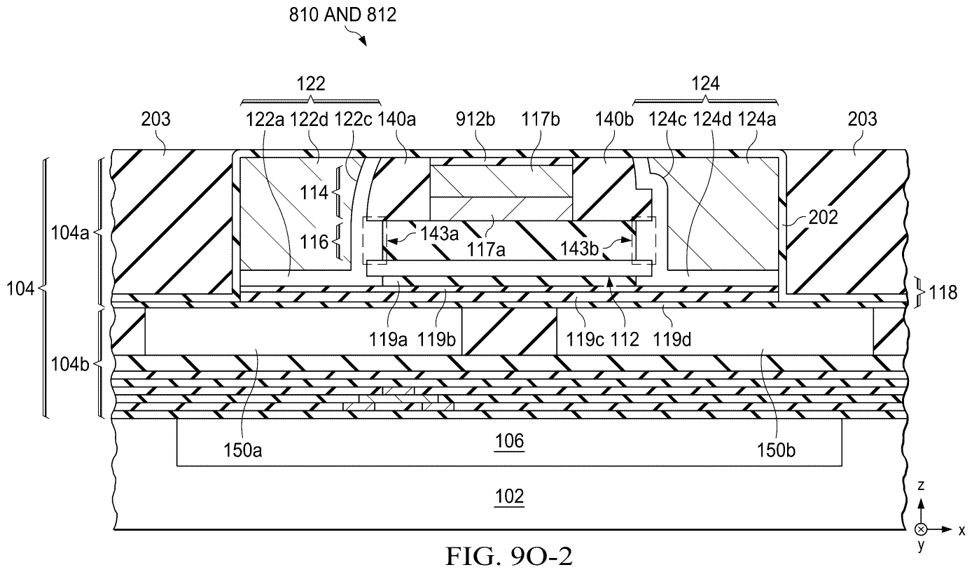

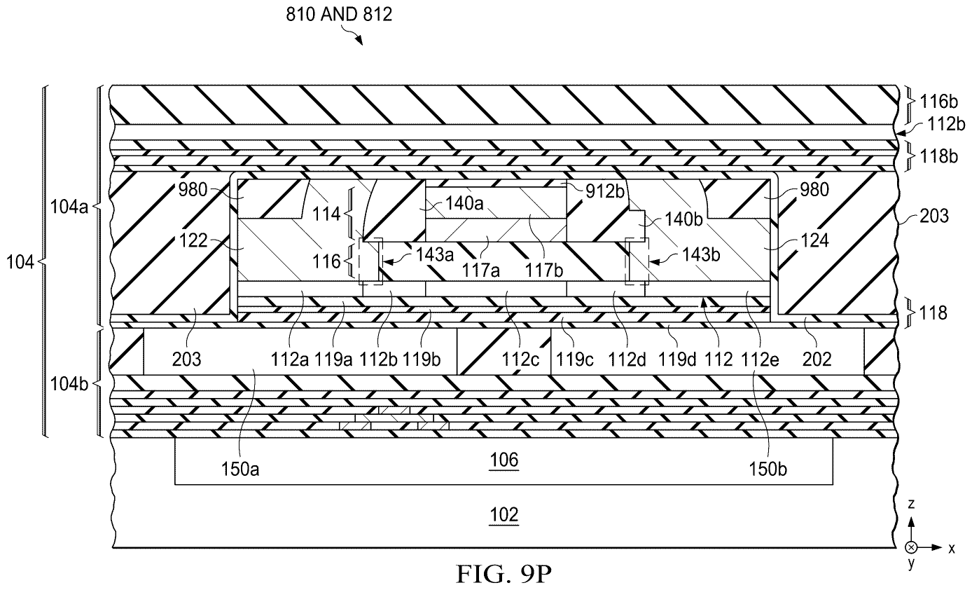

Also, dielectric structure 118 can also include one or more dielectric layers, such as 119a, 119b, 119c, and 119d shown in FIG. 1C. The dielectric layers include, for example, aluminum oxide (Al₂O₃), silicon oxide (SiO₂), silicon nitride (Si₃N₄), aluminum nitride (AlN), hexagonal boron nitride (hBN), amorphous BN, silicon carbonitride (SiCN), etc., to insulate channel layer 112 from other metal layers in metallization structure 104 below TFT 110, and can also act as a heat spreading layer to conduct heat away from channel layer 112. In some examples, dielectric structure 118 may provide a hydrogen diffusion barrier. Controlling the hydrogen content in channel layer 112 can improve the reliability and make the properties of channel layer 112 more consistent. In some examples, as to be described in FIGS. 4 and 5, some of dielectric layers 119 of dielectric structure 118 can be selectively etched to create step structures, which allow formation of edge contacts for current terminal 122 and current terminal 124. Also, in some examples, as to be described in FIG. 9A-2, one or more of dielectric layers 119 of dielectric structure 118 can have increased thickness under one of the current terminals 122 or 124 that receives a high voltage (e.g., the drain). Such arrangements can shape the electric field at the drain and increase the drain-source breakdown voltage (VDS) for a given channel length of the transistor. Further, dielectric structure 118 can provide a planar surface on which channel layer 112 is formed, which can ensure that at least the part of channel layer 112 under control terminal 114 is planar. Such arrangements can improve, for example, the uniformity of the threshold voltage for enabling a current channel across channel layer 112 under control terminal 114. The dielectric structures on top and bottom of the channel, 121 and 119 respectively, can also provide a lateral thermal diffusion of the heat developed in the channel, 112, to provide a heat sinking path towards current terminals 122 and 124 that can carry the heat though the metal structure to the external ambient to reduce thermal resistance of the channel, and also provide larger thermal capacitance to the channel generated heat. Further, one or more of dielectric structures 116 or 118 can include a material, such as Al₂O₃, that can provide a hydrogen barrier to facilitate control of the hydrogen content of channel layer 112, as described above.

Also, in the example shown in FIG. 1A, TFT 110 includes current terminals 122 and 124, and dielectric spacer structure 140 on side 113 of channel layer 112, where current terminal 122 and current terminal 124 are on at least two lateral sides (e.g., along the x/y axes) of dielectric structure 116 and dielectric spacer structure 140. Current terminals 122 and 124 can be electrically insulated from each other by dielectric spacer structure 140. One of the current terminals (e.g., current terminal 124) can be configured as a drain contact/terminal (D in FIG. 1D), and the other one of the current terminals (e.g., current terminal 122) can be configured as a source contact/terminal (S in FIG. 1D). Current terminals 122 and 124 and dielectric spacer structure 140 can be covered by a dielectric structure 128 of upper metallization structure 104a, which can include one or more dielectric layers. Current terminal 122 and current terminal 124 may include metal contacts (e.g., nickel (Ni), palladium (Pd), copper (Cu), tungsten (W), cobalt (Co), etc.) or a metal stack (e.g., stacks of Ni/Cu, Ni/Ti/W, Ni/Al, and a stack of A/B (e.g., a barrier layer metal and contact metal), where A can be TiN or TaN and B can be Ni, Cu, Al, or W) on first side 113 of channel layer 112. As to be described in FIGS. 4 and 5, current terminal 122 and current terminal 124 can include edge contacts that extend from side 113 to side 115 of channel layer 112 and abut dielectric structure 118. In some examples, the edge contacts can be metal terminals (e.g., Cu, Co, Ni). In some examples, as to be described in FIG. 6, the edge contacts can be hybrid contacts including a metal (e.g., Cu, W, Co, TiN, TaN, InSnO, and stacks of any combination of these materials) and the channel material. The edge contacts can shape the electric field around the drain and/source contacts, which can reduce peaking of the electric field and increase the breakdown voltage of the transistor when in the off-state, and reduce contact resistance. Upper metallization structure 104a also includes metal vias and external metal contacts, such as metal via 130a and metal contact 132a, metal via 130c and metal contact 132c, that are covered by dielectric structure 128 and coupled to, respectively, current terminal 122 and current terminal 124, to provide external access to the terminals.

In the example shown in FIG. 1A, dielectric spacer structure 140 can include dielectric spacers 140a and 140b that overhang and extend over, respectively, sides 141a and 141b of dielectric structures 116 and forming recesses 143a and 143b on side 113 of channel layer 112. In the example shown in FIG. 1A, recesses 143a and 143b can be filled by current terminals 122 and 124. As to be described below, dielectric structure 116, channel layer 112 (e.g., a metal oxide such as indium oxide), and dielectric structure 118 can be formed in situ (e.g., in the same vacuumed environment), to reduce/eliminate defects and contamination at the interfaces between channel layer 112 and each of dielectric structures 116 and 118. With such arrangements, the concentrations of defects/contaminations at the interfaces can be in the same order as the concentrations of defects/contamination at the channel layer and at the first and second dielectric structures. In contrast, in a case where the channel layer is not formed in situ with the first or second dielectric structures, the concentrations of defects/contaminations at the interfaces can be at least ten times of the concentrations of defects/contaminations at dielectric structures 116 and 118.

Part of the dielectric structure 116 is then etched with a mask (e.g., defined by dielectric spacer structure 140 or other masks), to expose channel layer 112, and to form the metal contacts of current terminals 122 and 124 that are in contact with the exposed channel layer. In some examples, the dielectric structures 116 and 118 and channel layer 112 can be formed by an atomic layer deposition (ALD) process, and channel layer 112 has a thickness in the order of nanometers (nm), such as 1-2 nm. In such examples, an isotropic wet etch operation can be performed to avoid etching through channel layer 112, and the wet etch operation may create undercuts in part of dielectric structure 116 below the dielectric structure, where the undercuts form recesses 143a and 143b.

TFT 110 also includes control terminal 150 on side 115 of channel layer 112 and in lower structure 104, where dielectric structure 118 is vertically between (e.g., along the z-axis of FIG. 1A) between control terminal 150 and channel layer 112 to provide electrical insulation. Control terminal 150 can be a gate terminal to control the on/off of TFT 110, and to control an amount of current that flows in the channel in channel layer 112 between current terminals 122 and 124 based on voltages at control terminal 150 and at current terminals 122 and 124, and also based on the threshold voltage of TFT 110. In the example of FIG. 1A, dielectric structures 116 and 118, channel layer 112, current terminals 122 and 124, and dielectric spacer structure 140 are in upper metallization structure, whereas control terminal 150 can be part of lower metallization structure 104b and can be coupled to active and/or passive FEOL circuitries in/on semiconductor substrate 102 (e.g., FEOL circuitries 106) via the metal interconnects (e.g., vias and metal layers) of the lower metallization structure.

In some example, as shown in FIG. 1B, TFT 110 may include a control terminal 114 on side 113 of channel layer 112. Control terminal 114 can be separated from current terminal 122 by dielectric spacer 140a that includes an overhang region) and separated from current terminal 124 by dielectric spacer 140b that includes another overhang region. Control terminal 114 can be configured as a top gate to control the on/off and current between current terminals 122/124 based on the voltages at the top gate, at current terminals 122/124, and the threshold voltage of TFT 110, as described above. TFT 110 can also include one or more control terminals 150 in lower structure 104b, such as control terminals 150a and 150b, on second side 115 of channel layer 112 and below current terminals 122 and 124 as shown in FIG. 1B. Upper metallization structure 104a may include additional metal interconnects, such as vias 130b, 130e, and 130d, and external contacts 132b, 132d, and 132e to provide external access to control terminals 114 and 150a and 150b.

In the example of FIG. 1B, control terminals 150 can be configured to tune various properties of TFT 110, such as the threshold voltage for formation of a channel in channel layer 112 and the breakdown drain-source voltage. For example, in a case where current terminal 122 is a source contact, second control terminal 150a can be on and overlap a region of channel layer 112 between current terminal 122 and control terminal 114 and is configured as a bottom gate (BG in FIG. 1D), while control terminal 114 is configured as a top gate (TG in FIG. 1D). Second control terminal 150a can receive a voltage from contact 132d and set the threshold voltage for channel formation based on the voltage, while control terminal 114 can enable the formation of the channel in channel layer 112 when the voltage at control terminal 114 (the gate voltage) exceeds the threshold voltage set by second control terminal 150a. Also, in a case where current terminal 124 is a drain contact, second control terminal 150b can be on and overlap a region of channel layer 112 between current terminal 124 and control terminal 114 and is configured as a field plate (FP in FIG. 1D). The field plate can receive a voltage to adjust the electric field distribution along part of the channel layer 112 laterally between control terminal 114 (gate) and current terminal 124 (drain) when the channel is disabled/off, which can increase the breakdown drain-source voltage of TFT 110.

Control terminals 150 allow formation of a transistor with multiple control terminals that allow static/dynamic tuning of various properties, such as charge density, on-resistance, and breakdown voltage of the transistor when the transistor is off, etc. The static tuning can be performed to track the process or a relatively static operation condition (e.g., temperature and voltage) of TFT 110. The dynamic tuning can be performed to track a relatively dynamic operation condition (e.g., changes in load condition, operation frequency, etc.). All these allow the transistor to be configured/adapted, using control signals, to support a wide range of applications, such as power converters operating in high voltage domains, communication circuits high frequency/speed applications, etc.

In some examples, as shown in FIG. 1C, a control terminal (e.g., control terminals 114 or 150) of TFT 110 can include a stack of two layers 117a and 117b of different metals. In FIG. 1C, layer 117b abuts metal via 130b and can provide improved electrical connection to metal via 130b. Layer 117b can include, for example, copper (Cu), cobalt (Co), tungsten (W), etc. Also, layer 117a is vertically between layer 117b and dielectric structure 116 and can set the threshold voltage of transistor. Layer 117a can include a high work function metal (e.g., a noble metal) or a metal oxide, such as Pt, Pd, Ir, IrOx, Rh, Re, Ru, RuO₂. Layer 117a can have a thickness of, e.g., 3-30 nm, with a work function of, e.g., 4.8-5.6 eV, to effectively control the channel formation in channel layer 112 and achieve a positive threshold voltage desired for a TFT.

Also, in some examples, in shown in FIG. 1C, at least one of dielectric spacers 140a or 140b have a sub-lithography lateral thickness Ls (e.g., along the x/y axes), where the lateral thickness is smaller than a minimum dimension allowed by the lithography process used in fabricating TFT 110, to reduce the parasitic capacitance (e.g., C_{off}) of the transistor for high frequency applications (e.g., radio-frequency (RF) applications), and/or to allow the source to be optimized for improved on-state current (Iₒₙ) over off-state current (I_{off}) ratio. For example, as shown in FIG. 1B, in a case where control terminal 114 is patterned to have a minimum channel length Lc (along an axis between the source and drain) allowed by the lithography process, at least one of dielectric spacers 140a/140b can have a lateral thickness Ls that is smaller than the channel length Lc.

Further, in some examples, as shown in FIG. 1C, dielectric spacers 140a and 140b can have different lateral thicknesses to enhance the tolerance of high drain/source voltages by the transistor for high voltage application. For example, in a case where current terminal 124 is configured as a drain contact and current terminal 122 is configured as a source contact, dielectric spacer 140b can have a larger lateral thickness Ls1 than the lateral thickness Ls of dielectric spacer 140a. Dielectric spacer 140b can include a drain extension to increase the separation between the drain contact and the gate to accommodate a large lateral electric field between drain and source, thereby reducing the voltage drop between drain and source and increase the drain-source breakdown voltage.

Also, in the example shown in FIG. 1C, channel layer 112 may include a region 112a interfacing current terminal 122, a region 112b under dielectric spacer 140a, a region 112c under control terminal 114, a region 112d under dielectric spacer 140b, and a region 112d under current terminal 124. In a case where channel layer 112 includes SWCNTs, regions 112a and 112e can be treated (e.g., a oxygen, nitrogen, inert gas and/or hydrogen plasma treatment) to introduce defects to the carbon nanotubes in the regions to improve contact between the current terminals and the carbon nanotubes, which can reduce contact resistance. The carbon nanotubes in region 112c under control terminal 114 can be masked/protected from the plasma treatment by, for example, the hydrogen barrier material (e.g., Al₂O₃) in dielectric structures 116 and/or 118, to improve charge mobility. Also, the oxide charge of the SWCNTs in regions 112b and 112d under the dielectric spacers can be controlled to improve the Iₒₙ/I_{off} ratio. Also, in a case where the charge layer includes a metal oxide material, such as indium oxide (e.g., In₂O₃, InGaO, InSnO, InGaZnO or others as previously mentioned), the oxygen vacancy (or doping content) of regions 112a and 112e can be adjusted through, for example, annealing, metal oxide reducing processes, metal choice for the metal oxide material, etc., to reduce contact resistance. Also, the oxygen vacancy (or doping content) of region 120c under the first control terminal (e.g., gate) can be adjusted to improve charge mobility through, for example, an oxidation process, introduction of hydrogen, etc., to charge compensate the oxygen vacancies. For example, annealing at BEOL compatible temperatures (<450 C) with one or more of the contact metals (e.g., cobalt (Co), nickel (Ni), molybdenum (Mo), titanium (Ti), tantalum (Ta), gallium (Ga), zinc (Zn), etc.) can be performed to share the oxygen already present and produce a low contact resistance. Further, the oxygen vacancy (or doping content) of region 120b under dielectric spacer 140a between the source (e.g., current terminal 122) and control terminal 114 can be adjusted to reduce I_{off}. Also, the oxygen vacancy (or doping content) of region 120d under dielectric spacer 140b between the drain (e.g., second current terminal 14) and control terminal 114 can also be adjusted to increase the drain-source breakdown voltage of TFT 110 when the transistor is in the off state.

FIG. 2A illustrates cross sections of an example of a semiconductor device 100 including a thin film bidirectional switch 200. Bidirectional switch 200 can be BEOL devices and can be in or on metallization structure 104 on semiconductor substrate 102, which can include active and/or passive FEOL circuitries 106a and 106b such as transistors, resistors, capacitors, STI, etc. In the examples shown in FIG. 2A, bidirectional switch 200 may include, in upper metallization structure 104a, channel layer 112, first control terminals 114a and 114b, dielectric structure 116, current terminal 122, current terminal 124, and dielectric structure 118. Bidirectional switch 200 may also include, in lower metallization structure 104b, control terminals 150a, 150b, and 150c. In the examples of FIG. 2A, first control terminals 114a and 114b, dielectric structure 116, current terminal 122, and current terminal 124 are on first side 113 of dielectric structure 116, with first control terminals 114a and 114b laterally between current terminal 122 and current terminal 124. Bidirectional switch 200 also includes dielectric spacer 140a laterally between current terminal 122 and control terminal 114a, dielectric spacer 140b laterally between current terminal 124 and control terminal 114b, and a dielectric spacer 140c laterally between first control terminals 114a and 114b. In the examples of FIG. 2A, control terminal 114a includes a stack of two layers 117b and 117a of different metals/metal oxides, and control terminal 114b includes a stack of two layers 117c and 117d of different metals (e.g., high work function metal/metal oxide for 117a/117c, copper/tungsten/cobalt for 117b/117d). In some examples, dielectric spacer 140a can overhang over dielectric structure 116 and form recess 143a on side 113 of channel layer 112, and dielectric spacer 140b can overhang over another side of dielectric structure 116 and form recess 143b on side 113 of channel layer 112, in a case where dielectric structures 116 and 118 and channel layer 112 are formed in situ and wet etching is performed to etch dielectric structure 116 to avoid etching into channel layer 112, as described above.

Current terminal 122, current terminal 124, first control terminals 114a and 114b, and dielectric spacers 140a, 140b, and 140c can be covered by dielectric structure 128 of upper metallization structure 104a including one or more dielectric layers. In some examples, dielectric structure 128 includes a dielectric layer 202, which can be Si₃N₄ or an etch stop layer. Dielectric layer 202 can cover and seal/insulate current terminal 122, current terminal 124, control terminals 114a and 114b, and channel layer 112 from different sides. In some examples, dielectric layer 202 can be formed to protect the terminals from the etching during the subsequent fabrication operation of metal vias and external metal contacts. Dielectric structure 128 also includes one or more dielectric layers 203 (e.g., SiO₂) on dielectric layer 202. Upper metallization structure 104a also includes the metal vias and external metal contacts, such as a metal via 230a and a metal contact 232a, a metal via 230b and a metal contact 232b, a metal via 230c and a metal contact 232c, and a metal via 230d and a metal contact 230d, all of which are covered by dielectric layer 203. Metal via 230a and metal contact 232a are coupled to current terminal 122. Metal via 230b and metal contact 232b are coupled to control terminal 114a. Metal via 230c and metal contact 232c are coupled to control terminal 114b. Metal via 230d and metal contact 232d are coupled to current terminal 124.

Also, dielectric structure 118 is on second side 115 of channel layer 112. Bidirectional switch 200 may also include control terminals 150a, 150b, and 150c on second side 115 of channel layer 112, where dielectric structure 118 is vertically between channel layer 112 and control terminals 150a-c to provide insulation. Second control terminal 150a can overlap a part of channel layer 112 between current terminal 122 and control terminal 114a, second control terminal 150b can overlap a part of channel layer 112 between first control terminals 114a and 114b, and second control terminal 150c can overlap a part of channel layer 112 between current terminal 124 and control terminal 114b. In the example of FIG. 2A, control terminals 150a-c are metal terminals and can be part of lower metallization structure 104b. Upper metallization structure 104a also includes metal interconnects including metal vias and external metal contacts, such as a metal via 130e and a metal contact 232e, a metal via 230f and a metal contact 232f, and a metal via 230g and a metal contact 232g coupled to, respectively, control terminals 150a, 150b, and 150c to provide external access to the terminals.

FIGS. 2B and 2C illustrate examples of circuit schematic representations of bidirectional switch 200. Referring to FIG. 2B, bidirectional switch 200 can include two transistors 204a and 204b coupled in series together and sharing a common drain (D in FIG. 2B). Current terminal 122 can be configured as a source terminal (S1 in FIG. 2B) of transistor 204a, which has control terminal 114a configured as a top gate (TG1 in FIG. 2B) and second control terminal 150a configured as a bottom gate (BG1 in FIG. 2B). Also, current terminal 124 is configured as a source terminal (S2 in FIG. 2B) of transistor 204b, which also has control terminal 114b configured as a top gate (TG2 in FIG. 2B) and second control terminal 150c configured as a bottom gate (BG2 in FIG. 2B). Bidirectional switch 200 also includes second control terminal 150b configured as a field plate (FP in FIG. 2B).

In FIG. 2B, bidirectional switch 200 is enabled when both transistors 204a and 204b are enabled, and is disabled when one or more of transistors 204a and 204b are disabled. Transistor 204a is enabled when the gate-source voltage of transistor 204a, between TG1 and S1, exceeds a first threshold voltage Vt1 of transistor 204a. Transistor 204b is enabled when the gate-source voltage of transistor 20ba, between TG2 and S2, exceeds a second threshold voltage Vt2 of transistor 204b. Bottom gate BG1 (second control terminal 150a) can receive a first voltage and set the first threshold voltage Vt1 of transistor 204a based on the first voltage, while bottom gate BG2 (second control terminal 150c) can receive a voltage and set the second threshold voltage Vt2 of transistor 204b based on the second voltage. Field plate FP (second control terminal 150c) can receive a third voltage and adjust the electric field distribution along channel layer 112, including the parts of channel layer 112 between the shared drain D and each of first control terminals 114a/114b, to increase the breakdown voltage of bidirectional switch 200.

FIG. 2C illustrates another example of circuit schematic representation of bidirectional switch 200. Referring to FIG. 2C, bidirectional switch 200 can include two transistors 204a and 204b coupled in series together and sharing a common source (S in FIG. 2C). Current terminal 122 can be configured as a drain terminal (D1 in FIG. 2C) of transistor 204a, which has control terminal 114a configured as a top gate (TG1 in FIG. 2C) and second control terminal 150a configured as a field plate (FP1 in FIG. 2C). Also, current terminal 124 is configured as a drain terminal (D2 in FIG. 2C) of transistor 204b, which also has control terminal 114b configured as a top gate (TG2 in FIG. 2C) and second control terminal 150c configured as a field plate (FP2 in FIG. 2C). Bidirectional switch 200 also includes second control terminal 150b configured as a common bottom gate of transistors 204a and 204b (BG in FIG. 2C).

In FIG. 2C, bidirectional switch 200 is enabled when both transistors 204a and 204b are enabled, and is disabled when one or more of transistors 204a and 204b are disabled. Transistor 204a is enabled when the gate-source voltage of transistor 204a, between TG1 and S, exceeds a common threshold voltage Vt shared by transistors 204a and 204b. Transistor 204b is enabled when the gate-source voltage of transistor 20ba, between TG2 and S, exceeds the common threshold voltage Vt. Bottom gate BG (second control terminal 150b) can receive a first voltage and set the common threshold voltage Vt of transistors 204a and 204b based on the first voltage. First field plate FP1 (second control terminal 150a) can receive a second voltage and adjust the electric field distribution along channel layer 112, including a part of channel layer 112 overlapping between drain D1 and top gate TG1, to increase the breakdown voltage of transistor 204a. Also, second field plate FP2 (second control terminal 150c) can receive a third voltage and adjust the electric field distribution along channel layer 112, including a part of channel layer 112 overlapping between drain D2 and top gate TG2, to increase the breakdown voltage of transistor 204b.

FIG. 3 illustrates additional examples of semiconductor device 100 including TFT 110. In the examples of FIG. 3, TFT 110 includes dielectric layer 202 covering current terminal 122, control terminal 114, and current terminal 124. In the examples of FIG. 3, the metal contacts of current terminal 122 and current terminal 124 are on first side 113 of channel layer 112. As described above, dielectric layer 202 can include Si₃N₄ or an etch stop layer to further insulate the metals of current terminal 122, current terminal 124, and control terminal 114, and to protect the terminals from subsequent etching during the fabrication operation of TFT 110. Also, in the examples of FIG. 3, current terminal 124 is configured as a drain contact, current terminal 122 is configured as a source contact, and dielectric spacer 140b can have a longer lateral length than dielectric spacer 140a to accommodate a large lateral electric field between drain and source and increase the drain-source breakdown voltage. Dielectric spacer 140a forms recess 143a over a side of dielectric structure 116 on side 113 of channel layer 112, and dielectric spacer 140b forms recess 143b over another side of dielectric structure 116 on side 113 of channel layer 112, in a case where dielectric structures 116 and 118 and channel layer 112 are formed in situ and wet etching is performed to etch dielectric structure 116 to avoid etching into channel layer 112, as described above.

FIG. 4A and FIG. 4B illustrate additional examples of cross sections of semiconductor device 100 including TFT 110 having current terminal 122 and current terminal 124 as metallic edge contacts. In the examples of FIG. 4A, the metal (e.g., copper, cobalt, tungsten, or other metals) of current terminal 122 extends from first side 113 of channel layer 112, around the edges of a third side 402 of channel layer 112, into second side 115 of channel layer 112, forming an edge contact. Also, the metal of current terminal 124 extends from first side 113 of channel layer 112, around the edges of a fourth side 404 of channel layer 112 opposing third side 402, into second side 115 of channel layer 112, and forming another edge contact. Sides 402 and 404 are angled from (e.g., orthogonal to) sides 113 and 115. The edge contacts can shape the voltage potential around the drain and/source contacts, making the electric field (voltage potential gradient) more uniform to the channel layer around the drain and/source contacts, which can reduce peaking of the electric field and increase the breakdown voltage of the transistor when in the off-state, and reduce contact resistance, as already described in prior paragraphs.

To enable fabrication of edge contacts, dielectric structure 118 can include dielectric layers of different materials having different etch selectivities. For example, dielectric structure 118 may include a dielectric layer 119a made of Al₂O₃, a dielectric layer 119b made of SiO₂, and a dielectric layer 119c configured as a metal seal/etch stop layer and may include silicon carbonitride (SiCN). As to be described below, some of the dielectric layers, such as dielectric layers 119a and 119b, can have different dielectric materials or otherwise have different etch selectivities, which allow forming a step structure in dielectric structure 118 to support formation of edge contacts. For example, during fabrication, part of dielectric layer 119a below channel layer 112 are etched/removed, to allow the metal of current terminal 122 and current terminal 124 to extend from first side 113 to second side 115 of channel layer 112, and on dielectric layer 119c (or dielectric layer 119b). Meanwhile, dielectric layers 119b, 119c, and 119d are not etched (or etched to a less extent), which can separate and electrically insulate current terminal 122 and current terminal 124 from lower metallization structure 104b, and provide a heat spreading layer to conduct heat away from channel layer 112 to lower metallization structure 104b.

FIG. 4B illustrates another example of TFT 110 having current terminal 122 and current terminal 124 as metallic edge contacts. As shown in FIG. 4B, TFT 110 can include a vertical stack (e.g., along the z-axis in FIG. 4B) of channel layers 112_0 and 112_1. TFT 100 also includes dielectric structure 118a, which can be an example of dielectric structure 118a in FIG. 4A and in other figures and include dielectric layers 119a-a, 119c-a, and 119d-a, is on side 115a of channel layer 112_0. Also, TFT 100 includes dielectric structure 116a and control terminal 114a (which can include layers 117a-a and 117b-a) on side 113a of channel layer 112_0, with dielectric structure 116a between control terminal 114a and channel layer 112_0, and dielectric spacers 140a and 140b on at least two opposing sides of control terminal 114a.

Further, TFT 100 may include a dielectric structure 118b on side 115b of channel layer 112_1 and between channel layer 112_1 and control terminal 114a and dielectric spacers 140a and 140b. TFT 100 includes dielectric structure 116b and control terminal 114b (which can include layers 117a-b and 117b-b) on side 113b of channel layer 112_1, with dielectric structure 116b between control terminal 114b and channel layer 112_1, and dielectric spacers 140c and 140d on at least two opposing sides of control terminal 114b. Control terminals 114a and 114b are electrically coupled by, for example, vias or other metal interconnect structures not shown in FIG. 4B, and can share a common gate voltage, and channel layers 112_0 and 112_1 are controlled by that common gate voltage at control terminals 114a and 114b.

Also, TFT 100 may include current terminals 122 and 124. Current terminal 122 can include multiple metallic edge contacts joined together, where the metallic edge contacts wrap around edges of end 402b of channel layer 112_1 and end 402a of channel layer 112_0. Also, current terminal 124 can include multiple metallic edge contacts joined together, where the metallic edge contacts wrap around edges of end 404b of channel layer 112_1 and end 404a of channel layer 112_0.

With the arrangements of FIG. 4B, current can flow between current terminals 122 and 124 via the multiple channel layers, which can increase the effective channel width and reduce the on-resistance of TFT 110, while maintaining the same (or very similar) footprint/area as a TFT with a single channel layer. As to be described below, additional channel layers can be formed by repeating the layer deposition and patterning processes for each channel layer, which can reduce the cost and complexity of the additional fabrication process involved in increasing the effective transistor channel width.

FIG. 5 illustrates additional examples of cross sections of semiconductor device 100 including TFT 110 having current terminal 122 and current terminal 124 as hybrid edge contacts, where the hybrid edge contact includes a metal portion (e.g., copper, tungsten, cobalt, or other metals) and a channel layer portion including the channel material (e.g., a metal oxide material, carbon nanotubes, etc.). In the examples of FIG. 5, current terminal 122 includes a metal portion 122a and a channel layer portion 122b, and current terminal 124 includes a metal portion 124a and a channel layer portion 124b. Metal portion 122a of current terminal 122 also extends from first side 113 of channel layer 112, around third side 402 of channel layer portion 122b, into second side 115 of channel layer 112, forming part of a hybrid edge contact. Channel layer portion 122b extends laterally from channel layer 112 into current terminal 122 and terminates at side 402, with at least part of channel layer portion 122b overlapping with metal via 130a. Also, metal portion 124a of current terminal 124 extends from first side 113 of channel layer 112, around fourth side 404 of channel layer portion 124b opposing side 402, into second side 115 of channel layer 112, and forming part of a hybrid edge contact. Channel layer portion 124b extends laterally from channel layer 112 into current terminal 124 and terminates at side 404, with at least part of channel layer portion 124b overlapping with metal via 130c.

In examples where channel layer 112 includes SWCNT, channel layer portions 122b and 124b can be formed by a SWCNT regrowth process using, for example, using a metal catalyst with PECVD using a hydrocarbon gas flow at BEOL thermal budgets as described before. The extension of channel layer 112 into edge contacts can also shape the electric field in these regions, especially on the drain side, enabling lower electric field peaking and increasing the breakdown voltage of such a thin film device as escribed before.

FIG. 6 illustrates additional examples of cross sections of semiconductor device 100 including TFT 110 having current terminal 122 and current terminal 124 as hybrid edge contacts, where the hybrid edge contact includes a metal contact portion (e.g., copper and cobalt, or other metals) and a channel contact portion including the channel material (e.g., a metal oxide material, carbon nanotubes, etc.). The channel contact portion can be conformal to the step structure formed by etching dielectric layer 119a and not etching (or etching to a less extend) dielectric layer 119b/c/d. Referring to FIG. 6, current terminal 122 includes a protruding channel contact portion 122c, a lateral channel contact portion 122d, and metal contact portion 122a on and abutting protruding channel contact portion 122c and lateral channel contact portion 122d. Lateral channel contact portion 122d can extend laterally (e.g., along the x/y axes) on dielectric layer 119c and conformal to a first step structure of dielectric structure 118 on a side 402 of channel layer 112. Protruding channel contact portion 122c can protrude from lateral channel contact portion 122d and cover dielectric spacer 140a, a side 602 of dielectric structure 116, side 404 of channel layer 112, and a side 606 of dielectric layer 119a. Also, current terminal 124 includes a protruding channel contact portion 124c, a lateral channel contact portion 124d, and metal portion 124a on and abutting protruding channel contact portion 124c and lateral channel contact portion 124d. Lateral channel contact portion 124d can extend laterally (e.g., along the x/y axes) on dielectric layer 119c and conformal to a second step structure of dielectric structure 118 on side 404 of channel layer 112 opposing side 402. Protruding channel layer portion 124c can protrude from lateral channel contact portion 124d and cover dielectric spacer 140b, a side 612 of dielectric structure 116 opposing side 602, side 404 of channel layer 112, and a side 616 of dielectric layer 119a of dielectric structure 118 opposing side 606. Lateral channel layer portion 124d can extend laterally (e.g., along the x/y axes) on dielectric layer 119b. In examples where the channel layer includes a metal oxide material (e.g., In₂O₃), the hybrid edge contacts can be formed by depositing (e.g., by an atomic layer deposition process) a layer of the channel material on the dielectric spacers 140a/140b, sides 602/612, 402/404, 606/616, and on dielectric layer 119b, followed by depositing a metal on the layer of the channel material.

The channel layer portions of the hybrid edge contacts can shape the electric field around the drain and/source contacts, which can reduce peaking of the electric field and increase the breakdown voltage of the transistor when in the off-state, while the metal portion can further reduce contact resistance. Also, thicker source and drain contacts provide more flexibility in controlling the electric field and its peaking, because electric field may peak at sharp edges of metal, and thicker metal relaxes this condition.

FIG. 7A illustrates additional examples of cross sections of semiconductor device 100 including TFT 110 having control terminal 114 formed by an additive patterning process, such as a damascene process. As part of the addictive patterning process for forming control terminal 114, the dielectric material in upper metallization structure 104b is etched/patterned to form a trench, followed by depositing a first metal layer in the trench to form a barrier layer lining the trench, and then followed by filling the trench (lined by the barrier layer) with a second metal to form the gate. The barrier layer can prevent the second metal from diffusing into the surrounding dielectric material and affecting the property of the dielectric material. The barrier layer may include titanium (Ta), titanium nitride (TaN), Ruthenium (Ru), or Ru-based material. The metal contacts and metal vias coupled to control terminal 114, current terminal 122, and current terminal 124, can also be formed by the addictive patterning process. In some examples, the barrier layer can be Ruthenium (Ru), or Ru-based material and can have a high work function, and can be used to set the threshold voltage of the transistor. In some examples, a third metal layer having a high work function can be formed on dielectric structure 116 to set the threshold voltage, followed by forming the trench and depositing the barrier layer and the first metal layer, as to be described below, and control terminal 114 can have a stack of three metal layers.

Referring to FIG. 7A, control terminal 114 may include layers 117b, 117a, and a barrier layer 702. In the example shown in FIG. 7A, layer 117a is vertically between layer 117b and dielectric structure 116, as described above. Also, a lateral portion 702a of barrier layer 702 extends laterally on layer 117a and is vertically between layers 117b and 117a. Also, side portions 702b of barrier layer 702 extends vertically (or protrudes from lateral portion 702a) and forms sidewalls abutting layer 117b. In the example shown in FIG. 7A, metal layer 117a can include a high work function metal, or a metal selected specifically to have a more suitable work-function potential to shift the threshold voltage more towards a positive value desired for a thin film electron carrier style transistor (e.g., having a similar behavior as an N-type field effect transistor). In some examples, barrier layer 702 can include a high work function metal (e.g., Ru) to set the threshold voltage, and layer 117a can be omitted, as described above.

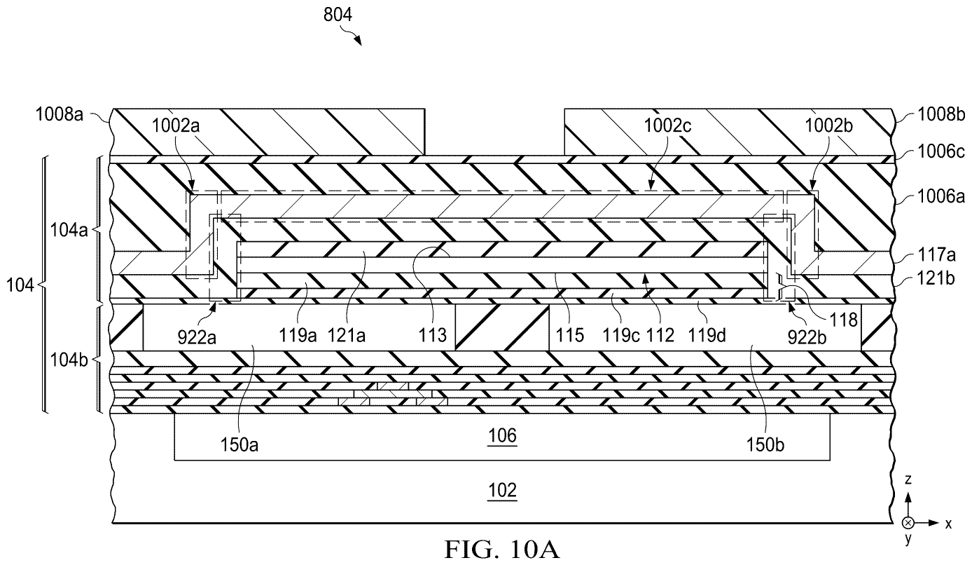

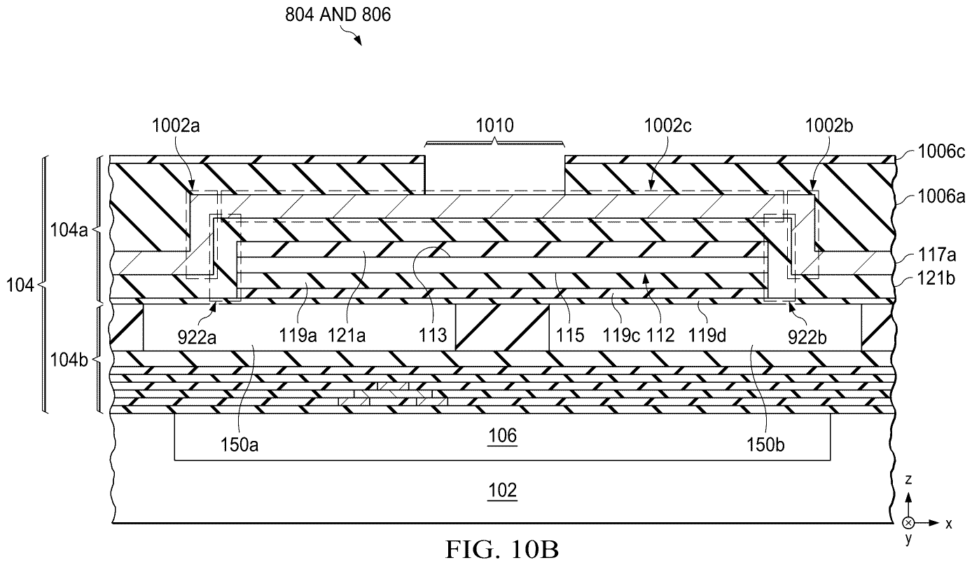

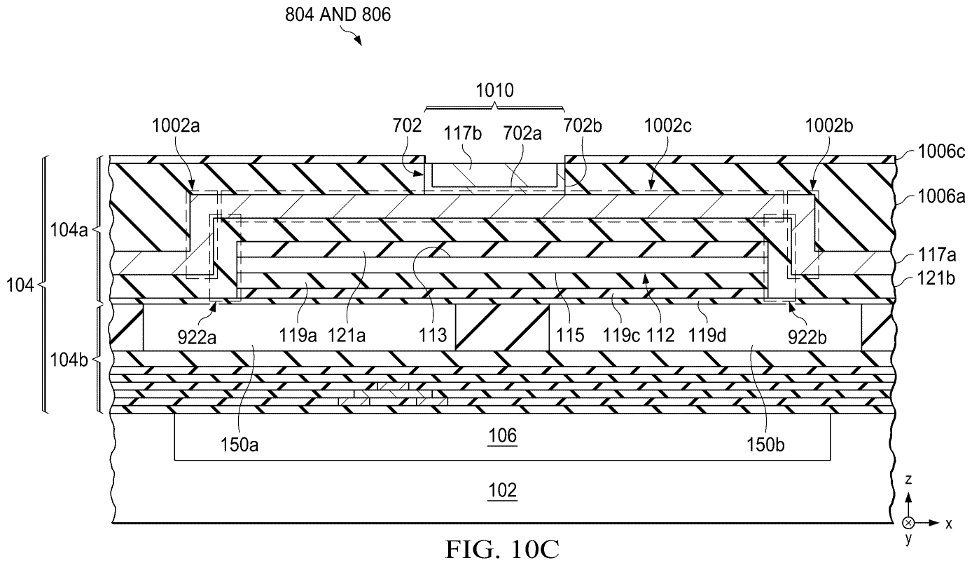

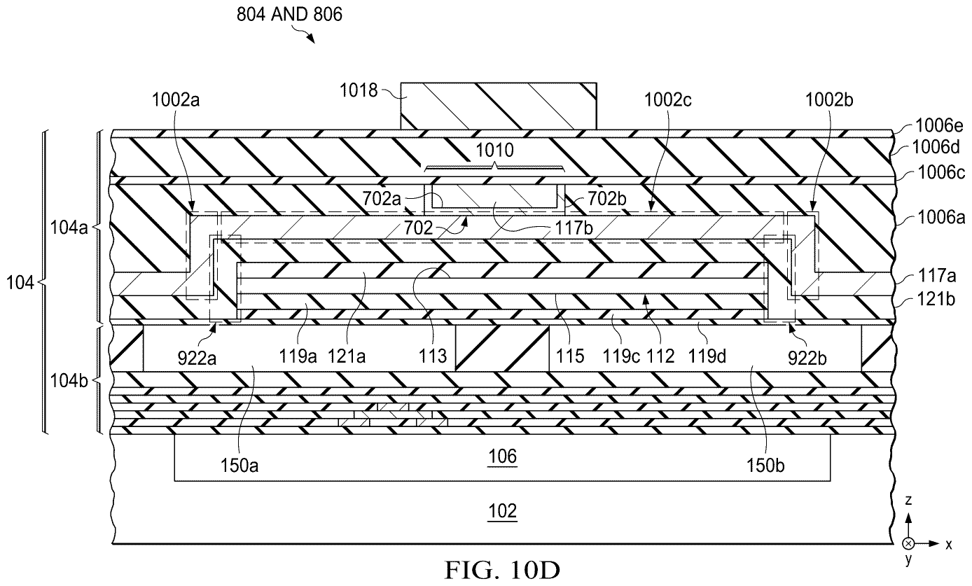

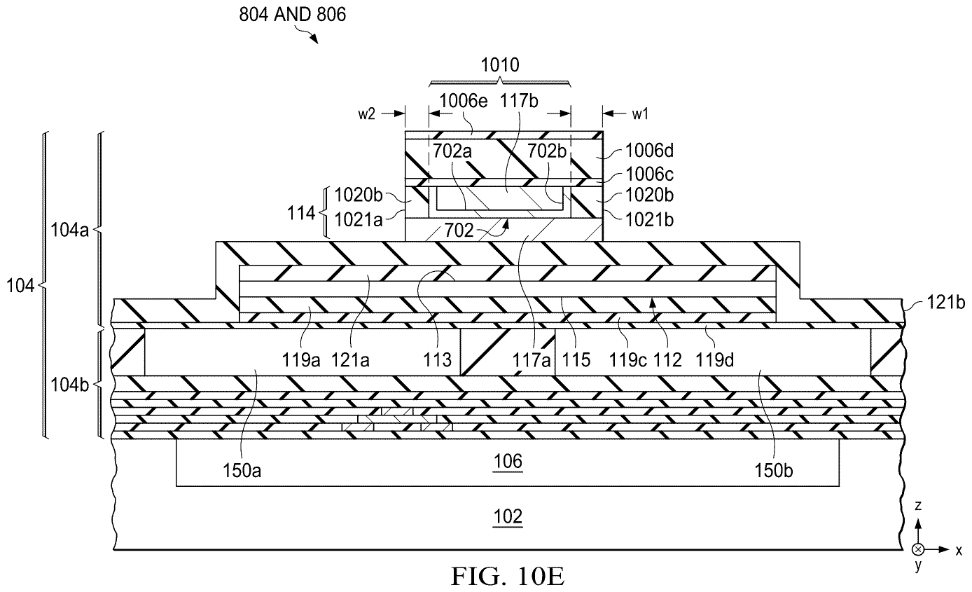

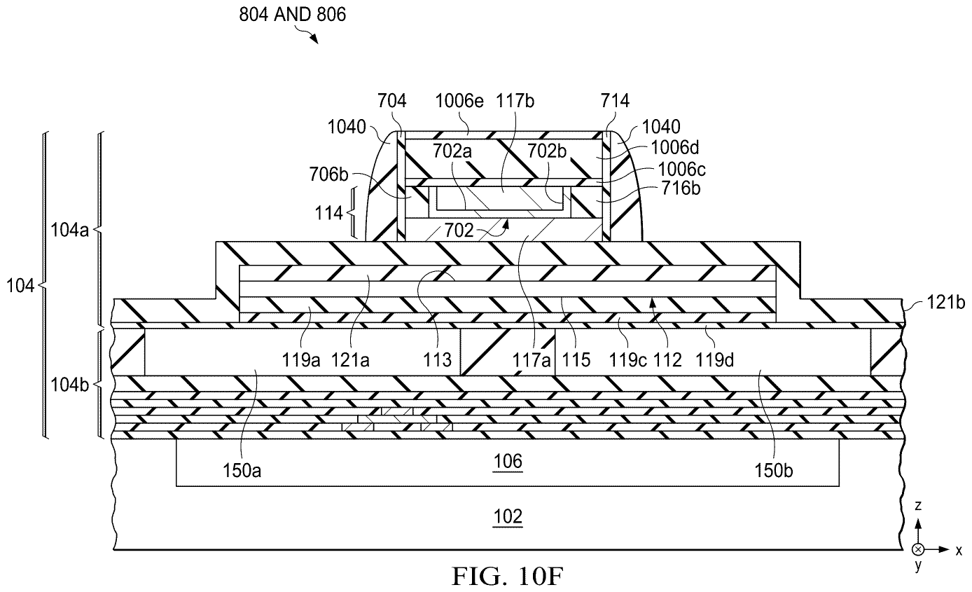

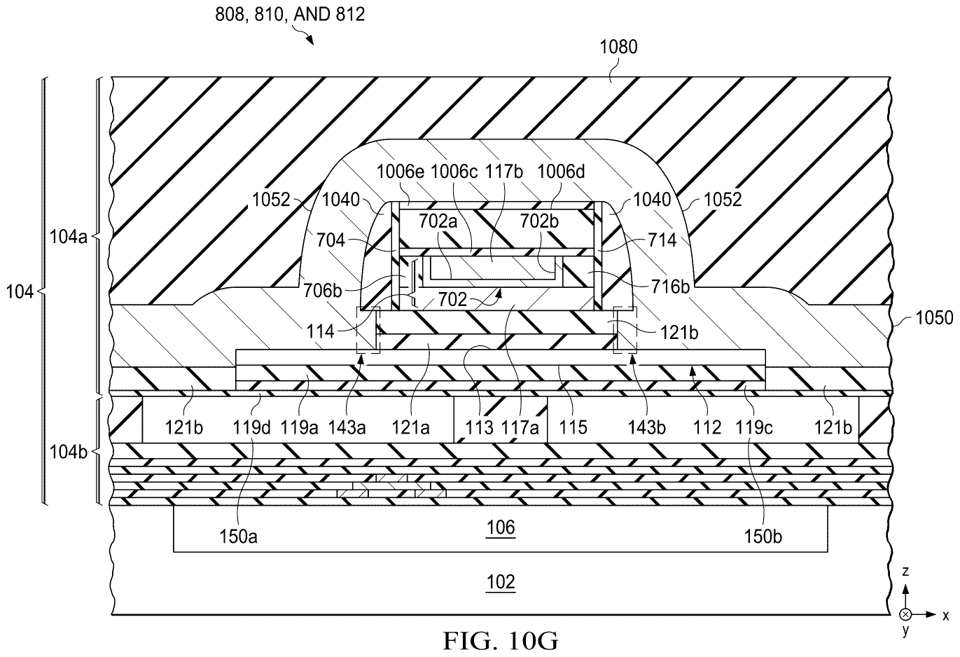

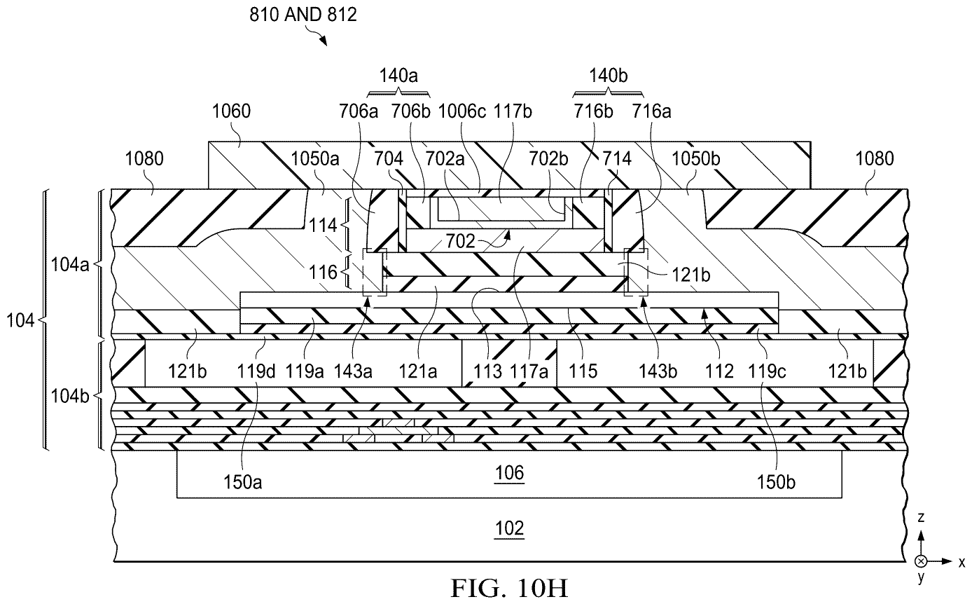

Also, each of dielectric spacers 140a and 140b may each include an etch stop material, such as Si₃N₄, sandwiched between two dielectric layers. For example, dielectric spacer 140a may include an etch stop layer 704 laterally between dielectric layers 706a and 706b, which can be of the same oxide material (e.g., SiO₂) or have different oxide materials, and forming a lateral laminate of dielectric layers. Also, dielectric spacer 140b may include an etch stop layer 714 laterally between dielectric layers 716a and 716b, which also can the same oxide (e.g., SiO₂) or different oxide materials, and forming another lateral laminate of dielectric layers. As to be described below in FIG. 10E, each of dielectric layers 706a and 706b can represent a baseline dielectric spacer on each side of control terminal 114, and the lateral thickness of each baseline dielectric spacer can be reduced by etching of the baseline dielectric spacer prior to forming etch stop layers 704 and 714. The lateral thickness of each dielectric spacer can then be optionally further increased by depositing dielectric layers 606a and 616a on, respectively, etch stop layers 704 and 714.

Also, current terminal 122, current terminal 124, metal vias 130a-130e, and metal contacts 132a-132e can also be formed with an additive patterning process. For example, current terminal 122 and current terminal 124 can each include a respective barrier layer (e.g., Ta, TaN) conformally on channel layer 112 and dielectric spacers 140a/140b. A dielectric layer 718a is on the barrier layer of current terminal 122, and a dielectric layer 618b is on the barrier layer of current terminal 124. Current terminal 122, second current terminal 122, dielectric layers 718a and 718b, and control terminal 114 are covered/sealed by dielectric layer 202, which can have the same etch stop material (e.g., Si₃N₄) as etch stop layers 704 and 714.

Also, metal via 130a and metal contact 132a can be surrounded by a barrier layer 720a, metal via 130b and metal contact 132b can be surrounded by a barrier layer 720b, metal via 130c and metal contact 132c can be surrounded by a barrier layer 720c, metal via 130d and metal contact 132d can be surrounded by a barrier layer 720d, and metal via 130e and metal contact 132e can be surrounded by a barrier layer 720e. Each of metal vias 130a, 130b, 130c, 130d, and 130e can be formed by etching trenches through the dielectric material of upper metallization structure 104b, including dielectric layer 202 and dielectric layers 618a/618b to expose the metal layers of control terminal 114 (e.g., layer 117b), current terminal 122, current terminal 124, and control terminals 150a and 150b, followed by depositing the barrier layer and the second metal (e.g., copper) in the trenches and on the exposed metal layers. Accordingly, barrier layer 720a of via 130a is in contact with the barrier layer of current terminal 122, and barrier layer 720c of via 130c is in contact with the barrier layer of second current terminal 122, while barrier layers 720b, 720d, and 720e is in contact with, respectively, layer 117b (of control terminal 114), second control terminal 150a, and second control terminal 150b. In some examples (not shown in the figures), second control terminals 150 can be formed using additive patterning processes and each may include a barrier layer (e.g., Ta, TaN, or other examples described above) and a contact metal layer (e.g., Cu, Co, Ni, or other examples described above).

FIG. 7B illustrates additional examples of cross sections of semiconductor device 100 including TFT 110 having control terminal 114 as a top gate and control terminal 150 as a bottom gate, where current terminals 122 and 124 are on side 113 of channel layer 112, and control terminal 150 and current terminals 122 and 124 are coupled to FEOL circuitries 106 via metal interconnects in lower metallization structure 104b. As shown in FIG. 7B, TFT 110 may include dielectric structure 116, channel layer 112, and dielectric structure 118 in upper metallization structure 104a and on a side 725 of lower metallization structure 104b. Dielectric spacers 140a and 140b are on at least two sides of control terminal 114 and form recesses 143a and 143b on side 113 of channel layer 112. Each of current terminals 122 and 124 can include a metal layer (e.g., TiW or any other material described therein) that extends from a side surface of dielectric spacer 140a/140b and over recesses 143a/143b, parts of sides 113 and sides 402/404 of channel layer 112, sides 726 and 728 of dielectric structure 118 (each angled from sides 113/115 of channel layer 112), and onto side 725 of lower metallization structure 104b.

Also, lower metallization structure 104b may include, in a first metal layer, contacts 730a and 730c that are in contact with, respectively, the metal layers of current terminals 122 and 124. Lower metallization structure 104b also includes control terminal 150 in the first metal layer, where control terminal 150 is on side 115 of channel layer 112, is separated from channel layer 112 by dielectric structure 118, and form a back gate. Lower metallization structure 104b may also includes vias 732a, 732b, and 732c, as well as contacts 734a, 734b, and 734c in a second metal layer. Contacts 730a and 734a and via 732a can provide electrical connection between FEOL circuitries 106 and current terminal 122. Contact 734b and via 732b can provide electrical connection between FEOL circuitries 106 and control terminal 150. Contacts 730c and 734c and via 732c can provide electrical connection between FEOL circuitries 106 and current terminal 124. Control terminals 114 and 150, as well as the vias, can be formed by patterning the metal layers, or by an additive patterning process (e.g., a damascene process, a dual damascene process, etc.), and can include barrier layers similar to those shown in FIG. 7A.

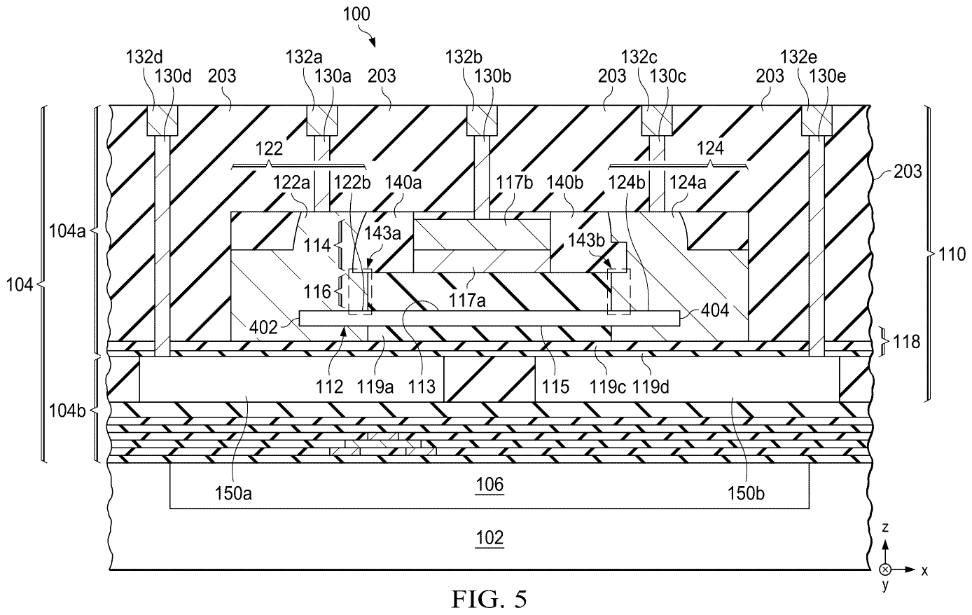

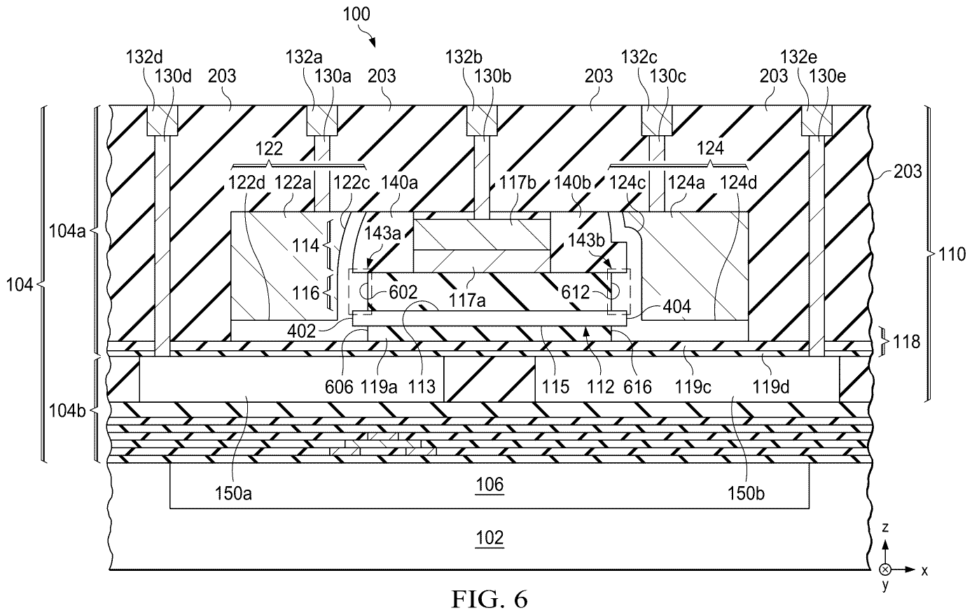

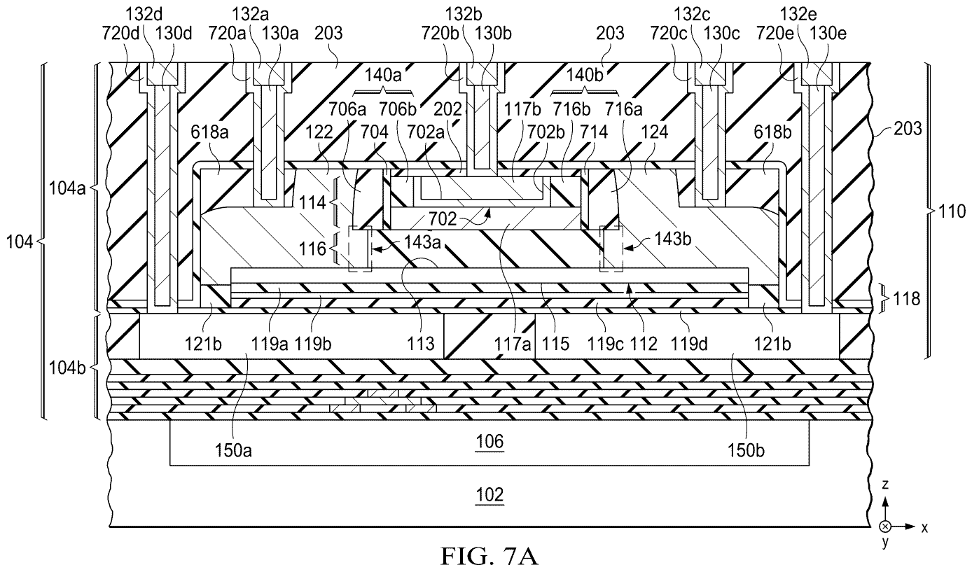

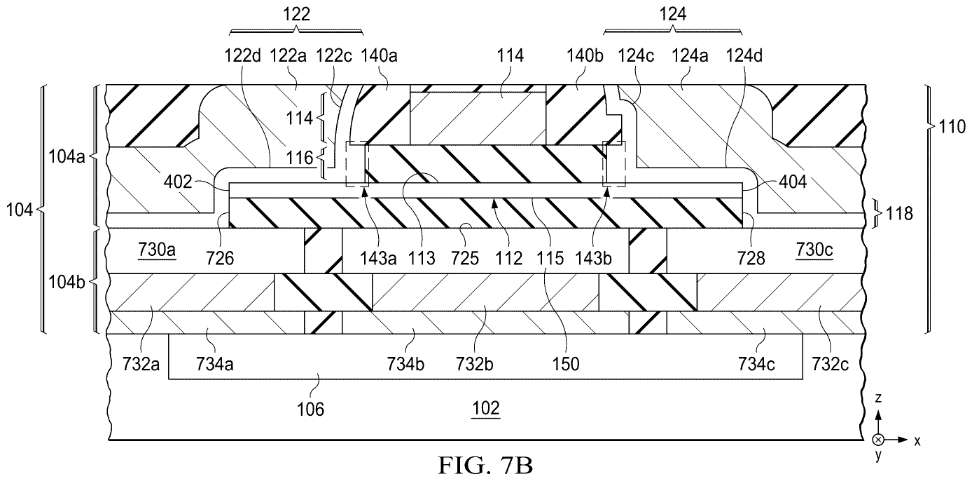

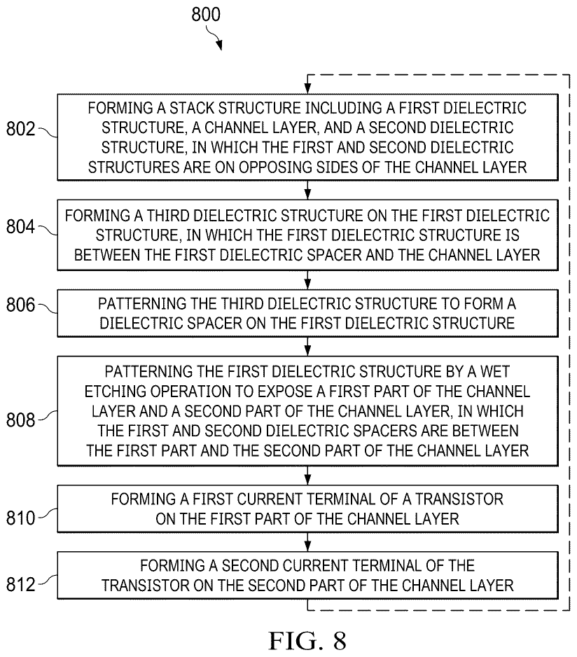

FIG. 8 illustrates a flowchart of examples of a method 800 of fabrication of a semiconductor device (e.g., semiconductor device 100) including a thin film semiconductor device, such as TFT 110 and thin film bidirectional switch 200 described in FIGS. 1A-7. In some examples, method 800 can be part of a BEOL process, or otherwise can be performed in an environment compatible with a BEOL process (e.g., at or below 400° C.). FIGS. 9A-1 to 9O-2 illustrate examples of cross sections of semiconductor device 100 during various operations of method 800, including forming control terminal 114 by a metal patterning process. Also, FIGS. 10A-10K examples of cross sections of semiconductor device 100 during various operations of method 800, including forming control terminal 114 by an addictive patterning process, such as a damascene process. The order of the operations shown in flowchart may be different from the actual order of the fabrication operations.

Referring to FIGS. 9A-1, 9A-2, and 9B, in operation 802, a stack structure including a first dielectric structure (e.g., dielectric structure 116), a channel layer (e.g., channel layer 112), and a second dielectric structure (e.g., dielectric structure 118) is formed, in which the first and second dielectric structures are on opposing sides of the channel layer.

The second dielectric structure (e.g., dielectric structure 118) can be part of the metallization structure (e.g., part of upper metallization structure 104a as shown) or above the metallization structure. The second dielectric structure includes one or more dielectric layers, such as dielectric layers 119d (e.g., SiCN layer, dielectric layer 119c (e.g., Al₂O₃, AlN, h-BN, or other materials described above), and dielectric layer 119a (e.g., Al₂O₃, or other materials described above). Some examples of the first dielectric structure may also include an etch stop layer, such as dielectric layer 119b (e.g., AlN, Si₃N₄, or other materials described above) shown in FIG. 1B. The dielectric layers can be formed by, for example, a thin film deposition process (e.g., chemical vapor deposition (CVD), atomic layer deposition (ALD), plasma-enhanced CVD (PECVD), reactive-physical vapor deposition (PVD), etc.). In some examples, as shown in FIG. 9A-2, dielectric layer 119c can be patterned to have an increased thickness over control terminal 150b (to be formed as a field plate below the drain terminal of the thin film transistor), to increase the breakdown voltage between the drain terminal and the field plate. Also, some of the dielectric layers, such as dielectric layers 119a and 119b, can have different dielectric materials or otherwise have different etch selectivities, which allow forming a step structure in dielectric structure 118 to support formation of edge contacts, as to be described below. The lower metallization structure 104b may include one or more control terminals 150, which can include a bottom gate to set a threshold of the TFT and/or a field plate to increase the break down voltage of the TFT.

Referring to FIG. 9B, as part of operation 802, following the formation of the second dielectric structure (e.g., dielectric structure 118), the channel layer (e.g., channel layer 112) is formed on the second dielectric structure, followed by formation of the first dielectric structure (e.g., dielectric structure 116) on the channel layer, so that the first dielectric structure and the second dielectric structure are on opposing sides (e.g., sides 113 and 115) of the channel layer.

The channel layer can be part of the metallization structure (e.g., upper metallization structure 104a as shown) or can be above the metallization structure. The channel layer may include, for example, a metal oxide (In₂O₃, or other materials described above), carbon nanotubes, etc. For example, In₂O₃ can be formed by a thin film deposition process, such as an atomic layer deposition (ALD) process, on the first dielectric structure. Also, carbon nanotubes, such as single wall carbon nanotubes (SWCNT), can be deposited in a desired aligned method by various techniques, such as arc discharge followed by laser ablation to filter and keep only the aligned SWCNTs, or by using tangential flow liquid methods for aligned deposition of prior grown and filtered semiconducting SWCNTs. In the examples shown in FIG. 9B and subsequent figures, dielectric structure 118 has a uniform thickness and has a planar surface. Channel layer 112 is conformal to the planar surface and can also be planar. In examples where first dielectric structure 118 has an increased thickness over second control terminal 150b, channel layer 112 is conformal to the stepped/staircase surface and can have a non-planar surface interfacing dielectric structure 118.

Also, referring to FIGS. 9B, 9C, 9D, and 9E, as part of operation 802, the first dielectric structure (e.g., dielectric structure 116) is formed on a top side (e.g., side 113) of channel layer 112 opposing the bottom side (e.g., side 115) of channel layer 112. Referring to FIG. 9B, dielectric layer 121a (of dielectric structure 116) can be formed on the top side of channel layer 112. Dielectric layer 121a can be formed by a thin film deposition process, such as chemical vapor deposition. As explained above, dielectric layer 121a can seal channel layer 112 and protect channel layer 112 from being impacted by agents (e.g., mask ash) involved in the fabrication of the thin film semiconductor devices. Dielectric layer 121a can also shield channel layer 112 from the interface with control terminal 114, which can include traps that affect the charge mobility of channel layer 112. Dielectric layer 121a can also be of an oxide type that enhances the charge mobility of channel layer 112, such as SiO₂ on top or bottom of an In₂O₃ channel, or around individual SWCNT, to enhance the charge mobility in the channel layer, followed by another higher-K dielectric material (e.g., HfO₂) on top of SiO₂. Such arrangements can improve the charge mobility in the channel, at least because SiO₂ offers a higher energy barrier for charge scattering versus HfO₂ which has a lower energy barrier for scattering. Accordingly, charge scattering in the channel can be reduced, and the charge mobility in the channel can be increased.

In some examples, the formation of channel layer 112 and dielectric structures 116 and 118 can be performed in situ (e.g., in the same vacuumed environment), to reduce/eliminate defects and contamination at the interfaces between the channel layer and the first and second dielectric structures.

Referring to FIG. 9C, as part of operation 802, a mask 902 is placed on dielectric layer 121a. Mask 902 can define the lateral dimensions and the lateral location (e.g., along the x or y axes of the figures) of channel layer 112 of the thin film transistor. Referring to FIG. 9D, dielectric layer 121a, channel layer 112, and dielectric layers 119a and 119c are patterned (e.g., by etching) using mask 902 and exposing parts of dielectric layer 119d. Also, dielectric layer 119d remains as an etch stop layer and protect the underlying metal layers, including control terminals 150a and 150b, from the etching. Further, referring to FIG. 9E, mask 902 is removed, and dielectric layer 121b is formed over and covering the patterned dielectric layer 121a, channel layer 112, and dielectric layers 119a and 119c, as well as the exposed parts of dielectric layer 119, thereby forming a step structure. Dielectric layer 121b can include side portions, such as side portions 910a and 910b, that enclose/seal the patterned channel layer 112 from different sides, including sides 402 and 404 (angled from sides 113 and 115). Such arrangements can prevent channel layer 112 from being contaminated in subsequent operations. The thickness of dielectric layer 121a can be multiple times of dielectric layer 121b. As to be described below, in subsequent operations, parts of side portions 910a and 910b separated by the lateral length of channel layer 112 (denoted by L in FIG. 9E, along the x-axis in FIG. 9E) are removed, while parts of side portions 910a and 910b separated by the lateral width of channel layer 112 (e.g., along the y-axis in FIG. 9E) remain. The lateral thickness of the remaining side portions of dielectric layer 121b abutting edges of channel layer 112 can be increased to improve the gate oxide break down voltage of control terminal 114, and to compensate for degradation of the gate oxide break down voltage that could have been caused by the relatively thin dielectric layer 121a.

Referring again to FIG. 8, in operation 804, a third dielectric structure is formed on the first dielectric structure, in which the first dielectric structure is between the first dielectric spacer and the channel layer. Also, in operation 806, the third dielectric structure is patterned to form a dielectric spacer on the first dielectric structure.

In some examples, the third dielectric structure is patterned to form a dielectric spacer between the first and second current terminals of a transistor (to be formed in operations 808 and 810), such as dielectric spacer 140 of FIG. 1A. In some examples, the patterning of the third dielectric structure is performed to form control terminal 114, and a first dielectric spacer (e.g., dielectric spacer 140a) and a second dielectric spacer (e.g., dielectric spacer 140b) on two sides of control terminal 114. The patterning of the third dielectric structure and the formation of control terminal 114 can include a metal patterning process, as illustrated in FIGS. 9F-FIG. 9H, or can include an additive patterning process (e.g., a damascene process), as illustrated in FIGS. 10A-10G.

Referring to FIG. 9F, as part of operation 804, layer 117a is formed on dielectric layer 116b, and layer 117b is formed on layer 117a, so that layer 117a is vertically between dielectric layer 116b and layer 117b. Both layers 117a and 117b can be conformal to the step structure of dielectric layer 116b and have side portions that extend vertically (e.g., along the z-axis), such as side portions 922a and 922b of layer 117b, and form a step structure. Also, a fourth dielectric structure including dielectric layers 912a, 912b, 912c, and 912d can be formed on layers 117a and 117b. Specifically, dielectric layer 912a (e.g., SiO₂) can be formed surrounding the side portions (e.g., side portions 922a and 922b) of layer 117b, and to fill in the space around the step structure. Also, dielectric layer 912b (e.g., Al₂O3, HfO₂, ZrO₂, Si₃N₄) can be formed on a lateral portion 922c of layer 117b (that extends laterally along the x/y axes) and on dielectric layer 912a, a dielectric layer 912c (e.g., SiO₂) can be formed on dielectric layer 912b, and a dielectric layer 912d (e.g., Al₂O3, HfO₂, ZrO₂, Si₃N₄) can be formed on dielectric layer 912c, such that a vertical stack of dielectric layers are formed on layer 117b. Each dielectric layer can be formed by, for example, a deposition process. As to be described below, dielectric layer 912d can be an etch stop layer for an etching process to form dielectric spacers 140a/140b, and dielectric layer 912b can a stop layer for a planarization operation (e.g., a chemical mechanical planarization (CMP) operation) on dielectric layer 912c subsequent to the etching process to finalize the dimensions and shape of dielectric spacers 140a/140b.

Further, as part of operation 806, a mask 924 is formed on dielectric layer 912d. Mask 924 can define the location, as well as the lateral dimensions (e.g., length along the x-axis of FIG. 9F, width along the y-axis of FIG. 9F), of control terminal 114. The lateral dimensions also define the length and width of the channel of a thin film transistor. Mask 924 also define the locations of current terminals 122 and 124, thereby self-aligning the gate (e.g., control terminal 114) to the source and drain (e.g., current terminals 122 and 124) of the TFT. Referring to FIG. 9G, with mask 924, dielectric layers 912a-d and layers 117a and 117b are patterned to form control terminal 114, while the step structure of dielectric layer 121b (including side portions 922a and 922b) is not etched (or at least not fully removed) and remains.

FIG. 9H-FIG. 9O-2 illustrate additional processing steps involved in operations 804 and 806. Referring to FIG. 9H, before or after mask 924 is removed, parts of dielectric layer 121b above channel layer regions 112b and 112d and below dielectric spacers 140a and 140b (yet to be formed in FIG. 9H) can be removed or thinned to adjust the charge traps in those regions, to improve the Iₒₙ/I_{off} ratio and adjust the threshold voltage of the thin film transistor as it impacts the source side spacer region, while side portions 910a and 910b of dielectric layer 121b remain.

Referring to FIG. 9I, a dielectric layer 930, which can include one or more oxide layers such as SiO2, is formed on and covering dielectric layers 912b-d, layers 117a and 117b of control terminal 114, dielectric layer 121b, sides 402 and 404 of channel layer 112, and dielectric layers 119a-d. In some examples, dielectric layer 930 can merge with the step structure of dielectric layer 121b. Dielectric layer 930 may include a mesa portion 932 having sloped surfaces 934a and 934b around dielectric layers 912b-d, and lateral portion 936a and 936b around control terminal 114 having, respectively, surfaces 938a and 938b. The sloped side walls can be caused by the anisotropic etch process, such as an anisotropic dry etch process, used to ensure that the spacer material is removed from the top (e.g., above dielectric layer 912d) while side wall portions (e.g., laterally adjacent to opposing sides of dielectric layers 912b-d) can remain. As to be described below, dielectric layer 930 may be patterned by an anisotropic etching process that etches mostly vertically, or along a direction orthogonal to surfaces 938a and 938b (e.g., along the z-axis in the figures), to form dielectric spacers 140a and 140b, and no mask or lithography is needed. Also, referring to FIG. 9J, in a case where a drain extension is to be formed, a mask 940 can be formed on and covering sloped surface 934b of mesa 932 and part of surface 938b of lateral portion 936b to stop/slow down the anisotropic etching process, so that dielectric spacer 140b can have a larger lateral thickness than dielectric spacer 140a.

FIGS. 10A-10E illustrate examples of cross sections of semiconductor device 100 in operations 804 and 806 including an additive patterning process (e.g., a damascene process). Referring to FIG. 10A, in some examples, layer 117a is formed on the step structure of dielectric layer 121b. Layer 117a can be conformal to the step structure and can include side portions 1002a and 1002b abutting, respectively, side portions 922a and 922b of dielectric layer 121b, and a lateral portion 1002c, also forming a step structure. In some examples, layer 117a is omitted, where the barrier layer (to be formed) can set the threshold voltage. Also, a dielectric layer 1006a (e.g., SiO₂) and a dielectric layer 1006b (e.g., Si₃N₄) are formed on and covering the step structures of layer 117a and dielectric layer 121b. Further, masks 1008a and 1008b is formed on dielectric layer 1006b and over layer 117a. Similar to mask 924 of FIG. 9F, masks 1008a and 1008b can define the location as well as the lateral dimensions (e.g., length along the x-axis of FIG. 9F, width along the y-axis of FIG. 9F) of control terminal 114, which is to be formed under area 1008c between masks 1008a and 1008b. In some examples (not shown in FIGS. 10A-10F), layer 117a is not deposited prior to forming masks 1008a and 1008b on dielectric layer 1006b. FIGS. 10B-10F illustrate additional processing steps of operation 810 including an additive patterning process. Referring to FIG. 10B, a recess 1010 is formed by etching away parts of dielectric layers 1006a and 1006 directly below mask 1008, with part of lateral portion 1002c of layer 117a exposed in recess 1010. Also, referring to FIG. 10C, barrier layer 702, including bottom portion 702a and side portion 702b, is formed in recess 1010, where side portion 702b lines the internal surfaces of recess 1010, and bottom portion 702a of barrier layer 702 abuts lateral portion 1002c of layer 117a. In a case where layer 117a is omitted, bottom portion 702a can include a high work function metal (e.g., Ru) and abut dielectric layer 121b, and can set the threshold voltage of the channel. Barrier layer 702 can be formed by a thin film deposition process on the internal surfaces of recess 1010. Layer 117b is then formed on barrier layer 702 in recess 1010 by, for example, a thin film deposition process, e.g., CVD and ALD.

Also, referring to FIG. 10D, a dielectric layer 1006c (e.g., Si₃N₄) is formed to covering layer 117a and barrier layer 702 in recess 1010. Dielectric layer 1006c can be formed after dielectric layer 1006b is removed, or on dielectric layer 1006b. A dielectric layer 1006d (e.g., SiO is formed on dielectric layer 1006c, and a dielectric layer 1006e (e.g., Si₃N₄) is formed on dielectric layer 1006d, so that dielectric layer 1006d is vertically situated between dielectric layers 1006c and 1006e. A mask 1018 is formed on dielectric layer 1006e and aligned (with certain tolerance) with recess 1010 (or masks 1008a/1008b), but with larger lateral dimensions (e.g., along the x and y axes) than recess 1010 creating overhangs. As to be described below, mask 1018 is used pattern dielectric layers 1006a and 1006c-e, and layer 117a to create control terminal 114 and dielectric spacers 140a and 140b. The overhangs together with the tolerance of misalignment allow creation of dielectric spacers 140a and 140b with sub-lithography dimensions and, in some examples, creation of asymmetric dielectric spacers 140a and 140b, where one of the dielectric spacers (e.g., dielectric spacer 140b) has a drain extension.

Referring to FIG. 10E, mask 1018 can be used to pattern dielectric layers 1006a and 1006c-e, and layer 117a (in examples where layer 117a is not formed in recess 1010) to form control terminal 114. Also, the step structure of dielectric layer 121b (including side portions 922a and 922b) is not etched (or at least not fully removed) and remains. In the examples shown in FIG. 10E, because mask 1018 have larger lateral dimensions than recess 1010 resulting in overhang, parts of dielectrics layer 1006a around recess 1010 (and side portions of barrier layer 702), including side portions 1020a and 1020b, remain, and can become parts of dielectric spacers 140a and 140b. For example, with 65 nm lithography that defines the lateral width (e.g., along the x-axis) of recess 1010, which can also define the channel length, and +/−15 nm misalignment and/or overhang, dielectric spacer 140a can have a lateral dimension w1 of 15 nm, and dielectric spacer 140b can have a lateral dimension w2 of 15 nm, both being a sub-lithography dimension (being smaller than 65 nm). Also, in some examples, as described above, the lateral dimensions of mask 1018 and/or relatively alignment between mask 1018 and recess 1010 can be made to introduce mismatches in lateral widths between side portions 1020a and 1020b of dielectric layer 1006a to create a drain extension. For example, in the examples shown in FIG. 10E, mask 1018 can have an overhang of 40 nm on opposing sides of recess 1010 and can be shifted towards left (e.g., due to misalignment), resulting in asymmetric dielectric spacers 140a and 140b. For example, side portion 1020b can have a lateral thickness w1 larger (e.g., 55 nm) than the lateral thickness w2 (e.g., 25 nm) of side portion 1020a, and side portion 1020b can be part of a drain extension as described in FIG. 1B. Also, side portion 1020a and 1020b can each define a baseline dielectric spacer. Anisotropic etching can be performed on vertical surfaces 1021a and 1021b of, respectively, side portions 1020a and 1020b to reduce w1 and w2. As to be described below, after the etching is performed to set the lateral thicknesses of side portions 1020a and 1020b, etch stop layers can be formed on surfaces 1021a and 1021b, and then additional dielectric material can be formed on the etch stop layers to set the final lateral thicknesses of dielectric spacers 140a and 140b.

Referring again to FIG. 8, in operation 808, the first dielectric structure (e.g., dielectric structure 116) can be wet etched to expose a first part of the channel layer and a second part of the channel layer, in which the first and second dielectric spacers are between the first part and the second part of the channel layer. The wet etch operation can be performed to avoid etching through the thin channel layer 112 (e.g., 1-2 nm). The wet etch operation can be isotropic and can form undercuts/recesses 143a and 143b below dielectric spacers 140a/140b.

FIG. 9K-1, FIG. 9K-2, FIG. 9K-3, and FIG. 9K-4 illustrate examples of cross sections of semiconductor device 100 after the anisotropic etching of dielectric layer 930 and the isotropic wet etching of dielectric structure 116. In the example of FIG. 9K-1, because of the anisotropic etching, part of dielectric layer 930 on dielectric layer 912d exposed by mask 940 is removed. Lateral portions 936a and 936b of dielectric layer 930 are also removed. A new dielectric mesa structure 952 of dielectric layer 930 is formed around dielectric layers 912b-d and layers 117a and 117b of control terminal 114. Dielectric layers 119a and 119c are not etched and remain, while dielectric layer 119c can act as an etch stop layer and protect the underlying lower metallization structure 104b from the etching. As to be described below, metal can then be deposited on side 113 of channel layer 112 and on regions 112a and 112e to form contacts of current terminals 122 and 124 as shown in FIG. 1B and FIG. 3. Also, the wet etch operation can be performed to remove parts of dielectric layers 121a and 121b under lateral portions 936a and 936b as well as the step structures including side portions 910a and 910b, are also removed, thereby exposing regions 112a and 112e of channel layer 112, as well as forming recesses 143a and 143b on two sides of channel layer 112 and under dielectric mesa structure 952.

In some examples, dielectric mesa structure 952 also has sloped surfaces 954a and 954b that can have the same slopes (e.g., with respect to the x/y planes, and/or with respect to channel layer 112) as, respectively, sloped surfaces 934a and 934b. Dielectric mesa structure 952 can have a lateral thickness L1 on a side of control terminal 114 facing the direction of region 112a, and a drain extension portion 952a having a lateral thickness L2 on a side of control terminal 114 facing the direction of region 112e, with L2 being larger than L1. Because the anisotropic etching does not involve mask and lithography, at least one of L1 or L2 can have a sub-lithography dimension, such that at least one of L1 or L2 is lower than a minimum dimension allowed by the lithography process used in fabricating other parts of the transistor. For example, mask 924 in FIG. 9G can have a minimum dimension, such as a length along the x-axis in FIG. 9G, allowed by lithography process, to minimize the length of layers 117a and 117b along the x-axis in FIG. 9G and FIG. 9K-1 to minimize channel length. In such examples, at least one of L1 or L2 can be lower than the length of layers 117a and 117b. As explained above, such arrangements can reduce the parasitic capacitance (e.g., C_{off}) of the transistor for high frequency applications (e.g., radio-frequency (RF) applications), and/or to allow the source to be optimized for improved on-state current (Iₒₙ) over off-state current (I_{off}) ratio.

In some examples, with region 112a of channel layer 112 (to be below current terminal 122) and region 112e of channel layer 112 (to be below current terminal 124) exposed after the removal of dielectric layers 121a and 121b, these exposed regions can be treated to have different mechanical structure and/or chemical compositions from the region directly under control terminal 114 (region 112c), to enhance various properties of the transistor. For example, in a case where channel layer 112 includes carbon nanotubes, regions 112a and 112e can be treated (e.g., a methane plasma treatment) to introduce defects to the carbon nanotubes in the regions to improve contact between the metal of the current terminals and the carbon nanotubes, which can reduce contact resistance. The SWCNTs in region 112c (under control terminal 114) can be masked/protected from the hydrogen, oxygen, nitrogen and inert gases plasma treatment to improve/maintain charge mobility. Also, in a case where the charge layer includes a metal oxide material, such as indium oxide (e.g., In₂O₃), the oxygen vacancy (or doping content) of regions 120a and 120e can be adjusted to reduce contact resistance. The vacancy concentration in In₂O₃ can be used to change the position of the charge neutrality line (CNL) or the Fermi level thus enabling threshold voltage control. In addition, the vacancy concentration can also be used to control the contact resistance; increasing the vacancy concentration increases the electron concentration and shift the CNL closer to the vacuum level thus eliminating the Schottky barrier. Also, the oxygen vacancy (or doping content) of region 120c under the first control terminal (e.g., gate) can be adjusted to improve charge mobility. Further, the oxygen vacancy (or doping content) of region 120b can be adjusted to reduce I_{off}. Also, the oxygen vacancy (or doping content) of region 120d can also be adjusted to increase the drain-source breakdown voltage of TFT 110 when the transistor is in the off state.

FIG. 9K-2, FIG. 9K-3, and FIG. 9k-4 illustrate examples of cross sections of semiconductor device 100 after the anisotropic etching and wet etching, plus other etching operations to form current terminals 122 and 124 as edge contacts or hybrid edge contacts as shown in FIGS. 4-7. As shown in FIG. 9K-2, dielectric structure 118 may include dielectric layer 119b as an etch stop layer. After the anisotropic etching on the lateral surfaces (e.g., parallel with x-y axes in FIG. 9K-2) to remove parts of dielectric layer 930 and form dielectric mesa structure 952, a wet etching can be performed to remove parts of channel layer 112, including regions 112a and 112e, as well as dielectric layer 119a below regions 112a and 112e. Regions 112b, 112c, and 112d remain, and recesses 143a and 143b are formed on regions 112b and 112d. Dielectric layer 119b can protect the underlying dielectric layers 119c, 119d, and lower metallization structure 104b from the etching. As to be described below, metal can then be deposited on and covering dielectric mesa structure 952 (including sloped surfaces 954a and 954b), sides 602 and 612 of dielectric structure 116, sides 402 and 404 of channel layer 112, sides 606 and 616 of dielectric layer 119a, and on dielectric layer 119b, to form edge contacts as shown in FIG. 4.

Also, referring to FIG. 9K-3, to form examples of hybrid edge contacts as shown in FIG. 6, a layer of the channel material 960 can be deposited (e.g., by an atomic layer deposition process) on and covering dielectric mesa structure 952 (including sloped surfaces 954a and 954b), sides 602 and 612 of dielectric structure 116, sides 402 and 404 of channel layer 112 (and merges with channel layer 112), sides 606 and 616 of dielectric layer 119a, and on dielectric layer 119b, to form protruding channel layer portion 122c and lateral channel layer portion 122d of current terminal 122, and to form protruding channel layer portion 124c and lateral channel layer portion 124d of current terminal 124, as shown in FIG. 6.

Further, referring to FIG. 9K-4, to form examples of hybrid edge contacts as shown in FIG. 5, parts of dielectric layer 119a on side 115 of channel layer 112 and below channel layer 112 is etched by an under etch process, while channel regions 112a-e remain. Metal can then be deposited on dielectric layer 119b and on sides 113 and 115 of channel layer 112 to form edge contacts that extend from side 113 of channel layer, around sides 402 and 404 of channel layer 112, and into side 115 of channel layer 112.

Referring to FIGS. 9L-1 and 9L-2, as part of operations 810 and 812 to form current terminals 122 and 124, a metal layer 970 (e.g., Co, TiN, TaN, Ni, or A/B stacks, A=TiN, TaN and B=W, Cu, Co, Ni) is formed on and covering dielectric mesa structure 952, channel layer 112, and dielectric layer 119b. In FIG. 9L-2, metal layer 970 can be formed on and covering layer 960 of channel material (e.g., from FIG. 9K-3), including protruding channel layer portions 122c and 124c and lateral channel layer portions 122d and 124d, to form the metal portions of the hybrid edge contacts. Metal layer 970 can be deposited using, for example depending on material, ALD, PVD or a combination. Metal layer 970 can include a metallic mesa structure 972 around dielectric mesa structure 952 with sloped surfaces 972a and 972b. Also, a dielectric material 980, which can include one or more dielectric layers, is formed on and covering metal layer 970.

Referring to FIGS. 9M-1 and 9M-2, as part of operation 806 to form dielectric spacers 140a and 140b, a planarization operation (e.g., chemical and mechanical planarization (CMP)) can be performed on metallic mesa structure 972 to remove top portions of metallic mesa structure 972, dielectric mesa structure 952, and dielectric layers 912d and 912c. The planarization operation stops when dielectric layer 912b is exposed. After the planarization operation, what remains of metal layer 970 can become metal layer portions 970a and 970b. In FIG. 9M-1, metal layer portion 970a is on region 112a of channel layer 112, which can then be patterned to form a metal contact of current terminal 122. Also, metal layer 970b is on region 112e of channel layer, which can then be patterned to form a metal contact of current terminal 124. Further, In FIG. 9M-2, metal layer portion 970a is on and abutting protruding channel layer portion 122c and lateral channel layer portion 122d, which can then be patterned to form metal portion 122a of the hybrid edge contact of current terminal 122. Also, metal layer portion 970b is on and abutting protruding channel layer portion 124c and lateral channel layer portion 124d, which can then be patterned to form metal portion 124a of the hybrid edge contact of current terminal 124.

Also, in both FIGS. 9M-1 and 9M-2, after the planarization operation, what remains of dielectric mesa structure 952 can include dielectric spacers 140a and 140b. Spacer 140a is laterally between current terminal 122 and layers 117a and 117b of control terminal 114, and spacer 140b is laterally between current terminal 124 and layers 117a and 117b of control terminal 114 by spacer 140b. Dielectric spacers 140a has the remaining part of the sloped surface 972a and can have a lateral thickness L1. Dielectric spacers 140b has the remaining part of the sloped surface 972a and can have a lateral thickness L2. As explained above, at least one of L1 or L2 can be of a sub-lithography dimension.

Referring to FIGS. 9N-1 and 9N-2, as part of operations 810 and 812 to form the current terminals, a mask 990 is formed on metal layer portions 970a and 970b, spacers 140a and 140b, and layers 117a and 117b of control terminal 114, and overlapping with channel layer 112. Mask 990 can define the overall dimension/footprint of the thin film transistor and can be used to pattern metal layer portions 970a and 970b. Referring to FIGS. 9O-1 and 9O-2, metal layer portions 970a and 970b outside the footprint of mask 990 are removed. In FIG. 9O-1, what remain of metal layer portions 970a and 970b can become the metal contacts of current terminals 122 and 124. Also, in FIG. 9O-2, as part of operations 810 and 812, what remain of metal layer portions 970a and 970b can become metal portion 122a of the hybrid edge contact of current terminal 122 and metal portion 124a of the hybrid edge contact of current terminal 124. In some examples, as shown in FIGS. 9O-1 and 9O-2, dielectric layer 202 can be formed to cover/seal current terminals 122 and 124, control terminal 114, and channel layer 112 from different sides, to protect the terminals from the etching during subsequent fabrication operations of metal vias and external metal contacts in upper metallization structure 104a. Dielectric layer 203 can also be formed on dielectric layer 202 to form dielectric structure 128. After patterning metal layer portions 970a and 970b to form the current terminals, metal vias and external metal contacts (e.g., metal vias 130a-e and metal contacts 132a-e), as well as dielectric material around the metal vias and the contacts, can be formed in upper metallization structure 104a and coupled to current terminals 122 and 124 and control terminals 114 and 150, in subsequent metal patterning operations or a subsequent additive patterning operation.

FIGS. 10F-10I illustrate examples of operations 804 and 806 for forming a control terminal (e.g., control terminal 114). Referring to FIG. 10F, in some examples, after finalizing the lateral widths of side portion 1020a and 1020b of dielectric layer 1006a, dielectric layer 704 of FIG. 7A (an etching stop layer, such as Si3N4) can be formed on and laterally adjacent to (e.g., along the x-y axes) side portion 1020a of dielectric layer 1006a, which can become dielectric layer 706b of FIG. 7A. Also, dielectric layer 714 of FIG. 7A (an etch stop layer, such as Si3N4) can be formed on and laterally adjacent to side portion 1020b of dielectric layer 1006a, which can become dielectric layer 716b of FIG. 7A. Dielectric layers 704 and 714 can provide an etch stop layer to protect side portions 1020a and 1020b in subsequent etching operation.

Also, a dielectric mesa structure 1040 is formed around dielectric layers 704 and 706b and around dielectric layers 714 and 716b. Dielectric mesa structure 1040 can be formed in similar processes as described in FIG. 9I-FIG. 9K-4, where a dielectric layer (e.g., dielectric layer 930, such as SiO2) is formed on and covering dielectric layers 1006c-e, layers 117a and 117b of control terminal 114, dielectric layer 121b, channel layer 112, and dielectric layers 119a, 119c, and 119d, followed by an anisotropic etching process that mostly etches vertically (e.g., along the z-axis). Dielectric mesa structure 1040 can add to the baseline lateral thicknesses provided by side portions 1020a and 1020b of dielectric layer 1006a to set the final lateral thicknesses of dielectric spacers 140a and 140b.

Referring to FIG. 10G, as part of operations 808, part of dielectric layers 121a and 121b are removed by wet etching, and regions of channel layer 112 (e.g., regions 112a and 112e) are exposed, and recesses 143a and 143b can be formed under dielectric mesa structure 1040 and on two sides of the remaining dielectric layers 121a and 121b. The exposed regions of channel layer 112 can be treated to, for example, reduce contact resistance, as described in FIG. 9K-1. Also, as part of operations 810 and 812 to form the current terminals, a metal layer 1050 is (e.g., Co, TiN, TaN, Ni, W, Cu, or other examples of materials described above for forming current terminals) is formed on and covering dielectric mesa structure 1040, channel layer 112, and dielectric layer 119d (and 121b if not removed as shown). Metal layer 1050 also forms a metallic mesa structure 1052 around dielectric mesa structure 1040. Also, a dielectric material 1080 (e.g., SiO2) is formed on and covering metal layer 1050.

Also, referring to FIG. 10G, as part of operation 806 to create the dielectric spacers, a planarization operation (e.g., a chemical and mechanical planarization operation) can be performed on metallic mesa structure 1052 to remove top portions of metallic mesa structure 1052, dielectric mesa structure 1040, and dielectric layers 1006e and 1006d. The planarization operation stops when dielectric layer 1006c is exposed. After the planarization operation, what remains of metal layer 1050 can become metal layer portions 1050a and 1050b, and what remains of dielectric mesa structure 1040 can become dielectric layers 706a and 706b. Dielectric spacers 140a and 140b are formed, where dielectric spacer 140a includes a lateral stack of dielectric layers 706a, 704, and 706b, and dielectric spacer 140b includes a lateral stack of dielectric layers 716a, 714, and 716b.

Also, referring to FIGS. 10H and 10I, as part of operations 810 and 812 to form the current terminals, after the planarization operation, a mask 1060 is formed on metal layer portions 1050a and 1050b, dielectric spacers 140a and 140b, and layers 117a and 117b of control terminal 114, and overlapping with channel layer 112. Similar to as described in FIGS. 9N-1 and 9N-2, mask 1060 can define the overall dimension/footprint of the thin film transistor and can be used to pattern metal layer portions 1050a and 1050b. Referring to FIG. 10I, metal layer portions 1050a and 1050b outside the footprint of mask 1060 are removed (e.g., by etching), and additional dielectric material can be deposited. What remain of metal layer portions 1050a and 1050b can become the metal contacts of current terminals 122 and 124, and what remain of dielectric material 1080 can merge with the newly deposited dielectric material and become, for example, dielectric layers 203 covering current terminals 122 and 124. Dielectric layer 202 (not shown in FIG. 10I) can also be formed to cover and seal/insulate current terminal 122, current terminal 124, control terminal 114, and channel layer 112 from different sides, and dielectric layer 203 can be formed on dielectric layer 202. After mask 1060 is removed, metal vias and external metal contacts (e.g., metal vias 130a-e and metal contacts 132a-e), as well as dielectric material around the metal vias and the contacts, can be formed in upper metallization structure 104a and coupled to current terminals 122 and 124 and control terminals 114 and 150, in subsequent metal patterning operations or a subsequent additive patterning operation.

Referring again to FIG. 8, in some examples, following operation 812 and prior to formation of metal vias and external metal contacts, an additional set of operations 802-812 can be repeated on the first and second current terminals, the control terminals, and the channel layer formed in the prior set of operations 802-810, to form a TFT with a stack of channel layers such as shown in FIG. 4B. For example, referring to FIG. 9P, the top part of dielectric layer 202 covering dielectric layer 980, current terminals 122 and 124, and control terminal 114 (e.g., from FIG. 9O-1) is either not formed or removed. And another stack of dielectric structure 116b, channel layer 112_1, and dielectric structure 118b can be performed in situ on current terminals 122 and 124, dielectric layer 980, and control terminal 114. The stack can then be patterned using another mask 902/1008 (in operation 802) to define the footprint of channel layer 112_1, followed by formation and patterning of a new stack of layers 117a-2 and 117b-2 using another mask 924/1018 to form control terminal 114b and dielectric spacers 140c and 140d (in operations 804, 806, and 808) and formation of metal layer and patterning of the metal layer with another mask 990/1060 to further extend current terminals 122 and 124 to connect to channel layer 112_1 (in operations 810 and 812).

FIGS. 11A, 11B, 11C, 11D, and 11E illustrate cross sections of additional examples of semiconductor device 100 including TFT 110, where current terminals 122 and 124 are on opposing sides of channel layer 112 with respect to control terminal 114. For example, as shown in FIGS. 11A and 11B, current terminals 122 and 124 are on second side 115 (e.g., bottom side) of channel layer 112, and control terminal 114 is on first side 113 (e.g., top side) of channel layer 112. Current terminals 122 and 124 can be part of lower structure 104a of metallization structure 104, whereas control terminal 114 can be part of upper structure 104a of metallization structure 104. As part of lower structure 104a, current terminal 122 can include a via 1102a and a metal interconnect 1104a surrounded by a dielectric structure 1105 (e.g., SiO₂), where via 1102a is vertically between channel layer 112 and metal interconnect 1104a and abuts (or contacts) channel layer 112. Also, current terminal 124 can include a via 1102b and a metal interconnect 1102b surrounded by a dielectric structure (e.g., SiO₂), where via 1102b is vertically between channel layer 112 and metal interconnect 1104b and abuts (or contacts) channel layer 112. Metal interconnects 1104a and 1104b can be coupled to, for example, active and/or passive FEOL circuitries 106 via other metal interconnects in lower structure 104b (not shown in the figures). Also, top surface 1107a of vias 1102a, and top surface 1107b of 1102b, and top surfaces 1109 of dielectric structure 1105 can be coplanar to form a planar surface on which channel layer 112 is formed. Further, in some examples, regions of channel layer 112 that are in contact with vias 1102a and 1102b can have different chemical compositions from the region of channel layer 112 under control terminal 114 (e.g., more defects in the case of carbon nanotubes, different oxygen contents in the case of conductive oxide) to improve contact resistances between current terminals 122/124 and channel layer 112, as described above.

Also, in upper structure 104a, semiconductor device 100 includes, in addition to control terminal 114, dielectric structure 116 covering first side 113, third side 402, and fourth side 404 of channel layer 112. Dielectric structure 116 is vertically between control terminal 114 and channel layer 112 and separates/insulates control terminal 114 from channel layer 112. In some examples, dielectric structure 116 and channel layer 112 can be formed in situ (e.g., in the same vacuumed environment) to reduce defect/contamination at the interface between dielectric structure 116 and channel layer 112. Upper structure 104a also includes a via 1102c and a metal interconnect 1104c (e.g., a metal contact) on and coupled to control terminal 114, where metal via 1102c and metal interconnect 1104c are surrounded by dielectric structure 128. In some examples, as shown in FIG. 11B, control terminal 114 may be formed with an additive patterning process (e.g., a damascene process) and may include a barrier layer, such as barrier layer 702 of FIG. 7A, and layer 117b on and surrounded by barrier layer 702. Barrier layer 702 can separate layer 117b from the surrounding dielectric structure. In the example of FIG. 11B, layer 117b can be material to facilitate electrical connection to via 1102c and metal interconnect 1104c, and may include copper (Cu), cobalt (Co), tungsten (W), or other materials described above. Barrier layer 702 can be a high work function metal to set the threshold voltage and may include Ruthenium (Ru) or Ru-based material. In some examples, as shown in FIG. 11C, control terminal 114 may include a stack of layer 117a, barrier layer 702, and layer 117b, with layer 117a vertically between barrier layer 702 and dielectric structure 116, in a similar configuration as FIG. 7A. In such examples, layer 117a can be a high work function metal (e.g., a noble metal) or a metal oxide, such as Pt, Pd, Ir, IrOx, RuO₂, or other materials described above. In both examples of FIGS. 11B and 11C, semiconductor device 100 may also include dielectric spacers 140a and 140b on two sides control terminal 114, which can be formed during the additive patterning process as to be described below. Dielectric spacers 140a and 140b may include low K dielectric material (e.g., SiO2) and may include the same or different dielectric material from dielectric structure 128.

Also, as shown in FIG. 11C, semiconductor device 100 can be asymmetric, where the lateral distance L1 between current terminal 122 (e.g., a source) and control terminal 124 can be shorter than the lateral distance L2 between current terminal 124 (e.g., a drain) and control terminal 124, to tolerate a higher breakdown VDS voltage.

In the examples of FIGS. 11A, 11B, 11C, 11D, and 11E, and in other examples described herein each of vias 1102a and 1102b can include a metal column, such as copper and tungsten. Each via can have various geometry footprints, such as a circular footprint or a non-circular footprint (e.g., a polygon such as a square, a rectangle, or otherwise having edges angled from each other). Also, each via and the metal interconnect coupled to it can have the same footprint, or different footprints (e.g., having different dimensions along the x/y axes as shown in the figures). In the example of FIG. 11B, each of vias 1102a and 1102b can include multiple layers/columns forming a vertical stack. For example, in the examples shown in FIG. 11D, via 1102a may include a layer 1120a and 1122a, where layer 1122a is vertically between channel layer 112 and layer 1120a, and layer 1122a abuts/contacts channel layer 112. Also, via 1102b may include a layer 1120b and 1122b, where layer 1122b is vertically between channel layer 112 and layer 1120b, and layer 1122b abuts/contacts channel layer 112. Top surface 1107a of layer 1122a, top surface 1107b of layer 1122b, and top surfaces 1109 of dielectric structure 1105 can be coplanar to form a planar surface on which channel layer 112 is formed. Layers 1120a and 1120b can include a metal, such as copper and tungsten, to facilitate electrical connection with metal interconnects 1104a and 1104b. Also, layers 1122a and 1122b can include a material different from layers 1120a/b to facilitate electrical connection with channel layer 112, such as a conductive oxide material (e.g., InSnO, IrOx, RuOx), or a noble metal (e.g., Ru, Ir, Pd, Pt, Ni, Co, Pt, Ru, Ti, Ir). Also, each of vias 1102a and 1102b (and 1102c) can be formed with an additive patterning process (e.g., a damascene process) and may include a barrier layer similar to barrier layers 702 and 720a-d shown in FIG. 7A.

As to be described below, the arrangements of FIGS. 11A-D, where channel layer 112 is formed on current terminals 122 and 124, can reduce the need to etch channel layer 112 to form contacts between current terminals 122/124 and channel layer 112. This can simplify the fabrication operation of semiconductor device 100. Moreover, by avoiding inadvertently introducing defects to areas of channel layer 112 under (or proximate) control terminal 114, the properties of channel layer 112 (e.g., charge mobility, current density, etc.) can also be improved. Further, by having control terminal 114 and current terminals 122/124 on an opposing sides of channel layer 112, the alignment between control terminal 114 and each of current terminals 122/124 can be relaxed, which in turn can reduce the lateral spacing between control terminal 114 and each of current terminals 122/124. Such arrangements can shrink the footprint of the TFT 110.

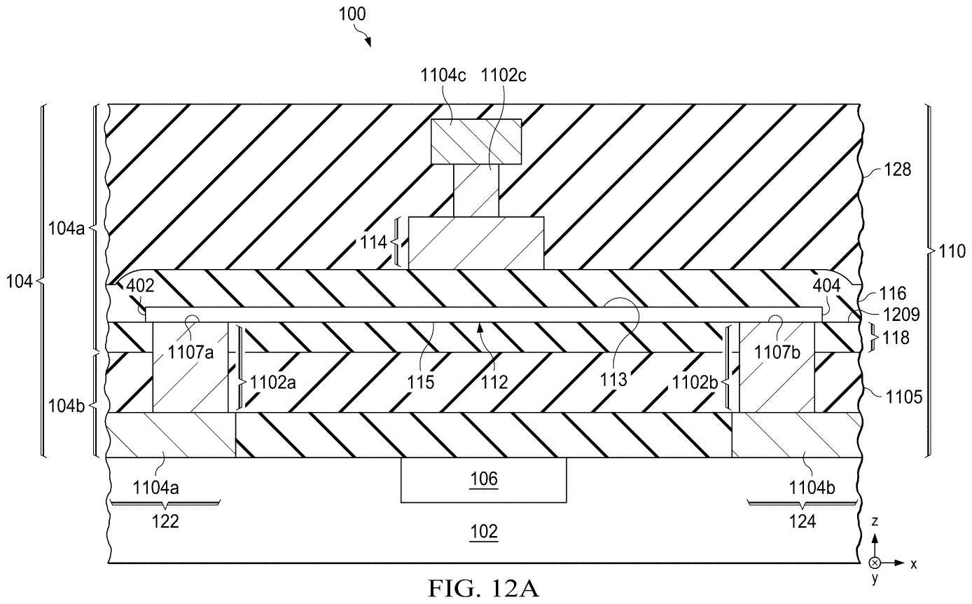

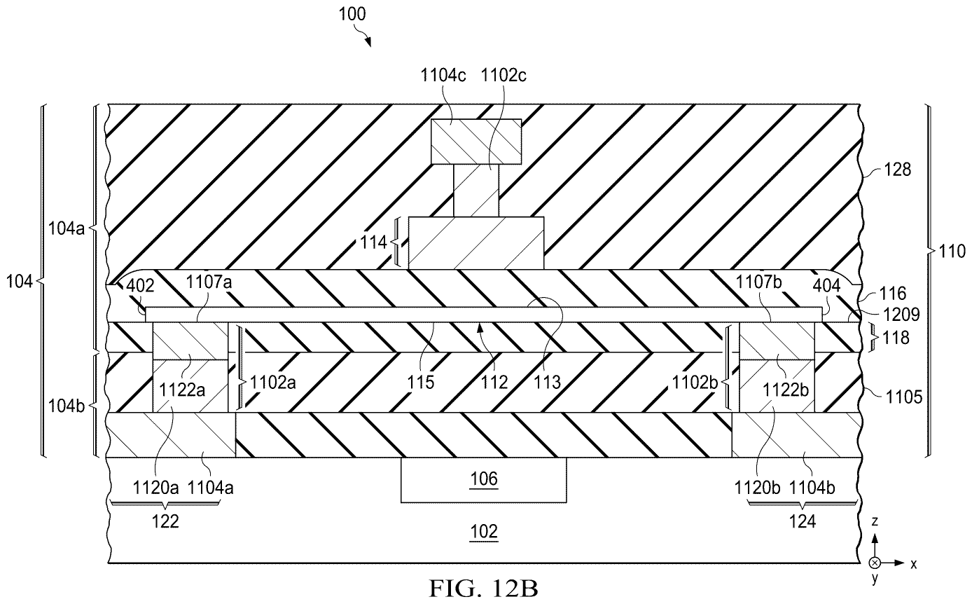

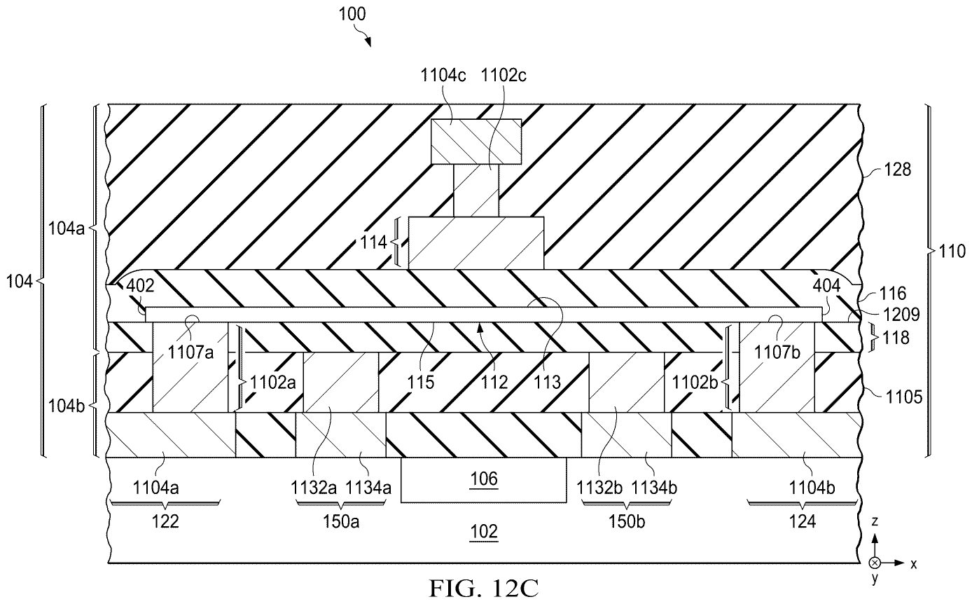

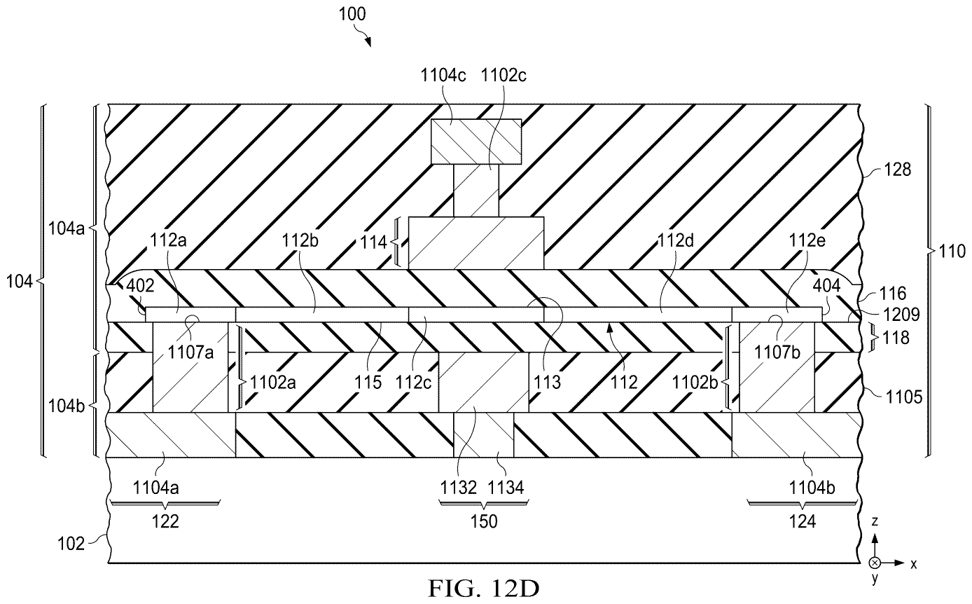

FIGS. 12A, 12B, 12C and 12D illustrate cross sections of additional examples of semiconductor device 100 including TFT 110 having dielectric structure 118 on second side 115 of channel layer 112. Dielectric structure 118 can provide various functions. First, as described above, dielectric structure 118 can provide a planar surface on which channel layer 112 is formed, which can ensure that at least the part of channel layer 112 under control terminal 114 is planar to improve uniformity of the threshold voltage across channel layer 112. Also, as to be described in subsequent figures, in fabricating some examples of vias 1102a and 1102b that have multiple layers/columns forming a vertical stack, a planarization operation (e.g., a CMP operation) can be performed to remove excess via materials from the planar surface of dielectric structure 118. To facilitate the CMP operation, dielectric structure 118 can have a material that is more resistant to the CMP operation than the rest of the dielectric structure (e.g., dielectric structure 1105) of lower structure 104b. For example, dielectric structure 118 can include Al₂O₃, while the rest of the dielectric structure of lower structure can include SiO₂. Further, dielectric structure 118 can provide insulation of channel layer 112 from a bottom gate (e.g., control terminal 150a) and/or a field plate (e.g., control terminal 150b) formed in lower structure 104b.

Specifically, as shown in FIG. 12A, each of vias 1102a and 1102b includes a single metal column (e.g., copper or tungsten) that penetrates through dielectric structure 118 and abuts/contacts channel layer 112. Top surface 1107a of via 1102a, top surface 1107b of via 1102b, and top surface 1209 of dielectric structure 118 can be coplanar to form a planar surface on which channel layer 112 is formed. Also, as shown in FIG. 12B, in some examples, each of vias 1102aand 1102b includes multiple layers forming a vertical stack (e.g., layers 1120a and 1122a for via 1102a, layers 1120b and 1122b for via 1102b), and each of vias 1102a and 1102b penetrates through dielectric structure 118 and abuts/contacts channel layer 112. Further, as shown in FIG. 12C, semiconductor device 100 may include, as part of lower structure 104b, control terminals 150a and 150b in addition to current terminals 122 and 124 on second side 115 of channel layer 112. Control terminal 150a can include a metal via 1132a and a metal interconnect 1134a, and control terminal 150b can include a metal via 1132b and a metal interconnect 1132b. Control terminal 150a can overlap a region of channel layer 112 laterally between current terminal 122 and control terminal 114, and control terminal 150b can overlap a region of channel layer 112 laterally between current terminal 124 and control terminal 114. Control terminals 150a and 150b are separated (and insulated) from channel layer 112 by dielectric structure 118.

In some examples, as shown in FIG. 12D, control terminals 114 and 150 can be directly overlapping each other. Channel region 112a of channel layer 112 overlaps with via 1102a of current terminal 122, channel region 112b of channel layer 112 overlaps with an area between via 1102a and control terminals 114/150, channel region 112c of channel layer 112 is vertically between control terminals 114 and 150. Also, channel region 112e of channel layer 112 overlaps with via 1102b of current terminal 124, and channel region 112d of channel layer 112 overlaps with an area between via 1102b and control terminals 114/150. In some examples of FIG. 12D, control terminal 150 can enable/disable the channel in channel layer 112 between current terminals 122 and 124, while control terminal 114 can set the threshold voltage at control terminal 150 for enabling the channel. In such examples, metal via 1132 can include a stack of metal layers, such as a high work function layer 117a abutting dielectric structure 118 to effectively control the channel formation in channel layer 112 and achieve a positive threshold voltage, and a layer 117b between layer 117a and metal interconnect 1134 to improve electrical connection.

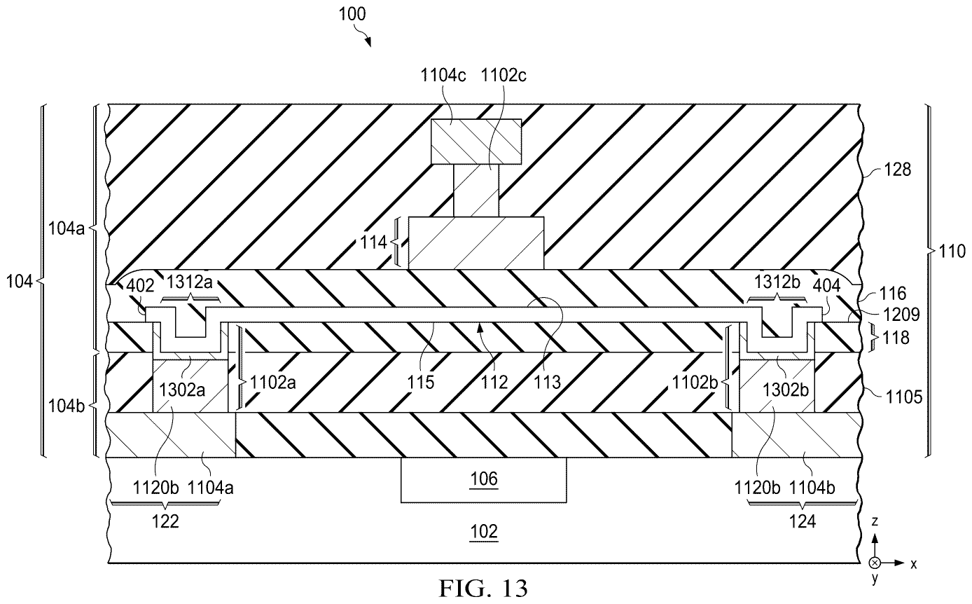

FIG. 13 illustrates another example of semiconductor device 100 including thin film transistor 100 having dielectric structure 118 on second side 115 of channel layer 112. In the examples shown in FIG. 13, via 1102a includes a recess structure 1302a and layer 1120a forming a vertical stack, and via 1102b includes a recess structure 1302b and layer 1120b forming another vertical stack. Recess structures 1302a and 1302b penetrate through dielectric structure 118. Recess structures 1302a and 1302b are not coplanar with top surface 1209 of dielectric structure 118. Channel layer 112 is formed on dielectric structure 118 and on recess structures 1302a and 1302b. Channel layer 112 can be formed by a thin film deposition process (e.g., atomic layer deposition) and can have a uniform thickness. Accordingly, channel layer 112 may include recess regions 1312a conformal to recess structure 1302a and recess regions 1312b conformal to recess structure 1302b. Accordingly, each of current terminals 122 and 124 can include a recess structure at the interface between the via and channel layer 112. The recess structures in FIG. 13 can improve the electrical connection (and reduce contact resistance) between channel layer 112 and each of vias 1102a and 1102b. The recess process enables the use of different materials at the top of the via structure versus the standard via materials present at the bottom of the via.

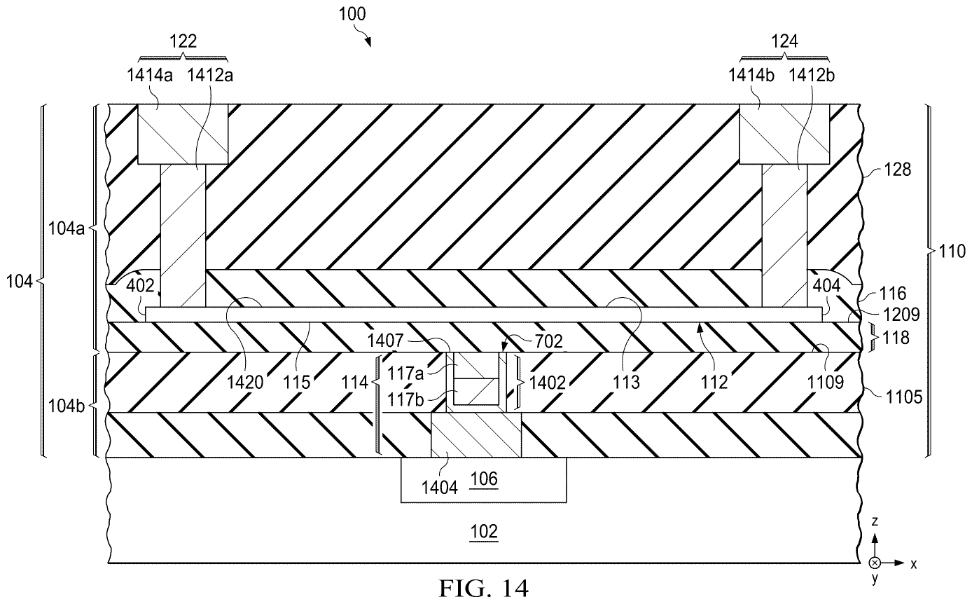

FIG. 14 illustrates additional examples of semiconductor device 100 including TFT 110 having dielectric structure 118 on second side 115 of channel layer 112. In the examples shown in FIG. 14, control terminal 114 is part of lower structure 104b and on second side 115 of channel layer 112 and separated from channel layer 112 by dielectric structure 118. Control terminal 114 includes a via 1402 and a metal interconnect 1404, where via 1402 is vertically between dielectric structure 118 and metal interconnect 1404.

In the examples shown in FIG. 14, via 1402 may include layers 117a and 117b forming a stack. Layer 117a has a high work function metal and abuts dielectric structure 118 to effectively control the channel formation in channel layer 112 and achieve a positive threshold voltage, and layer 117b is between layer 117a. In some examples where via 1402 is formed by an additive process (e.g., a damascene process), via 1402 may also include a barrier layer (e.g., barrier layer 702) to separate layers 117a and 117b from dielectric structure 1105. Top surface 1407 of via 1402 can be coplanar with top surface 1109 of dielectric structure 1105 to provide a planar surface on which dielectric structure 118 is formed. This in turn allows dielectric structure 118 to be planar and provide a planar top surface 1209 on which channel layer 112 is formed. Accordingly, channel layer 112, including the region overlapping control terminal 114, can be planar, which can improve the uniformity of the threshold voltage of TFT 110 across channel layer 112.

Also, in the examples shown in FIG. 14, current terminals 122 and 124 are on first side 113 of channel layer 112. Current terminal 122 includes a via 1412a and a metal interconnect 1414a, and current terminal 124 includes a via 1412b and a metal interconnect 1414b. Via 1412a is vertically between metal interconnect 1414a and channel layer 112, and via 1412b is vertically between metal interconnect 1414b and channel layer 112. Both vias 1412a and 1412b can be formed by a metal patterning process or an additive process (e.g., a damascene process). In some examples (not shown in the figures), current terminals 122/124 and control terminal 114 can all be on second side 115 of channel layer 112

In some examples, vias 1412a and 1412b can be formed on a planar top surface 1420 of channel layer 112 on first side 113 without etching channel layer 112, which can reduce the need to etch channel layer 112 for contact formation between channel layer 112 and the current terminals, which in turn can avoid inadvertently introducing defects to areas of channel layer 112 under (or proximate) control terminal 114, the properties of channel layer 112 (e.g., charge mobility, current density, etc.) can also be improved. Further, in examples where current terminals 122/124 and control terminal 114 on opposing sides of channel layer 112, the alignment between control terminal 114 and each of current terminals 122/124 can be relaxed, which in turn can reduce the lateral spacing between control terminal 114 and each of current terminals 122/124, and the footprint of the TFT 110 can be shrunk.

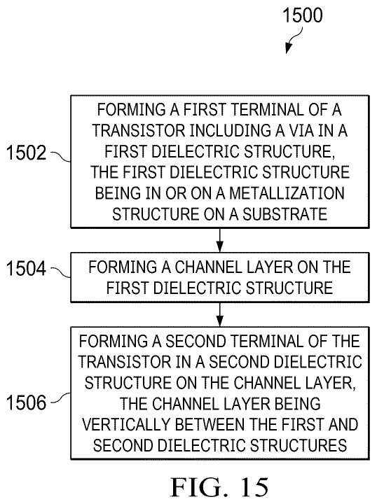

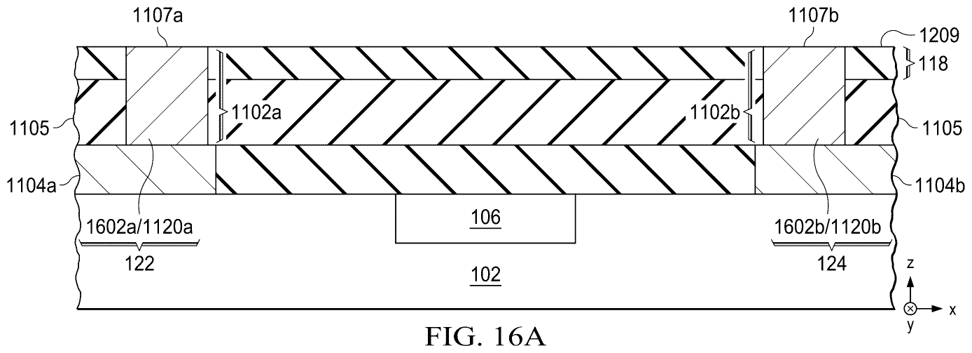

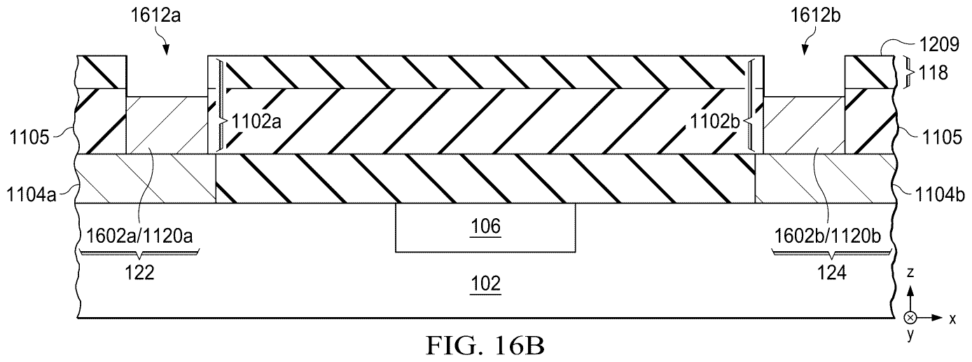

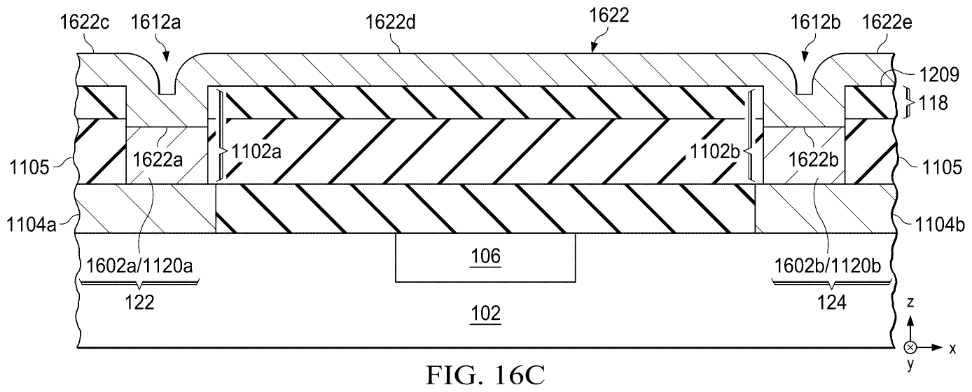

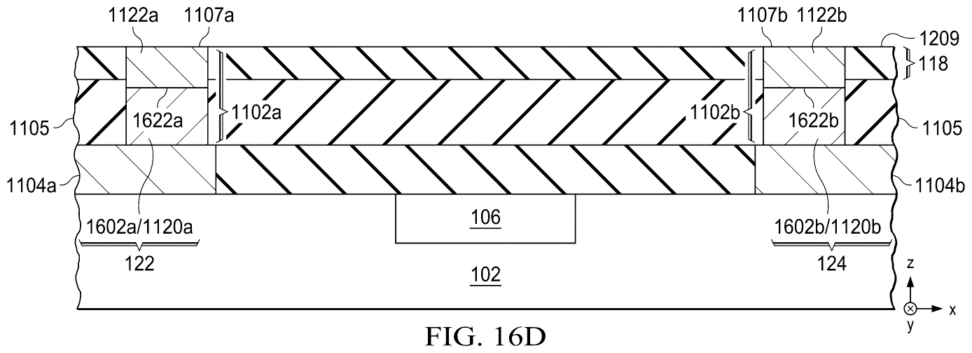

FIG. 15 illustrates a flowchart of examples of a method 1500 of fabrication of a semiconductor device (e.g., semiconductor device 100) including a thin film semiconductor device, such as TFT 110 and thin film bidirectional switch 200 described in FIGS. 11A-14. The techniques described in FIG. 15 and in subsequent figures can be combined with various techniques described in method 800 of FIG. 8 and FIG. 9A-1 to FIG. 10I. In some examples, method 1500 can be part of a BEOL process, or otherwise can be performed in an environment compatible with a BEOL process (e.g., at or below 400° C.). FIGS. 16A-20B illustrate examples of cross sections of semiconductor device 100 during various operations of method 1500.

In operation 1502, a first terminal (e.g., current terminals 122/124 and control terminals 150a/b of FIGS. 11A-13, control terminal 114 of FIG. 14) of TFT 110 including a via (e.g., vias 1102a, 1102b, 1402) is formed in a first dielectric structure, the first dielectric structure being in or on a metallization structure on a substrate. In the examples shown, the first dielectric structure can include dielectric structure 1105, which can be part of lower structure 104b of metallization structure 104. In some examples, as shown in FIGS. 12A-12C, the first dielectric structure can include dielectric structure 118, where dielectric structure 118 can provide a planar surface on which channel layer 112 can be formed.

In some examples, the vias can have multiple layers of different materials, such as layers 1122a and 1120a of via 1102a, layers 1122b and 1120b of via 1102b, and layers 117a and 117b of via 1402. Each via may also a top surface that is coplanar with a surface of the first dielectric structure, and the vias and the first dielectric structure together can form a planar surface on which channel layer 112 can be formed, such as vias 1102a/1102b of FIGS. 11-12C and via 1402 of FIG. 14. FIGS. 16A-16E illustrate examples of operations included in operation 1502. Referring to FIG. 16A, a first metal layer (e.g., copper or tungsten) can be formed (e.g., on metal interconnects 1104a and 1104b and on semiconductor substrate 102) and then patterned, and the first dielectric structure (including dielectric structures 118 and 1105 as shown) can be formed around the patterned metal layers 1602a and 1602b. In some examples, such as shown in FIGS. 11A-11C, the patterned metal layers 1602a and 1602b can become vias 1102a and 1102b. Patterned metal layers 1602a and 1602b penetrate through dielectric structure 118, and top surface 1107a of patterned metal layer 1602a and top surface 1107b of patterned metal layer 1602b can be coplanar with top surface 1209 of dielectric structure to form a planar surface.

Referring to FIG. 16B, part of patterned metal layers 1602a and 1602b are removed to form, respectively, a recess region 1612a and a recess region 1612b. The patterned metal layers can be removed by, for example, a dry etch operation, a wet etch operation, etc. The remaining metal layer 1602a can become layer 1120a of FIG. 11D, and the remaining metal layer 1602b can become layer 1120b of FIG. 11D.

Referring to FIG. 16C, a second layer of material 1622 is formed on dielectric structure 118 and in recess regions 1612a and 1612b. Second layer 1622 may include a conductive oxide material (e.g., InSnO, InO, SnO, doped ZnO, IrOx, RuOx), or a noble or near noble metal (e.g., Ru, Ir, Pd, Pt, Ni, Co, Pt, Ru, Ti, Ir). In some examples, a conductive barrier layer can be formed beneath layer 1622. The conductive barrier can be a conductive nitride or carbide material that also is a good hydrogen diffusion barrier. Example materials might be those listed tantalum nitride (TaN), tantalum carbo nitride (TaCN), titanium nitride (TiN), titanium carbo nitride (TiCN), titanium silicon carbo nitride (TiSiCN), tantalum silicon carbo nitride (TaSiCN) ruthenium (Ru), ruthenium nitride (RuN), ruthenium carbo nitride (RuCN), ruthenium silicon carbo nitride (RuSiCN). Second layer 1622 can be formed by a deposition operation, such as atomic layer deposition (ALD) for the InSnO and/or physical vapor deposition (PVD) for the metal oxides and elemental metals. Second layer 1622 can be conformal to the top surface 1209 of dielectric structure 118 and recess regions 1612a and 1612b, and can have a thickness that equals or exceeds the depth of recess regions 1612a and 1612b and the thickness of dielectric structure 118. For example, the second layer 1622 can include a region 1622a that fills recess region 1612a, a region 1622b that fills recess region 1612b, and regions 1622c, 1622d, and 1622e on dielectric structure 118.

Referring to FIG. 16D, parts of second layer of material 1622, including regions 1622c-e on dielectric structure 118 can be removed to expose top surface 1209, while regions 1622a and 1622b in recess regions 1612a and 1612b remain and become, respectively, layers 1122a and 1122b of FIG. 11D, thus forming vias 1102a and 1102b. Layer 1122a can have top surface 1107a, and layer 1122b can have top surface 1107b. The removal of second layer of material 1622 can be performed using a planarization operation, such as a chemical and mechanical planarization (CMP) operation, so that the top surfaces 1107a and 1107b can be coplanar with top surface 1209 to form a planar surface, and channel layer 112 can be subsequently formed on the planar surface as a planar layer. Also, in a case where a conductive barrier layer is formed beneath layer 1622, part of the conductive barrier layer can also be removed, and the remaining conductive barrier layer can be on the sides and the bottom of region 1622a (and layer 1122a) and of region 1622b (and layer 1122b).

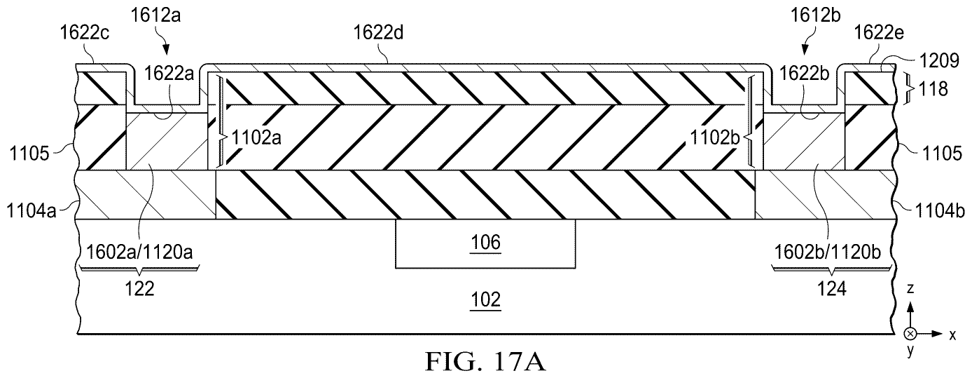

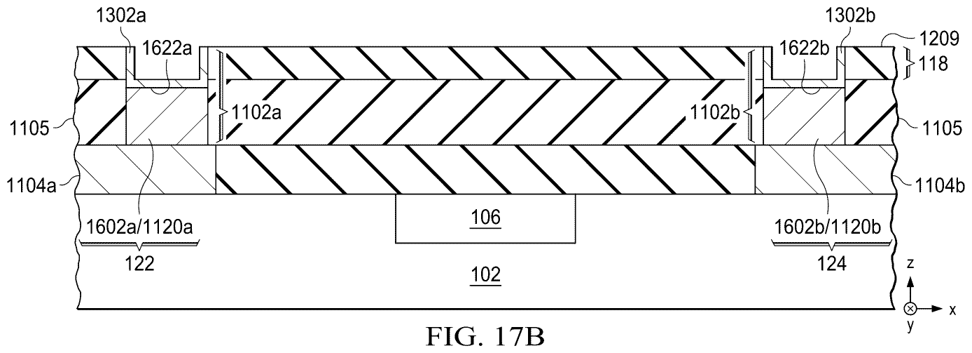

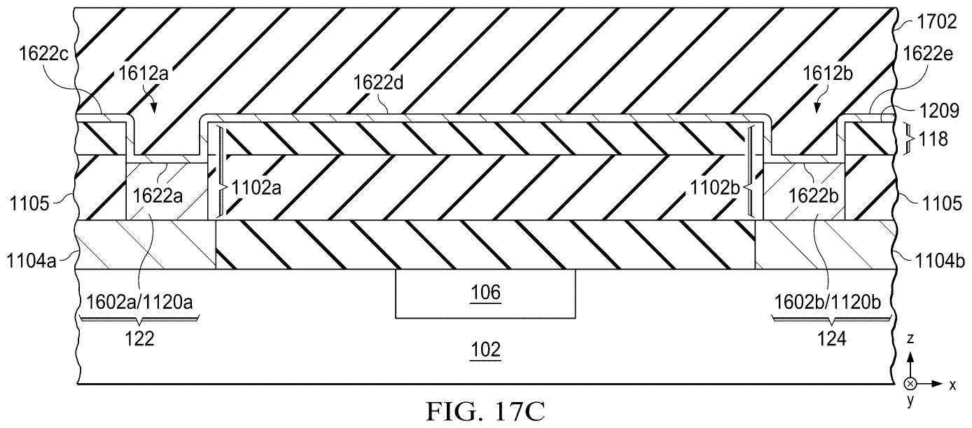

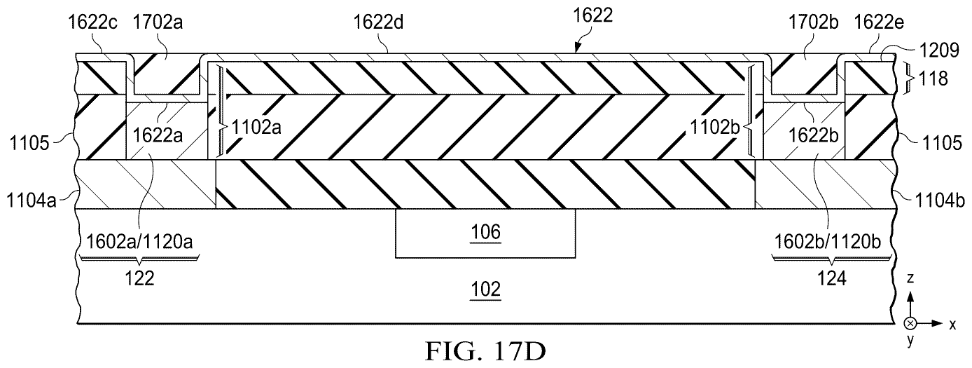

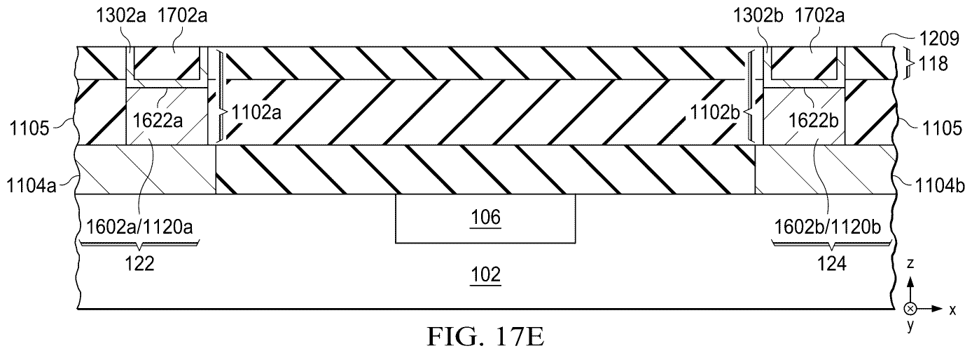

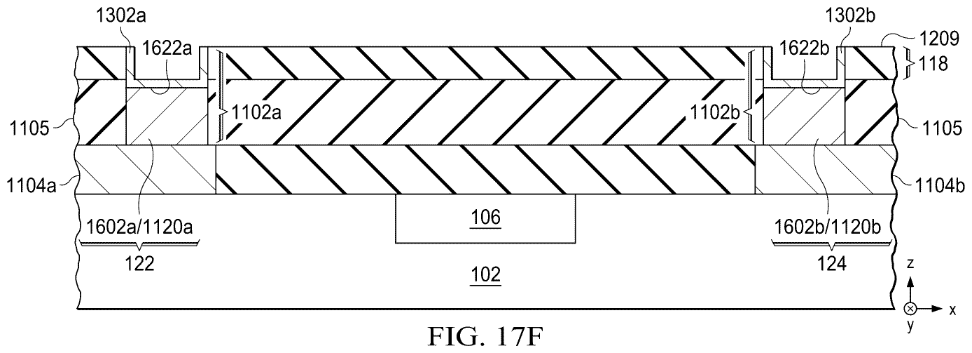

In some examples, the vias can have recess structures, such as recess structures 1302a and 1302b, to reduce contact resistance. FIGS. 17A-17F illustrate example operations to form vias having recess structures, as part of operation 1502. The example operations can be subsequent to the operation shown in FIG. 16B where regions 1612a and 1612b are formed and second layer 1622 is formed and then patterned to form recess structures 1302a and 1302b.

FIGS. 17A and 17B illustrate examples of operations in which second layer 1622 is patterned by a planarization operation. Referring to FIG. 17A, second layer 1622 is formed on dielectric structure 118 and in recess regions 1612a and 1612b. In the examples shown in FIG. 17A, the thickness of second layer 1622 is smaller than the depth of recess regions 1612a and 1612b, so that regions 1622a and 1622b do not fill recess regions 1612a and 1612b.

Referring to FIG. 17B, parts of second layer 1622 on dielectric structure 118, including regions 1622c, 1622d, and 1622e, are removed, while regions 1622a and 1622b in recess regions 1612a and 1612b remain and become recess structures 1302a and 1302b. The parts of second layer 1622 can be removed by, for example, a planarization operation (e.g., CMP) until dielectric structure 118 is exposed.

FIGS. 17C-17F illustrate examples of operations in which second layer 1622 is patterned by an etch operation. Referring to FIG. 17C, after second layer 1622 is formed on dielectric structure 118 and in recess regions 1612a and 1612b, a dielectric structure 1702 can be formed on second layer 1622 and fills recess regions 1612a and 1612b. Referring to FIG. 17D, part of dielectric structure 1702 can be removed by a planarization operation (e.g., CMP) until regions 1622c, 1622d, and 1622e of second layer 1622 are exposed, and regions 1702a and 1702b of dielectric structure 1702 remain in recess regions 1612a and 1612b. Referring to FIG. 17E, the exposed regions 1622c, 1622d, and 1622e of second layer 1622 can be removed by etching, while regions 1622a and 1622b of second layer 1622 are covered by regions 1702a and 1702b of dielectric structure 1702 and are not etched. Referring to FIG. 17F, regions 1702a and 1702b of dielectric structure 1702 are removed, and regions 1622a and 1622b of second layer 1622 can become recess structures 1302a and 1302b.

Referring again to FIG. 15, in operation 1504, a channel layer (e.g., channel layer 112) can be formed on the first dielectric structure (e.g., dielectric structures 1105 and/or 118). Channel layer 112 can include for example, a conductive oxide (e.g., In2O3), or carbon nanotubes. In the case of conductive oxide, channel layer 112 can be formed by an atomic layer deposition operation to form a thin (e.g., a few nanometers) and planar layer on a planar surface of the first dielectric structure, which can improve the uniformity of the threshold voltage of the transistor. In a case where the first terminal has a recess structure (e.g., recess structures 1302a/1302), channel layer 112 may also have recess regions conformal to the recess structure to reduce contact resistance.

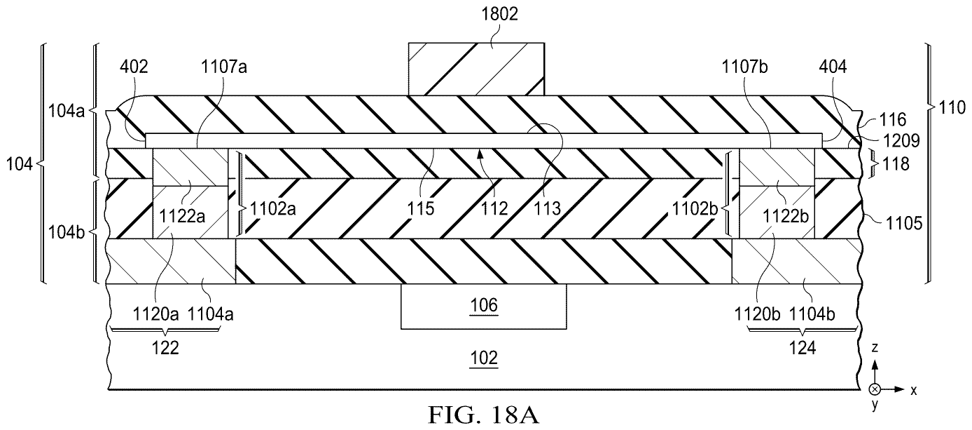

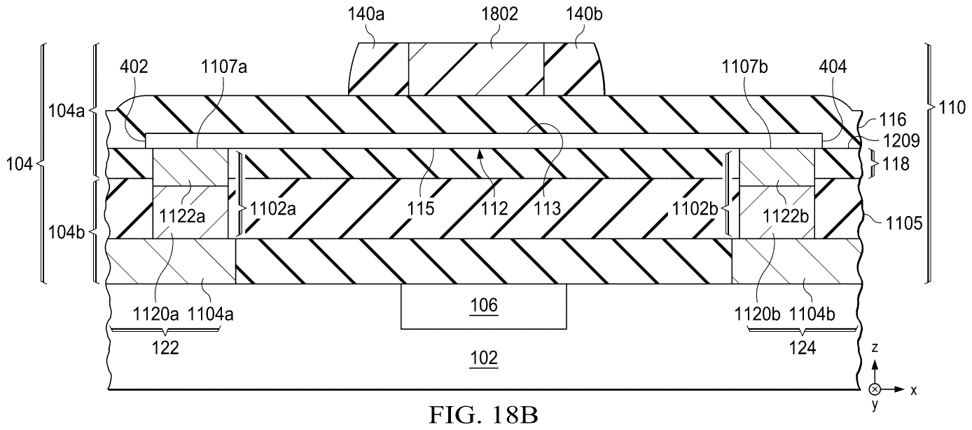

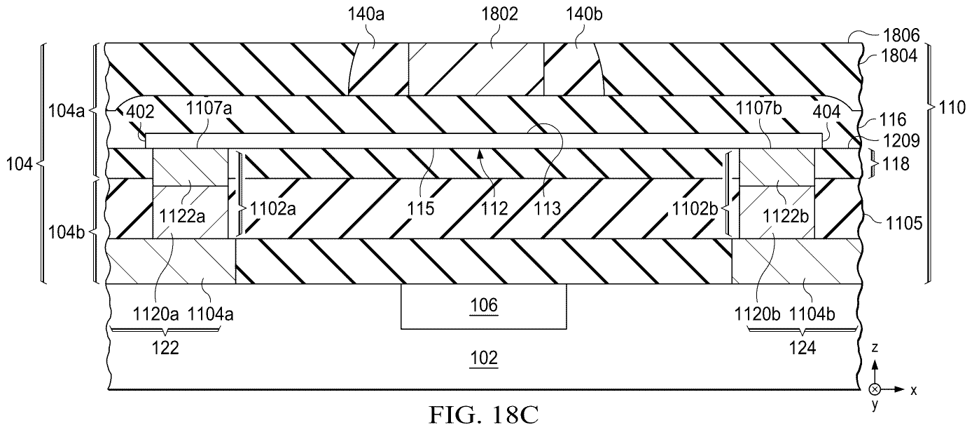

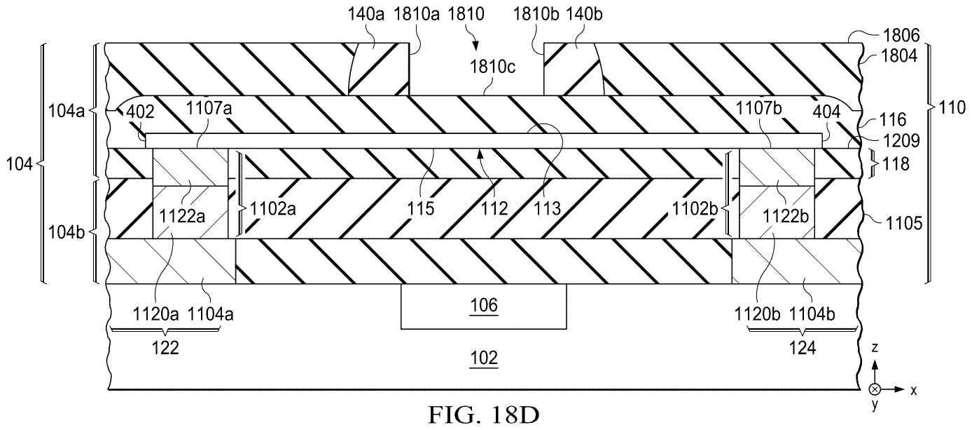

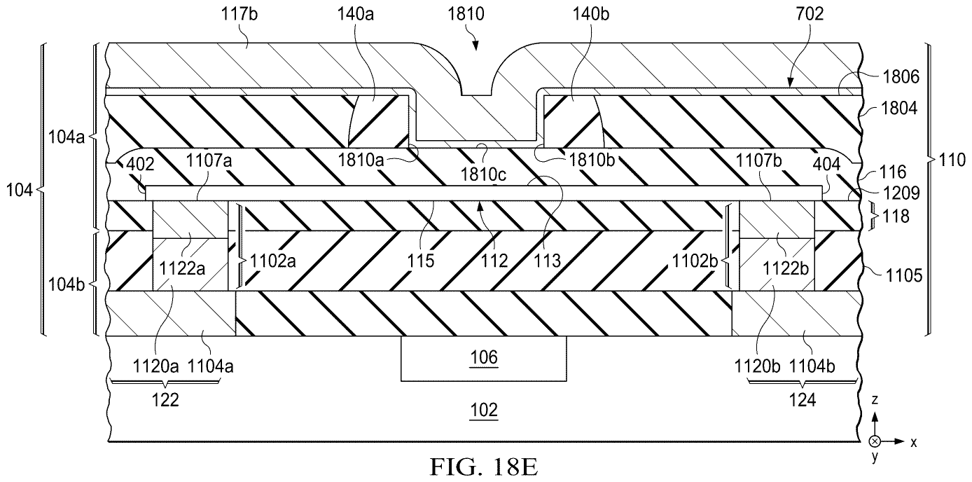

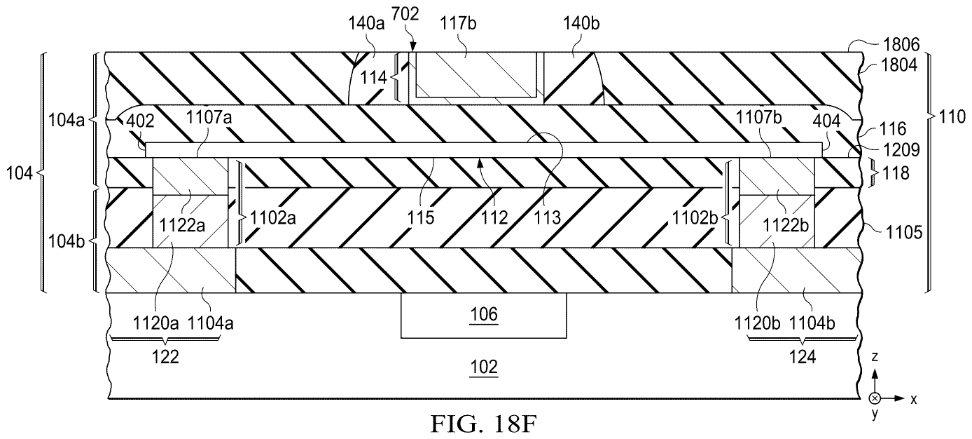

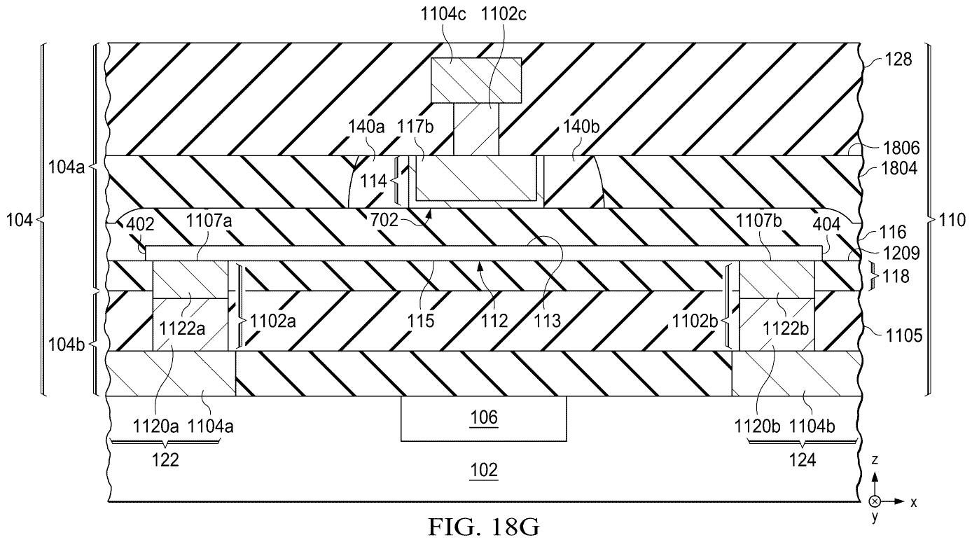

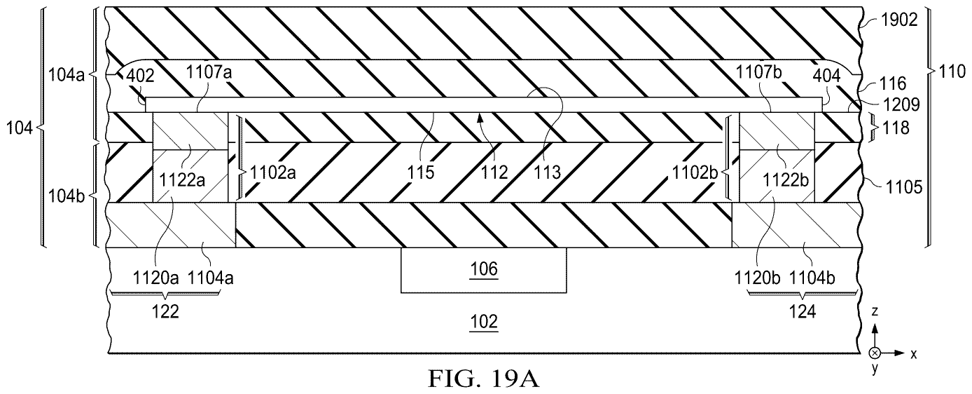

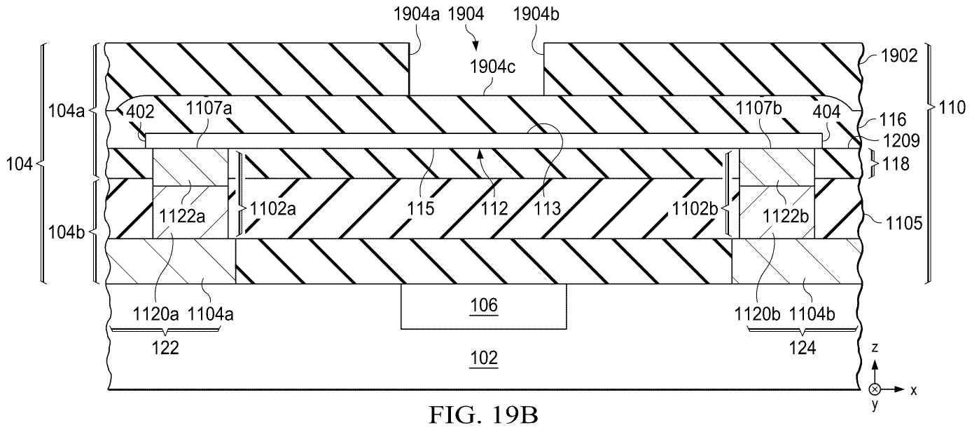

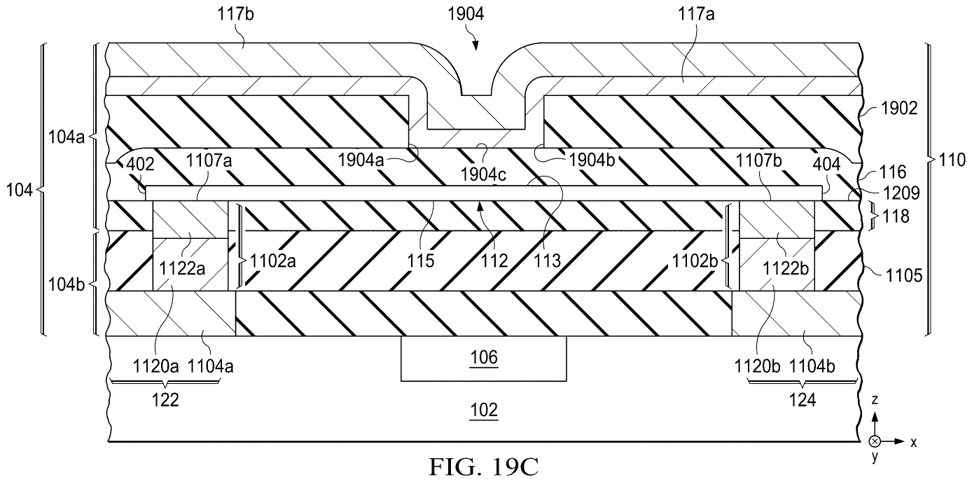

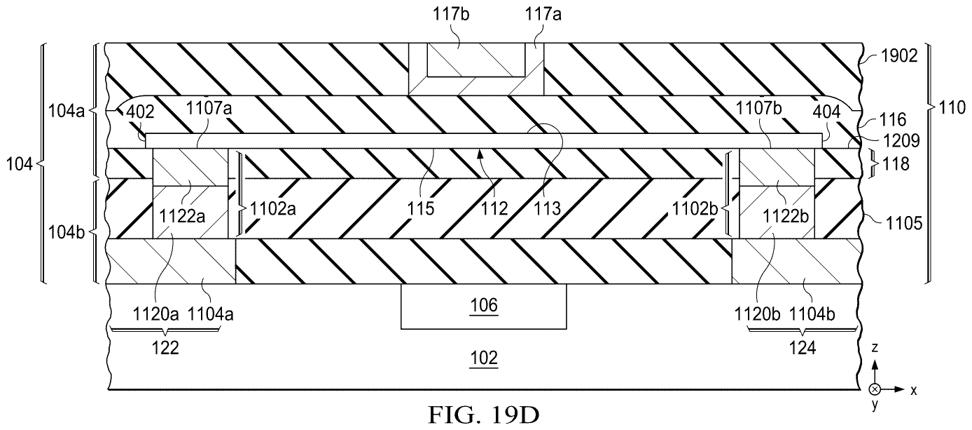

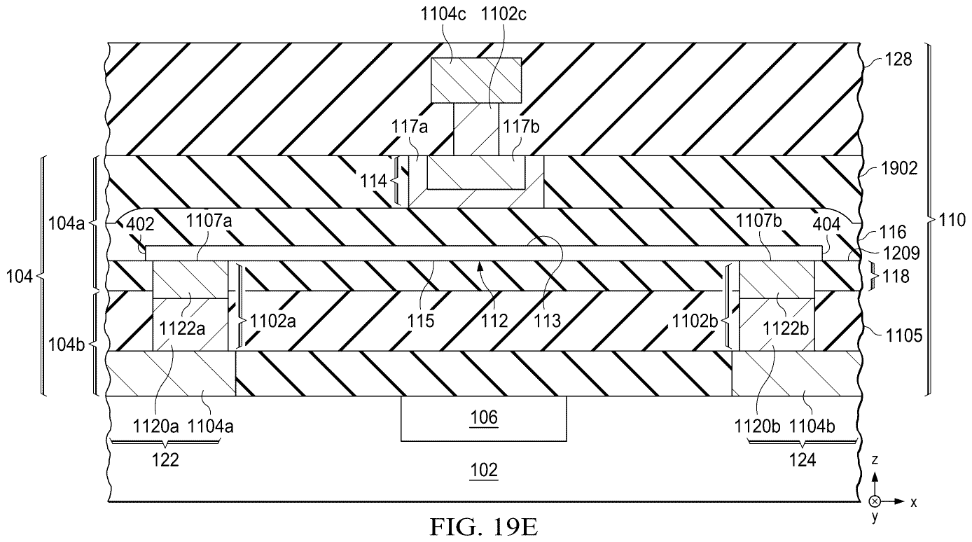

Also, in operation 1506, a second terminal (e.g., control terminal 114 of FIGS. 11A-13) of the transistor is formed in a second dielectric structure (e.g., dielectric structure 128) on the channel layer, in which the channel layer is vertically between the first and second dielectric structures. Operation 1506 can include an additive patterning process (e.g., a damascene process), as shown in FIGS. 18A-18G to form examples of control terminal 114 shown in FIG. 11B, or a metal patterning process, as shown in FIGS. 19A-19E to form other examples of control terminal 114.

FIGS. 18A-18G illustrate example operations of forming the second terminal, as part of operation 1506, with an additive patterning process. Referring to FIG. 18A, channel layer 112 can be formed on dielectric structures 118/1105, and dielectric structure 116 can be formed on first side 113 of channel layer 112, with dielectric structure 116 and dielectric structures 118/1105 on second side 115 of channel layer 112. As described above, dielectric structure 116 and channel layer 112 can be formed in situ to reduce defect/contamination at the interface between dielectric structure 116 and channel layer 112. Also, a dummy/sacrificial layer 1802 can be formed on dielectric structure 116, with dielectric stricture 116 being vertically between dummy/sacrificial layer 1802 and channel layer 112. Dummy/sacrificial layer 1802 can define the footprint and location of control terminal 114. Dummy/sacrificial layer 1802 can made of a material that is easier to etch than the metal layers of control terminal 114 to be formed in subsequent operations. For example, in examples where control terminal 114 includes a noble metal for layer 117b and copper for layer 117a, dummy/sacrificial layer 1802 can include titanium (Ti), silicon dioxide (SiO₂), amorphous silicon (Si), etc. The material can be deposited on dielectric structure 116 and then can be patterned to form dummy/sacrificial layer 1802.

In some examples, channel layer 112 and dielectric structure 116 are formed in a different vacuumed environment (and not in situ) from the formation of dielectric structure 118. In some examples, part of a dielectric structure 118 can also be formed in situ with channel layer 112 and dielectric structure 116. In such examples, deposition of dielectric structure 118 can be performed in a selective ALD process only selectively occurs on a dielectric seed layer where there is no metal interconnects (e.g., vias).

In some examples (not shown in FIG. 18A), a high work function metal layer 117a can be formed on dielectric structure 116 and is then patterned using a mask to define the footprint and location of control terminal 114. Dummy/sacrificial layer 1802 is then formed on the patterned metal layer 117a. In such examples, the barrier layer to be formed in subsequent operation needs not be a high work function metal, and may include Ta, TaN, or other barrier metal material described above.

Referring to FIG. 18B, dielectric spacers 140a and 140b can be formed on two sides of dummy/sacrificial layer 1802 (and layer 117a if present). Dielectric spacers 140a and 140b can be formed using techniques similar to those described in FIG. 9I to FIG. 9J, where a layer of dielectric material (e.g., dielectric material 930, such as SiO₂) is formed on dummy/sacrificial layer 1802, and the dielectric material can be patterned by an anisotropic etching process that etches mostly vertically (e.g., along the z-axis in FIG. 18B) to form dielectric spacers 140a and 140b.

Referring to FIG. 18C, a dielectric structure 1804 (e.g., one or more layers of SiO₂, or a different dielectric material from dielectric spacers 140a and 140b) can be formed over and covering dielectric structure 116, dielectric spacers 140a and 140b, and dummy/sacrificial layer 1802. A planarization operation (e.g., CMP) can be performed to remove part of dielectric structure 1804 and/or parts of dielectric spacers 140a and 140b to expose dummy/sacrificial layer 1802. The planarization operation can be performed to provide a planar surface 1806 on dielectric structure 1804 for subsequent deposition of metal layers.

Referring to FIG. 18D, dummy/sacrificial layer 1802 is removed (e.g., by etching), leaving a recess 1810 having sidewalls 1810a/b provided by dielectric spacers 140a/140b and a bottom surface 1810c provided by dielectric structure 116 or layer 117a. Referring to FIG. 18E, barrier layer 702 and layer 117b, are formed on planar surface 1806 of dielectric structure 1804 and in recess 1810, where the layers can be conformal to the sidewalls and the bottom surface of recess 1810. The combined thicknesses of barrier layer 702 and layer 117b can be the same or exceed the depth of recess 1810.

Also, referring to FIG. 18F, a planarization operation (e.g., CMP) can be performed to remove parts of barrier layer 702 and layers 117a and 117b on planar surface 1806 of dielectric structure 1804, and parts of 117b protruding out of recess 1810. The remaining parts of barrier layer 702 and layer 117b in recess 1810 can become control terminal 114. This is followed by forming via 1102c and metal interconnect 1104c in dielectric structure 128 on control terminal 114, as shown in FIG. 18G.

FIGS. 19A-19E illustrate example operations of forming the second terminal, as part of operation 1506, with a metal patterning process. Referring to FIG. 19A, after forming a channel layer 112 on dielectric structures 118/1105, a dielectric structure 116 can be formed on first side 113 of channel layer 112, with dielectric structure 116 and dielectric structures 118/1105 on second side 115 of channel layer 112. Also, a dielectric structure 1902 can be formed on dielectric structure 116, with dielectric structure 116 being vertical between dielectric structure 1902 and channel layer 112.

Referring to FIG. 19B, dielectric structure 1902 can be patterned to expose part of dielectric structure 116 and form a recess 1904 having sidewalls 1904a/b and a bottom surface 1904c provided by the exposed dielectric structure 116. Referring to FIG. 19C, layers 117a and 117b are formed on the patterned dielectric structure 1902 and in recess 1904, where the layers can be conformal to the sidewalls and the bottom surface of recess 1904. The combined thicknesses of layers 117a and 117b can be the same or exceed the depth of recess 1904.

Also, referring to FIG. 19D, a planarization operation (e.g., CMP) can be performed to remove parts of layers 117a and 117b on dielectric structure 1902, and parts of layers 117a and 117b protruding out of recess 1904. The remaining parts of layers 117a and 117b in recess 1904 can become control terminal 114. This is followed by forming via 1102c and metal interconnect 1104c in dielectric structure 128 on control terminal 114, as shown in FIG. 19E.

Examples of thin film devices can support various applications. For example, semiconductor device 100 can implement a half bridge with two instances of thin film transistors 110, where each thin film transistor can have asymmetric drain and source (e.g., by having dielectric spacer 140b with a drain extension, as shown in FIGS. 1B, and 3A-7, and/or field plate 150b, to support high voltage applications. The drivers and the control circuit for the thin film transistors can be implemented as FEOL devices (e.g., as part of FEOL circuitries 106) and coupled to thin film transistors 110 via metal interconnects in metallization structure 104. As another example, semiconductor device 100 can implement instances of thin film transistors 110 to support high speed applications, such as radio frequency (RF) applications, logic devices, etc., where thin film transistors 110 can have dielectric spacers 140a/140b having sub-lithography dimensions to reduce the parasitic gate capacitance and to support high switching/operation speed. As yet another example, semiconductor device 100 can implement a TFT 110 with self-calibration capabilities, where a calibration circuit can be implemented as part of FEOL circuit 106 to measure an operation condition of thin film transistor (e.g., process/voltage/temperature (PVTs)), and provide a signal to control terminal 150a (or control terminal 114 of FIG. 12D) to set the threshold voltage of channel layer 112 of TFT 110 based on the measured operation condition, to reduce the variation of the threshold voltage of TFT 110 due to PVT variation.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. In case of SWCNT, which are ambipolar, the biasing of the gates (top and bottom) and the surrounding oxide charge and/or the metal contact selection, can preferentially use only electrons or holes in the main channel conduction, hence forming NMOS or PMOS, respectively.

For example, in case of metal oxide channel layer, a field effect transistor (“FET”) with holes as dominant carrier, a p-channel FET (PFET) using a material such as ZnO, NiO, CuAlO2, CuCrO2 and SnO for the channel, may be used in place of or in conjunction with the devices described herein. Also, if one or both of the metal terminals of the device use specific metals (such as Pt, Pd, Ir, Ru, IrOx, RuO2) that create a Schottky barrier contact, the device can be used as a Schottky barrier diode, or back to back Schottky barrier diodes. Furthermore, two of the terminals can be used as terminals for a capacitor, or varactor and possibly a third terminal can be used to vary that capacitance. Furthermore, the devices may be implemented in/over a silicon substrate (Si), a silicon carbide substrate (SiC), a gallium nitride substrate (GaN), a gallium arsenide substrate (GaAs), glass, ceramic or composite materials.

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. A method comprising:
forming a stack structure including a first dielectric structure, a channel layer, and a second dielectric structure, in which the first and second dielectric structures are on opposing sides of the channel layer;
forming a third dielectric structure on the first dielectric structure, in which the first dielectric structure is between the third dielectric structure and the channel layer;
patterning the third dielectric structure to form a dielectric spacer;
patterning the first dielectric structure by a wet etching operation to expose a first part of the channel layer and a second part of the channel layer, in which the dielectric spacer is between the first part and the second part of the channel layer;
forming a first current terminal of a transistor on the first part of the channel layer; and
forming a second current terminal of the transistor on the second part of the channel layer.

2. The method of claim 1, wherein the channel layer includes at least one of: a metal oxide material, or carbon nanotubes.

3. The method of claim 1, wherein the first and second dielectric structures and the channel layer are formed in situ.

4. The method of claim 1, wherein the dielectric spacer is a first dielectric spacer, and the third dielectric structure is patterned to form a second dielectric spacer, at least part of the first dielectric spacer overhangs above a first side of the first dielectric structure and forms a first recess over the channel layer, and at least part of the second dielectric spacer overhangs above a second side of the first dielectric structure opposing the first side of the first dielectric structure and forms a second recess over the channel layer.

5. The method of claim 1, further comprising forming a control terminal of the transistor on the second dielectric structures, in which the second dielectric structure is between the channel layer and the control terminal.

6. The method of claim 1, wherein forming a first dielectric structure includes:
forming a first dielectric layer of the first dielectric structure on the channel layer; and
forming a second dielectric layer of the first dielectric structure on the first dielectric layer and covering the channel layer on multiple sides.

7. The method of claim 1, wherein the dielectric spacer is a first dielectric spacer, patterning the third dielectric structure includes forming the first dielectric spacer and a second dielectric spacer, and forming a control terminal of the transistor on the first dielectric structure, wherein the first dielectric spacer is between the first current terminal and the control terminal, and the second dielectric spacer is between the second current terminal and the control terminal.

8. The method of claim 7, wherein forming a control terminal of the transistor includes:
forming a metal layer on the channel layer;
forming a first dielectric layer of the third dielectric structure on the metal layer;
patterning the metal layer and the first dielectric layer;
forming a second dielectric layer of the third dielectric structure on the patterned metal layer and the patterned first dielectric layer; and
patterning the second dielectric layer to form the first dielectric spacer and the second dielectric spacer on two sides of the patterned the metal layer.

9. The method of claim 8, further comprising forming a third dielectric layer on the first dielectric layer, wherein patterning the metal layer and the first dielectric layer includes patterning the third dielectric layer, and forming a second dielectric layer of the third dielectric structure on the patterned metal layer and the patterned first dielectric layer includes forming the second dielectric layer on the patterned metal layer and the patterned first and third dielectric layers; and
wherein the wet etching operation is a first etching operation, and patterning the second dielectric layer includes performing a second etching operation to remove a first part of the second dielectric layer and expose the third dielectric layer, and removing a second part of the second dielectric layer and the third dielectric layer to expose the first dielectric layer.

10. The method of claim 9, wherein the second etching operation is an anisotropic etching operation.

11. The method of claim 9, wherein the removing a second part of the second dielectric layer and the third dielectric layer is by a chemical and mechanical planarization operation.

12. The method of claim 8, wherein the metal layer is a first metal layer, and forming a control terminal of the transistor includes:
forming a through trench in the first dielectric layer;
forming the first metal layer or a third metal layer as a barrier metal layer on sidewalls of the through trench;
forming the second metal layer in the through trench and on the first or third metal layers;
forming a third dielectric layer of the third dielectric structure on the through trench including the barrier metal layer and the second metal layer;
patterning the first and third dielectric layers; and
forming the second dielectric layer on the patterned first and third electric layers.

13. The method of claim 12, wherein the barrier metal layer is the third metal layer and is formed on the first metal layer.

14. The method of claim 12, wherein the wet etching operation is a first etching operation, and patterning the second dielectric layer includes performing a second etching operation to remove a first part of the second dielectric layer and expose the third dielectric layer, and removing a second part of the second dielectric layer and the third dielectric layer to expose the first dielectric layer.

15. The method of claim 14, wherein the second etching operation is an anisotropic etching operation.

16. The method of claim 14, wherein the removing the second part of the third dielectric structure is by a chemical and mechanical planarization operation.

17. The method of claim 7, wherein the control terminal is between the first and second dielectric spacers along an axis, and at least one of the first or second dielectric spacers has a first dimension that is smaller than a second dimension of the control terminal along the axis.

18. The method of claim 17, wherein the second dimension is a minimum lithography dimension of the control terminal.

19. The method of claim 1, wherein the channel layer includes an oxide material, and the method further comprises reducing an oxygen content of the oxide material in the first and second parts of the channel layer.

20. The method of claim 19, wherein reducing an oxygen content of the oxide material in the first and second regions of the channel layer includes performing an oxygen anneal on the first and second parts of the channel layer.

21. The method of claim 1, wherein the channel layer includes carbon nanotubes, and the method further comprises introducing defects to the carbon nanotubes in the first and second parts of the channel layer.

22. The method of claim 21, wherein introducing defects to the carbon nanotubes in the first and second regions of the channel layer includes providing a plasma treatment to the carbon nanotubes in the first and second regions of the channel layer.

23. The method of claim 1, wherein the second dielectric structure includes a first dielectric layer and a second dielectric layer having different etch selectivities, and wherein forming a first current terminal of the transistor and forming a second current terminal of the transistor includes:
removing a first region and a second region of the first dielectric layer by a selective etching operation;
forming a first metal contact of the first current terminal at a location of the removed first region of the first dielectric layer and on the second dielectric layer; and
forming a second metal contact of the second current terminal at a location of the removed second region of the first dielectric layer and on the second dielectric layer.

24. The method of claim 1, wherein forming a first current terminal of the transistor and forming a second current terminal of the transistor includes:
forming a first layer of channel material on a first side of the dielectric spacer; and
forming a second layer of the channel material on a second side of the dielectric spacer opposing the first side, in which the first and second layer of the channel material abut the channel layer and have a same channel material as the channel layer.

25. The method of claim 24, wherein forming a first current terminal of the transistor and forming a second current terminal of the transistor includes:
selectively etching the second dielectric structure to form a first step structure and a second step structure on opposing sides of the channel layer;
forming a third layer of the channel material on the first step structure and abutting the first layer of the channel material;
forming a fourth layer of the channel material on the first step structure and abutting the second layer of the channel material;
forming a first layer of metal on the first and third layers of the channel material; and
forming a second layer of metal on the second and fourth layers of the channel material.

26. The method of claim 1, wherein the stack structure is a first stack structure, the channel layer is a first channel layer, the dielectric spacer is a first dielectric spacer, the wet etching operation is a first wet etching operation, and the method further comprises:
forming a second stack structure on the first dielectric spacer, in which the second stack structure includes a fourth dielectric structure, a second channel layer, and a fifth dielectric structure, in which the fourth and fifth dielectric structures are on opposing sides of the second channel layer, and the fifth dielectric structure and the first dielectric spacer are between the first and second channel layers;
forming a sixth dielectric structure on the fourth dielectric structure, in which the fourth dielectric structure is between the sixth dielectric structure and the second channel layer;
patterning the sixth dielectric structure to form a second dielectric spacer;
patterning the fourth dielectric structure by a second wet etching operation to expose a first part of the second channel layer and a second part of the second channel layer, in which the second dielectric spacer is between the first part and the second part of the second channel layer;
extending the first current terminal of the transistor to cover the first part of the second channel layer; and
extending the second current terminal of the transistor to cover the second part of the channel layer.
